(19) United States
(12) Patent Application Publication
(10) Pub. No.: US 2026/0058090 A1
(43) Pub. Date: Feb. 26, 2026

(54) TEACHING OF CHARGED-PARTICLE MICROSCOPY ROBOTIC GRIPPERS VIA BEAMSPLITTING

(71) Applicant: FEI Company, Hillsboro, OR (US)

(72) Inventors: David Nicholas Barsic, Portland, OR (US); Ronald Edward Neely, Hillsboro, OR (US); Esau Alameda De La Mora, Hillsboro, OR (US); Jae Hong Kim, Lake Oswego, OR (US); Elisabeth Susan Tappert, Portland, OR (US); Cameron Ivans Fischer, Streamwood, IL (US); Simon-Pierre Smith, Beaverton, OR (US); Luon B. Chung, Beaverton, OR (US); Andrei Karyukin, Tigard, OR (US); Ali Kerim Guzeldere, Hillsboro, OR (US)

(21) Appl. No.: 18/809,984

(22) Filed: Aug. 20, 2024

(51) Int. Cl. H01J 37/22; B25J 9/16; H01J 37/02

(52) U.S. Cl. CPC H01J 37/226; B25J 9/163; H01J 37/023; H01J 2237/1501; H01J 2237/1502

(57) ABSTRACT

Systems/techniques are provided for facilitating teaching of charged-particle microscopy robotic grippers via beamsplitting. In various embodiments, a system can access a charged-particle microscope having a vacuum chamber, wherein the vacuum chamber can comprise a robotic gripper and a microscopy grid receptacle. In various aspects, the system can teach the robotic gripper to angularly or translationally align its shaft-axis with a bore-axis of the microscopy grid receptacle, based on a beamsplitter-equipped light source coupled to the robotic gripper.

### BACKGROUND

Aligning a charged-particle microscopy robotic gripper with a grid receptacle can be difficult.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate teaching of charged-particle microscopy robotic grippers via beamsplitting are described.

According to one or more embodiments, an apparatus is provided. In various aspects, the apparatus can comprise a charged-particle microscope having a vacuum chamber, wherein the vacuum chamber can comprise a robotic gripper and a microscopy grid receptacle. In various instances, the apparatus can comprise a processor that can be configured to teach the robotic gripper to angularly or translationally align its shaft-axis with a bore-axis of the microscopy grid receptacle, based on a light source coupled to the robotic gripper.

According to one or more embodiments, a computer-implemented method is provided. In various aspects, the computer-implemented method can comprise accessing, by a device operatively coupled to a processor, a charged-particle microscope having a vacuum chamber, wherein the vacuum chamber can comprise a robotic gripper and a microscopy grid receptacle. In various instances, the computer-implemented method can comprise teaching, by the device, the robotic gripper to angularly or translationally align its shaft-axis with a bore-axis of the microscopy grid receptacle, based on a light source coupled to the robotic gripper.

According to one or more embodiments, a computer program product for facilitating teaching of charged-particle microscopy robotic grippers via beamsplitting is provided. In various embodiments, the computer program product can comprise a non-transitory computer-readable memory having program instructions embodied therewith. In various aspects, the program instructions can be executable by a processor to cause the processor to access a charged-particle microscope having a vacuum chamber, wherein the vacuum chamber can comprise a robotic gripper and a microscopy grid receptacle. In various instances, the program instructions can be executable by the processor to cause the processor to cause a light source affixed to the robotic gripper to shine a light beam through a beamsplitter, wherein the beamsplitter can be configured to direct a first portion of the light beam toward a camera, wherein the beamsplitter can be configured to direct a second portion of the light beam toward a reflector that can be positioned on or in a bore of the microscopy grid receptacle, wherein the reflector can be configured to reflect the second portion of the light beam back toward the beamsplitter, and wherein the beamsplitter can be configured to direct at least some of the second portion of the light beam toward the camera. In various cases, the program instructions can be executable by the processor to cause the processor to access an image captured by the camera, wherein the image can depict a first illuminated spot caused by the first portion of the light beam, and wherein the image can depict a second illuminated spot caused by the at least some of the second portion of the light beam. In various aspects, the program instructions can be executable by the processor to cause the processor to identify, based on a distance separating respective centroids of the first illuminated spot and the second illuminated spot, one or more angular or translational movements of the robotic gripper that would cause a shaft-axis of the robotic gripper to become angularly or translationally aligned with the bore of the microscopy grid receptacle. In various instances, the program instructions can be executable by the processor to cause the processor to cause the robotic gripper to perform the one or more angular or translational movements.

### DESCRIPTION OF THE DRAWINGS

Various embodiments will be readily understood by the following detailed description in conjunction with the accompanying figures. To facilitate this description, like reference numerals designate like structural elements. Embodiments are illustrated by way of example, not by way of limitation, in the figures. The figures are not necessarily drawn to scale.

FIG. 1 illustrates an example, non-limiting block diagram of a scientific instrument module in accordance with various embodiments described herein.

FIG. 2 illustrates an example, non-limiting flow diagram of a computer-implemented method in accordance with various embodiments described herein.

FIG. 3 illustrates a block diagram of an example, non-limiting system that facilitates teaching of charged-particle microscopy robotic grippers via beamsplitting in accordance with one or more embodiments described herein.

FIGS. 4-12 illustrate example, non-limiting block diagrams showing how a robotic gripper and a grid receptacle of a charged-particle microscope can be outfitted or equipped with alignment hardware in accordance with one or more embodiments described herein.

FIG. 13 illustrates a block diagram of an example, non-limiting system including an image that facilitates teaching of charged-particle microscopy robotic grippers via beamsplitting in accordance with one or more embodiments described herein.

FIGS. 14-17 illustrate non-limiting examples of images in accordance with one or more embodiments described herein.

FIG. 18 illustrates a block diagram of an example, non-limiting system including an object detection algorithm and an overlap determination that facilitates teaching of charged-particle microscopy robotic grippers via beamsplitting in accordance with one or more embodiments described herein.

FIG. 19 illustrates an example, non-limiting block diagram showing how an overlap determination can be obtained from an image in accordance with one or more embodiments described herein.

FIG. 20 illustrates a block diagram of an example, non-limiting system including a new angular configuration that facilitates teaching of charged-particle microscopy robotic grippers via beamsplitting in accordance with one or more embodiments described herein.

FIGS. 21-26 illustrate example, non-limiting block diagrams showing how a new angular configuration can be identified based on an overlap determination in accordance with one or more embodiments described herein.

FIGS. 27-30 illustrate flow diagrams of example, non-limiting computer-implemented methods that facilitate teaching of charged-particle microscopy robotic grippers via beamsplitting in accordance with one or more embodiments described herein.

FIG. 31 illustrates an example, non-limiting block diagram showing how various artificial intelligence models can be trained in accordance with one or more embodiments described herein.

FIGS. 32-36 illustrate example, non-limiting images of various experimental reductions to practice in accordance with one or more embodiments described herein.

FIG. 37 illustrates an example, non-limiting block diagram of a graphical user interface that can be used in the performance of some or all of the methods or techniques disclosed herein, in accordance with various embodiments described herein.

FIG. 38 illustrates an example, non-limiting block diagram of a computing device that can perform some or all of the methods or techniques disclosed herein, in accordance with various embodiments described herein.

FIG. 39 illustrates an example, non-limiting block diagram of a scientific instrument support system in which some or all of the methods or techniques disclosed herein may be performed, in accordance with various embodiments described herein.

FIG. 40 illustrates a block diagram of an example, non-limiting operating environment in which one or more embodiments described herein can be facilitated.

FIG. 41 illustrates an example networking environment operable to execute various implementations described herein.

FIG. 42 illustrates an example dual beam microscope that can be implemented in accordance with various embodiments described herein.

### DETAILED DESCRIPTION

The following detailed description is merely illustrative and is not intended to limit embodiments or application/uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiments. Various additional operations can be performed, or described operations can be omitted in additional embodiments.

Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices. As used herein, the phrase “based on” should be understood to mean “based at least in part on,” unless otherwise specified.

A charged-particle microscope (e.g., a scanning electron microscope (SEM), a transmission electron microscope (TEM), a dual beam microscope) can be any suitable computerized device that can capture or generate microscopic or nanoscopic images of specimens in a scientific, laboratory, research, or clinical operational environment. To facilitate the capture or generation of such images, charged-particle microscopes can leverage complex arrangements of actuatable parts (e.g., ion sources, electron sources, optical lenses or apertures, optical plates or deflectors, columns, coils, heaters, coolers, fluid valves, fluid pumps, circuit switches, specimen stages), sensors (e.g., ion detectors, electron detectors, voltmeters, thermistors, potentiometers, pressure gauges), or consumables (e.g., carrier fluids, calibrants, filters, reactive gases).

In order for a charged-particle microscope to capture an image of a specimen (e.g., an integrated circuit chip, a semiconductor wafer, a lamella, an organic or biological tissue sample), the specimen can be placed on an actuatable stage within a vacuum chamber of the charged-particle microscope. Such placement can be accomplished via a robotic gripper and a grid receptacle that are also within the vacuum chamber (e.g., that are located within a load-lock portion of the vacuum chamber). In particular, the grid receptacle can be any suitable fixed, static, or otherwise substantially stationary structure that can physically hold, house, or otherwise support any suitable number of grids, where each grid can be any suitable mesh, carrier, plate, or dish on which any suitable number of specimens can physically rest. Furthermore, the robotic gripper can be any suitable articulating or telescoping end-effector (e.g., an automated claw, an automated clamp, an automated hand) that can selectively grab one or more desired grids, and thus one or more desired specimens, from the grid receptacle and that can angularly or translationally move, so as to transport or convey the one or more desired grids to the actuatable stage. Accordingly, the robotic gripper can release its grip on the one or more desired grids, thereby placing, setting, or leaving the one or more desired grids, and thus the one or more desired specimens, on the actuatable stage, and so the charged-particle microscope can subsequently scan or capture images of the one or more desired specimens. After such scanning or image capturing, the robotic gripper can grab the one or more desired grids from the actuatable stage and can angularly or translationally move, so as to transport or convey the one or more desired grids back to the grid receptacle. Accordingly, the robotic gripper can release its grip on the one or more desired grids, thereby causing the one or more desired grids, and thus the one or more desired specimens, to be replaced or re-housed on or in the grid receptacle.

For any given grid, the given grid can be physically held, housed, or otherwise supported by the grid receptacle, based on or due to a shaft that protrudes from the given grid (e.g., that protrudes from the grid itself, or that protrudes from any suitable intermediate holder, carrier, cartridge, or other accessory to which the given grid is temporarily or permanently coupled) being inserted into a corresponding bore of the grid receptacle. Indeed, the shaft and the bore can be considered as mating surfaces. Accordingly, when the shaft protruding from the given grid is physically inserted into the bore of the grid receptacle, the given grid can be considered as being removably or slidably mated to the grid receptacle. Thus, when it is desired to transport or convey the given grid to the actuatable stage from the grid receptacle, the robotic gripper can grab onto the given grid (or onto whatever intermediate holder, carrier, cartridge, or other accessory is temporarily or permanently coupled to the given grid, as appropriate) and can physically pull on the given grid, so as to slide the shaft protruding from the given grid out of the bore, thereby freeing the given grid from the grid receptacle. Conversely, when it is desired to transport or convey the given grid to the grid receptacle from the actuatable stage, the robotic gripper can grab onto the given grid (or onto whatever intermediate holder, carrier, cartridge, or other accessory is temporarily or permanently coupled to the given grid, as appropriate) and can physically push on the given grid, so as to slide the shaft protruding from the given grid into the bore, thereby once again slidably or removably mating the given grid to the grid receptacle.

In order for the robotic gripper to correctly, properly, or otherwise accurately retrieve the given grid from the grid receptacle or replace the given grid back onto the grid receptacle, the robotic gripper should know how to angularly or translationally position or orient itself in three-dimensional space, so that the shaft protruding from the grid receptacle is precisely aligned in two translational directions (e.g., left-right direction, up-down direction) and in two rotational directions (e.g., pitch, yaw) with the bore of the grid receptacle. Indeed, there can be as little as only 6 to 30 micrometers of clearance between the shaft and the bore. If the shaft is not precisely aligned with the bore when the robotic gripper attempts to remove the given grid from the grid receptacle, or when the robotic gripper attempts to replace the given grid back onto the grid receptacle, then the shaft's outer surface can rub, bind, or collide excessively against the bore's inner surface. In some cases, such excessive rubbing, binding, or collision can physically jostle, destabilize, or otherwise damage whatever specimen is on the given grid, which can be undesirable. In other cases, such excessive rubbing, binding, or collision can generate metal shavings or other particulates that can contaminate whatever specimen is on the given grid, which can be undesirable. In even other cases, such excessive rubbing, binding, or collision can physically deteriorate or prematurely wear the robotic gripper, the given grid, or the grid receptacle, which can be undesirable.

Unfortunately, as the inventors of various embodiments described herein recognized, existing techniques for teaching the robotic gripper how to translationally or angularly align the shaft with the bore are imprecise and time-consuming. Indeed, existing techniques utilize borescopes or cameras that attempt to visually see when the shaft is translationally or angularly aligned with the bore. Some existing techniques utilize a borescope or camera that is physically coupled to or held by the robotic gripper, so as to capture a video feed that shows what the bore looks like from the point of view of the shaft. Accordingly, whatever three-dimensional position or orientation of the robotic gripper that causes the bore in the video feed to visually look or appear to be translationally or angularly aligned can be considered, marked, or flagged as achieving alignment. Conversely, whatever three-dimensional positions or orientations of the robotic gripper that cause the bore in the video feed to visually look or appear to be translationally or angularly misaligned can be considered, marked, or flagged as failing to achieve alignment. Such existing techniques are imprecise, since they can be considered as “eyeballing” methods that can provide only rough estimates of aligned positions. Additionally, most available cameras or borescopes are bulky or heavy in comparison to specimen grids (e.g., a grid or grid holder can weigh on the order of 1.3 grams, whereas most available miniature cameras or borescopes weigh on the order of tens of grams). Accordingly, such existing techniques suffer additional imprecision, due to the robotic gripper experiencing more deflection from the weight of the camera or borescope than it would experience from the weight of a grid or grid holder (e.g., because of such additional deflection, a position of the robotic gripper that seems to visually align the shaft with the bore when the robotic gripper is holding the camera or borescope might actually fail to align the shaft with the bore when the robotic gripper is instead holding a grid). Other existing techniques attempt to deal with this additional deflection problem by using cameras or borescopes that are not coupled to or held by the robotic gripper and that have both the robotic gripper and the bore in their fields of view. Although such other embodiments eliminate the problem of additional deflection, they require multiple cameras or borescopes (e.g., a top-view or bottom-view camera or borescope does a poor job showing top-down translational alignment and pitch angular alignment; a side-view camera or borescope does a poor job showing left-right translational alignment and yaw angular alignment), and they still qualify as imprecise “eyeballing” methods that can provide only rough alignment estimates. In any case, existing techniques that rely upon cameras or borescopes require hours, even days, of meticulous positional iteration to identify which three-dimensional positions or orientations of the robotic gripper visually appear to be aligned with the bore of the grid receptacle.

Accordingly, systems or techniques that can more efficiently or efficaciously teach the robotic gripper how to become aligned with the bore of the grid receptacle can be desirable.

Various embodiments described herein can address this technical problem. One or more embodiments described herein can include systems, computer-implemented methods, apparatus, or computer program products that can facilitate teaching of charged-particle microscopy robotic grippers via beamsplitting. In other words, the inventors of various embodiments described herein devised various techniques for teaching a robotic gripper how to become angularly or translationally aligned with a bore of a grid receptacle, which do not suffer from the imprecision or time-consuming iteration of existing techniques. Various embodiments described herein can facilitate such teaching via a light source coupled to or held by the robotic gripper. In particular, the light source can shine a light beam through a beamsplitter that is also coupled to or held by the robotic gripper. In various aspects, the beamsplitter can direct a first portion of the light beam toward the camera. In various instances, the beamsplitter can direct a second portion of the light beam toward a reflector that is located on or in the bore of the grid receptacle. In various cases, the reflector can direct the second portion of the light beam back toward the beamsplitter, and the beamsplitter can direct at least some of the second portion of the light beam toward the camera. Accordingly, the camera can capture an image that depicts two illuminated spots: a first spot caused by the first portion of the light beam; and a second spot caused by the at least some of the second portion of the light beam.

In various aspects, whether or not the robotic gripper is angularly aligned with the bore of the grid receptacle can be determined based on that image. For instance, if the first and second spots are not concentric with each other, it can be concluded that the robotic gripper is not angularly aligned with the bore (e.g., it can be concluded that the robotic gripper is misaligned in a yaw or pitch direction with respect to the bore). Conversely, if the first and second spots are concentric with each other, it can instead be concluded that the robotic gripper is angularly aligned with the bore (e.g., it can be concluded that the robotic gripper is aligned in both the yaw and pitch directions with respect to the bore).

In various other aspects, whether or not the robotic gripper is translationally aligned with the bore can also be determined based on that image. Indeed, the reflector can be constructed in a non-uniform or segmented fashion, such that it provides a strongest or highest amount of reflection at its center (and thus at the center of the bore), and such that it provides progressively lesser or weaker amounts of reflection towards its edges (and thus toward the inner surface of the bore). Accordingly, if an intensity of the second spot is weak (e.g., below a threshold value), it can be concluded that the robotic gripper is not translationally aligned with the bore (e.g., it can be concluded that the robotic gripper is misaligned in a top-down or right-left direction with respect to the bore such that the light source is not pointing at the center of the bore). Conversely, if an intensity of the second spot is strong (e.g., above a threshold value), it can instead be concluded that the robotic gripper is translationally aligned with the bore (e.g., it can be concluded that the robotic gripper is aligned in both the top-down and right-left directions with respect to the bore such that the light source is pointing at the center of the bore).

In any case, various embodiments described herein can teach the robotic gripper without suffering from the disadvantages of existing techniques. In particular, sub-gram light sources (e.g., micro-lasers, miniature light-emitting diodes (LEDs)) and sub-gram beamsplitters are more readily available than sub-gram cameras or borescopes. Accordingly, various embodiments described herein can refrain from causing the robotic gripper to experience significantly more deflection during the learning or teaching phase than it would experience while holding a grid. Furthermore, various embodiments described herein do not require the use of multiple cameras or borescopes. Instead, a single camera or borescope into which the beamsplitter can direct light can suffice. Further still, at least with respect to angular alignment, various embodiments described herein do not require nearly as many iterations as the “eyeballing” methods of existing techniques. Indeed, because the dimensions of and between the robotic gripper and the grid receptacle can be known or controlled, kinematic formulations can be derived to mathematically relate the three-dimensional position or orientation of the robotic gripper to the intra-image positions of the first and second spots in the image captured by the camera. Accordingly, if the first and second spots are not yet concentric in the image, those kinematic formulations and the current intra-image locations of the first and second spots can be used so as to identify what three-dimensional position or orientation of the robotic gripper would cause the first and second spots to become concentric with each other (or to at least get closer to concentricity). Once the first and second spots have achieved a threshold level of concentricity (e.g., once they are within a threshold margin or proximity of each other), even further angular alignment can be achieved by: fitting a least-area contour around both the first and second spots; sweeping the robotic gripper through a range of near-by positions or orientations; and selecting whichever swept position or orientation causes the least-area contour to have a minimized area value. Thus, the time-consuming trial-and-error of existing eyeballing techniques can be eschewed, due to the more directed or guided techniques described herein.

Various embodiments described herein can be considered as a computerized tool (e.g., any suitable combination of computer-executable hardware or computer-executable software) that can facilitate teaching of charged-particle microscopy robotic grippers via beamsplitting. In various aspects, such computerized tool can comprise an access component, an overlap component, a correction component, or an execution component.

In various embodiments, there can be a charged-particle microscope. In various aspects, the charged-particle microscope can exhibit any suitable design or construction (e.g., can be an SEM, can be a TEM, can be a dual-beam microscope). In various instances, the charged-particle microscope can have any suitable vacuum chamber, and any suitable robotic gripper and grid receptacle can be deployed or implemented within the vacuum chamber.

In any case, it can be desired to teach the robotic gripper to align its shaft-axis (e.g., axis that would be concentric with a shaft protruding from a grid, when the grid is held by the robotic gripper) with a bore-axis (e.g., axis of a bore into which a shaft protruding from a grid can be inserted) of the grid receptacle. As described herein, the computerized tool can accomplish such teaching, by leveraging various alignment hardware that can equipped onto or into the charged-particle microscope.

In particular, the alignment hardware can include a light source, a collimator lens, a beamsplitter, a reflector, or a camera.

In various embodiments, the robotic gripper and the grid receptacle can be affixed to any suitable surfaces or walls within the vacuum chamber, such that the grid receptacle (and thus whatever grids or grid holders that it can house, carry, or support) is within reach of the robotic gripper.

In various aspects, the light source can be any suitable device whose weight is less than or otherwise within any suitable margin of a gram, and that can emit or create light beams of any suitable wavelengths or frequencies along any suitable optical-axis (e.g., the light source can be an integrated circuit LED or micro-laser). In various instances, the light source can be gripped, held by, or otherwise coupled in any suitable fashion to the robotic gripper, such that the optical-axis of the light source is colinear with the shaft-axis of the robotic gripper.

In various cases, the collimator lens can be any suitable lens or optical device whose weight is less than or otherwise within any suitable margin of a gram, and that can cause incoming light to become parallel or collimated (e.g., plano-convex lens, meniscus lens, cylindrical lens, Fresnel lens). In various aspects, the collimator lens can be coupled in any suitable fashion to the light source, such that the collimator lens can collimate (e.g., can make parallel) light beams emitted by the light source.

In various instances, the beamsplitter can be any suitable lens or optical device whose weight is less than or otherwise within any suitable margin of a gram, and that can split incoming light into distinct or separate beams according to any suitable transmittance-to-reflectance ratios (e.g., dielectric beamsplitter, metallic beamsplitter, cubic prism beamsplitter, plate beamsplitter). In particular, the beamsplitter can be a cubic prism having two distinct beamsplitting coatings: a first beamsplitting coating on an interior diagonal plane of the cubic prism; and a second beamsplitting coating on an exterior surface of the cubic prism that faces toward the grid receptacle. Accordingly, the first and second beamsplitting coatings can be considered as having an angle of 45 degrees between them. In other words, the first beamsplitting coating can be oriented 45 degrees with respect to the optical-axis of the robotic gripper, whereas the second beamsplitting coating can instead be oriented perpendicularly or orthogonally with respect to the optical-axis of the robotic gripper. In various cases, the beamsplitter can be coupled in any suitable fashion to the collimator lens, such that the beamsplitter can split light beams emitted by the light source and collimated by the collimator lens.

It should be understood that the light source, collimator lens, and beamsplitter can, in some instances, be coupled to each other via any suitable sub-gram mounting bracket, sub-gram cantilever, or other sub-gram mounting hardware.

In various aspects, the reflector can be any suitable lens or optical device that can reflect incoming light (e.g., mirror, or beamsplitting coating having 0% transmittance). In various instances, the reflector can be coupled in any suitable fashion to, on, or within a bore of the grid receptacle, such that the reflector is orthogonal or perpendicular to the bore-axis of the grid receptacle. Note that the reflector can be not held by or otherwise coupled to the robotic gripper.

In various cases, the camera can be any suitable image-capture device. In various aspects, the camera can be located or positioned on or within the vacuum chamber, such that light beams that are split by the beamsplitter can be directed toward (e.g., seen by) the camera. In some instances, the camera can be physically inside of the vacuum chamber. However, in other instances, the camera can instead be physically outside of the vacuum chamber and can peer or see into the vacuum chamber via any suitable window or viewport of the vacuum chamber. As above, note that the camera can be not held by or otherwise coupled to the robotic gripper.

Now, in various embodiments, the light source can emit a light beam. For ease of explanation, let the light beam be referred to as a light beam A. In various aspects, the light beam A can pass through the collimator lens and into the beamsplitter. As mentioned above, the beamsplitter can, in some cases, be a cubic prism having a first beamsplitting coating along an interior diagonal plane and a second beamsplitting coating along an exterior surface that faces toward the grid receptacle. Accordingly, the light beam A can enter the beamsplitter and interact with the first beamsplitting coating.

The first beamsplitting coating can allow some of the light beam A to transmit or pass, while reflecting a remainder of the light beam A. For ease of explanation, the passed or transmitted portion can be referred to as a light beam B, whereas the reflected portion can be referred to as a light beam C. In various cases, the first and second beamsplitting coatings can be oriented such that the 45-degree angle formed between them opens or faces toward the camera. This can cause the light beam C to be directed away from, and thus to not be seen by, the camera. This can also cause the light beam B to continue propagating through the beamsplitter, so as to next interact with the second beamsplitting coating.

The second beamsplitting coating can allow some of the light beam B to transmit or pass, while reflecting a remainder of the light beam B. For ease of explanation, the passed or transmitted portion can be referred to as a light beam D, whereas the reflected portion can be referred to as a light beam E. The orientation of the second beamsplitting coating can cause the light beam E to propagate back toward, and thus interact with, the first beamsplitting coating. In contrast, the orientation of the second beamsplitting coating can cause the light beam D to instead propagate toward, and thus interact with, the reflector within the bore of the grid receptacle.

As above, the first beamsplitting coating can allow some of the light beam E to transmit or pass (e.g., so as to propagate toward the light source), while reflecting a remainder of the light beam E. For ease of explanation, the reflected portion can be referred to as a light beam F. In various cases, the orientation of the first beamsplitting coating can cause the light beam F to be directed toward, and thus to be seen by, the camera.

Now, consider again the light beam D that is passed or transmitted toward the reflector by the second beamsplitting coating. The reflector can cause the light beam D to be reflected back toward the second beamsplitting coating. The second beamsplitting coating can allow some of the light beam D to transmit or pass, while reflecting a remainder of the light beam D (e.g., so as to propagate back toward the reflector). For ease of explanation, the passed or transmitted portion can be referred to as a light beam G. The orientation of the second beamsplitting coating can cause the light beam G to propagate back toward, and thus interact with, the first beamsplitting coating.

As above, the first beamsplitting coating can allow some of the light beam G to transmit or pass (e.g., so as to propagate toward the light source), while reflecting a remainder of the light beam G. For ease of explanation, the reflected portion can be referred to as a light beam H. In various cases, the orientation of the first beamsplitting coating can cause the light beam H to be directed toward, and thus to be seen by, the camera.

Accordingly, the camera can capture an image that depicts two illuminated spots: a first illuminated spot corresponding to or otherwise caused by the light beam F; and a second illuminated spot corresponding to or otherwise caused by the light beam H. In various instances, the image can depict nothing other than the first and second illuminated spots. For example, the image can contain non-zero-value pixels and zero-value pixels, where some of the non-zero pixels belong to or make up the first illuminated spot, and where the remaining non-zero-value pixels belong to or make up the second illuminated spot. In various aspects, whether or not the optical-axis of the robotic gripper is angularly aligned with the bore-axis of the grid receptacle can be determined based on the image.

Indeed, because the first illuminated spot can be caused by the light beam F, because the light beam F can be based on a reflection caused by the second beamsplitting coating, and because the second beamsplitting coating can be orthogonal to the optical-axis of the robotic gripper, the intra-image location of the second illuminated spot can be considered as depending upon or indicating the angular orientation of the optical-axis. In other words, the angular orientation in three-dimensional space of the optical-axis can be considered as controlling or influencing where the first illuminated spot is positioned within the image. In contrast, because the second illuminated spot can be caused by the light beam H, because the light beam H can be based on a reflection caused by the reflector, and because the reflector can be orthogonal to the bore-axis of the grid receptacle, the intra-image location of the second illuminated spot can be considered as depending upon the angular orientation of the bore-axis. In other words, the angular orientation in three-dimensional space of the bore-axis can be considered as controlling or influencing where the second illuminated spot is positioned within the image.

In this way, the first and second illuminated spots can be considered as conveying information regarding whether or not the optical-axis and the bore-axis are angularly aligned. Indeed, if the image shows or depicts the first and second illuminated spots as being concentric with each other, the optical-axis and the bore-axis can be considered as being angularly aligned. On the other hand, if the image shows or depicts the first and second illuminated spots as not being concentric with each other, the optical-axis and the bore-axis can instead be considered as being angularly misaligned.

As described herein, the computerized tool can electronically teach the robotic gripper how to make the optical-axis (and thus its shaft-axis) angularly aligned with the bore-axis of the grid receptacle, based on the image.

In various embodiments, the access component of the computerized tool can electronically access the image. For instance, the access component can electronically receive or retrieve the image from the camera. In some cases, the access component can be considered as a conduit through which other components of the computerized tool can electronically interact with (e.g., read, write, edit, copy, manipulate) the image.

In various embodiments, the overlap component of the computerized tool can electronically determine whether or not the first and second illuminated spots are overlapping with each other.

In particular, the overlap component can electronically store, maintain, control, or otherwise access an object detection algorithm. In various aspects, the object detection algorithm can be any suitable algorithm or procedure for detecting or recognizing how many distinct or separate objects are depicted within any given image. In some instances, the object detection algorithm can exhibit any suitable machine learning architecture. For example, the object detection algorithm can be a deep learning neural network that is configured to receive an inputted image and to produce as output a scalar indicating a total number of objects that are (in the opinion of the deep learning neural network) depicted in the inputted image. In such case, the deep learning neural network can have any suitable numbers of any suitable types of layers (e.g., input layer, one or more hidden layers, output layer, any of which can be convolutional layers, dense layers, long short-term memory (LSTM) layers, non-linearity layers, pooling layers, batch normalization layers, or padding layers), can have any suitable numbers of neurons in various layers (e.g., different layers can have the same or different numbers of neurons as each other), can have any suitable activation functions (e.g., softmax, sigmoid, hyperbolic tangent, rectified linear unit) in various neurons (e.g., different neurons can have the same or different activation functions as each other), or can have any suitable interneuron connections or interlayer connections (e.g., forward connections, skip connections, recurrent connections). In other instances, the object detection algorithm can instead exhibit any suitable non-machine-learning architecture. For example, the object detection algorithm can include any suitable computer vision procedures or techniques that utilize Hu moments, pixel intensity profiles, histograms of oriented gradients, template matching, Haar cascades, or edge boxes.

Regardless of its specific internal architecture, the object detection algorithm can be configured to determine how many distinct or separate objects are illustrated within any given image. Accordingly, the overlap component can electronically execute the object detection algorithm on the image captured by the camera of the alignment hardware, and such execution can yield a scalar that indicates how many total objects are depicted in the image (as inferred by the object detection algorithm). For example, suppose that the object detection algorithm is a deep learning neural network. In such case, the overlap component can feed the image to an input layer of the object detection algorithm, the image can complete a forward pass through one or more hidden layers of the object detection algorithm, and an output layer of the object detection algorithm can calculate the scalar based on activations provided by the one or more hidden layers of the object detection algorithm. As another example, suppose that the object detection algorithm is instead a non-machine-learning algorithm. In such case, the overlap component can compute for the image whatever Hu moments, intensity profiles, or pixel histograms are called for the object detection algorithm, and the overlap component can calculate the scalar based on such Hu moments, intensity profiles, or pixel histograms.

In any case, the scalar can be a positive integer whose value or magnitude indicates how many distinct, separate objects that the object detection algorithm has detected or recognized within the image. As mentioned above, the image can depict or illustrate the first and second illuminated spots. In various aspects, the image can depict no objects other than the first and second illuminated spots (although the image might depict artifacts or residuals of the first and second illuminated spots, such artifacts or residuals can be removed via pixel thresholding). Accordingly, there can be two possible scenarios: a first scenario in which the image can have two distinct, separate objects, which can occur when the first and second illuminated spots are not overlapping with each other; and a second scenario in which the image can instead have only a single object, which instead can occur when the first and second illuminated spots are overlapping with each other by at least some amount.

Accordingly, by leveraging the object detection algorithm, the overlap component can be considered as determining whether or not the first and second illuminated spots are overlapping. If the object detection algorithm infers that the image depicts two objects, the overlap component can conclude that the first and second illuminated spots must not be overlapping or touching in the image (e.g., otherwise, the first and second illuminated spots would not be visually distinguishable from the perspective of the object detection algorithm). In contrast, if the object detection algorithm instead infers that the image depicts one object, the overlap component can conclude that the first and second illuminated spots must be overlapping, touching, or otherwise conjoined in the image.

In various embodiments, the correction component of the computerized tool can electronically identify a position or orientation of the robotic gripper in three-dimensional space which would cause the optical-axis (and thus the shaft-axis) of the robotic gripper to become angularly aligned with the bore-axis of the grid receptacle. For ease of explanation, such identified position or orientation can be referred to as a new angular configuration. In various aspects, how the correction component identifies the new angular configuration can be based on whether or not the first and second illuminated spots are overlapping.

Suppose that the overlap component determines that the first and second illuminated spots are not overlapping. In such case, whatever pixels that belong to or make up the first illuminated spot can be known, and whatever pixels that belong to or make up the second illuminated spot can likewise be known (e.g., because there can be no overlap, and because the image can depict no objects other than the first and second illuminated spots, each non-zero-value pixel in the image can be considered as belonging to exactly one of the first and second illuminated spots). So, in various aspects, the correction component can average the intra-image positions of whichever pixels belong to the first illuminated spot, thereby yielding a first centroid of the first illuminated spot. Similarly, the correction component can average the intra-image positions of whichever pixels belong to the second illuminated spot, thereby yielding a second centroid of the second illuminated spot. In various instances, the correction component can identify the new angular configuration, by applying any suitable pixel-to-physical kinematic formulas to the first and second centroids. Indeed, because the dimensions, relative locations, and other properties or characteristics of the robotic gripper, of the bore of the grid receptacle, of the light source, of the collimator lens, of the beamsplitter, of the reflector, and of the camera can all be known or otherwise controlled, any suitable mathematical formulas can be derived (e.g., from classical or quantum mechanics; taking into account angular displacements of the robotic gripper, angles of incidence or angles of reflection of light beams with which the beamsplitter or reflector interact, transmission-to-reflectance ratios of the beamsplitter or reflector, distance separating the camera from the beamsplitter, or distance separating the beamsplitter from the reflector) that define or quantify how an angular movement of the robotic gripper can influence the intra-image locations of the first and second centroids. In other words, there can be any suitable mathematical transformations or functions that relate the first and second centroids to the three-dimensional position or orientation of the robotic gripper. Accordingly, the correction component can be considered as knowing how angular or translational deviations of the robotic gripper from its current three-dimensional position or orientation will cause the centroids of the first and second illuminated spots to move (e.g., given the current intra-image locations of the robotic gripper, reducing pitch of the robotic gripper by θ degrees will move the first centroid to a first new location and will simultaneously move the second centroid to a second new location; given the current intra-image locations of the robotic gripper, increasing yaw of the robotic gripper by φ degrees will move the first centroid to a third new location and will simultaneously move the second centroid to a fourth new location). So, the correction component can utilize those mathematical transformations or functions, so as to identify the new angular configuration (e.g., so as to identify a three-dimensional position or orientation of the robotic gripper that would cause the first and second centroids to become concentric or to otherwise move closer together). Note that aimless trial-and-error is not required to identify the new angular configuration in such case, unlike with existing eyeballing techniques.

Now, suppose instead that the overlap component determines that the first and second illuminated spots are overlapping. In such case, the pixels that make up the first illuminated spot might not be visually distinguishable from the pixels that make up the second illuminated spot (e.g., due to the detected overlap, some pixels of the image might belong to both the first and second illuminated spots, and it can be non-trivial to identify such pixels). Accordingly, pixel position averaging cannot be reliably used to locate the first and second centroids. In various aspects, the correction component can fit a contour to the image, such that the contour is any suitable two-dimensional boundary (e.g., rectangle, ellipse) of least-area that circumscribes both the first and second illuminated spots (e.g., that circumscribes all of the non-zero pixels of the image). To accomplish this, any suitable computer vision contour fitting techniques can be implemented. In some cases, the correction component can implement any suitable machine learning contour fitting technique. For example, the machine learning contour fitting technique can be a deep learning neural network that is configured to receive the image as input and to identify as output the vertices or edges of the contour. In such case, the deep learning neural network can have any suitable numbers of any suitable types of layers (e.g., input layer, one or more hidden layers, output layer, any of which can be convolutional layers, dense layers, LSTM layers, non-linearity layers, pooling layers, batch normalization layers, or padding layers), can have any suitable numbers of neurons in various layers (e.g., different layers can have the same or different numbers of neurons as each other), can have any suitable activation functions (e.g., softmax, sigmoid, hyperbolic tangent, rectified linear unit) in various neurons (e.g., different neurons can have the same or different activation functions as each other), or can have any suitable interneuron connections or interlayer connections (e.g., forward connections, skip connections, recurrent connections). In other cases, the correction component can instead implement any suitable non-machine-learning contour fitting technique. For example, the non-machine-learning contour technique can include any suitable computer vision procedures or techniques that utilize polygon approximations, convex hull computations, or curve fitting calculations. In any case, the dimensions of the fitted contour can be known, and the correction component can leverage those dimensions to identify the first and second centroids, by applying any suitable geometric formulas to the fitted contour (e.g., the first and second illuminated spots can be assumed to be circles having identical radii, those radii can be geometrically approximated based on the known dimensions of the fitted contour, and so the first and second centroids can be located based on those radii and on the known location of the fitted contour).

Now, the present inventors found that identifying the new angular configuration via the pixel-to-physical kinematic formulas can become less accurate or reliable as the first and second centroids get closer together (e.g., as the amount of overlap between the first and second illuminated spots grows). Accordingly, in various aspects, the correction component can compute or measure a distance that separates the first centroid from the second centroid. If that distance exceeds any suitable threshold value, the correction component can conclude that the first and second centroids are far enough apart so that the pixel-to-physical kinematic formulas can be reliably used. Thus, the correction component can identify the new angular configuration, by applying the pixel-to-physical kinematic formulas to the first and second centroids, as mentioned above. In contrast, if that distance is less than the threshold value, the correction component can instead conclude that the first and second centroid are too close together for the pixel-to-physical kinematic formulas to be reliably used. In such case, the correction component can identify the new angular configuration, by sweeping the robotic gripper through a range of angular configuration that are within any suitable threshold margin or proximity of its current angular configuration. For each of those swept angular configurations, the correction component can compute a respective area which that swept angular configuration causes the fitted contour to have. Whichever one of those swept angular configurations causes the fitted contour to exhibit a minimum or minimized area can be considered as causing the first and second illuminated spots to be as close together as possible, and such swept angular configuration can thus be considered or treated as the new angular configuration.

In any case, the new angular configuration can be considered as being whatever three-dimensional position or orientation of the robotic gripper that causes the optical-axis, and thus the shaft-axis, to be angularly aligned (e.g., parallel) with the bore-axis. Indeed, experiments conducted by the present inventors verified that various embodiments described herein were able to achieve angular alignment to less than 1 arcsecond per pixel resolution, which can be considered as highly precise angular alignment. Moreover, various embodiments described herein achieved such angular alignment in mere minutes. Contrast this with the tedious hours or days consumed by existing eyeballing techniques.

In various embodiments, the execution component of the computerized tool can electronically perform or initiate any suitable electronic actions based on the new angular configuration. For example, the execution component can cause the robotic gripper to move to or otherwise occupy the new angular configuration. As another example, the execution component can mark or flag the new angular configuration as being angularly aligned with the bore of the grid receptacle, such that the new angular configuration can be easily or quickly referenced or used in the future. In other words, the robotic gripper can now be considered as knowing, having learned, or having been taught that the new angular configuration is angularly aligned with the bore of the grid receptacle.

Although the herein disclosure has so far mainly described various embodiments in which the image captured by the camera of the alignment hardware can be used to teach the robotic gripper how to become angularly aligned with the bore of the grid receptacle, these are mere non-limiting examples. In some cases, the image captured by the camera of the alignment hardware can also be used to teach the robotic gripper how to become translationally aligned with the grid receptacle. For example, the reflector that is placed on or in the bore of the grid receptacle can be segmented, fragmented, or otherwise non-uniform. In other words, the reflector can, in some embodiments, have a spatially-varying reflectance property. Indeed, in some cases, the reflectance of the reflector can be at a maximum value at its center, and thus at the center of the bore, and progressively (e.g., in continuous or step-wise fashion) decrease radially outward. Accordingly, because the second illuminated spot can be created due to the reflector, the correction component can electronically determine whether or not the optical-axis of the robotic gripper is translationally aligned (e.g., colinear) with the bore-axis, based on an intensity (e.g., average intensity, maximum intensity, intensity profile) of the second illuminated spot. If the robotic gripper has already been angularly aligned with the bore, and if the intensity of the second illuminated spot is above any suitable threshold, it can be inferred that the optical-axis of the robotic gripper is pointing toward the high-reflectance center of the reflector and is thus translationally aligned with the bore. In contrast, if the robotic gripper has already been angularly aligned with the bore, and if the intensity of the second illuminated spot is below the threshold, it can instead be inferred that the optical-axis of the robotic gripper is not pointing toward the high-reflectance center of the reflector and is thus not translationally aligned with the bore. In such case, the correction component can sweep the robotic gripper through a range of translational configurations that are within any suitable margin or proximity of its current translational configuration, and whichever swept translational configuration that causes the intensity of the second illuminated spot to satisfy the threshold can be considered as causing the robotic gripper to become translationally aligned with the bore.

It should be appreciated that the grid receptacle can have any suitable number of different bores and that various embodiments described herein can be implemented with respect to each of such different bores (e.g., to teach the robotic gripper how to become angularly or translationally aligned with each of such different bores).

Various embodiments described herein can be employed to use hardware or software to solve problems that are highly technical in nature (e.g., to facilitate teaching of charged-particle microscopy robotic grippers via beamsplitting), that are not abstract and that cannot be performed as a set of mental acts by a human. Further, some of the processes performed can be performed by a specialized computer (e.g., charged-particle microscopes such as SEMs, TEMs, or dual-beam microscopes having vacuum chambers and grid-handling robotics; optical hardware such as cameras, light sources, beamsplitters, and reflectors) for carrying out defined acts related to the field of charged-particle microscopy.

For example, such defined acts can include: accessing, by a device operatively coupled to a processor, a charged-particle microscope having a vacuum chamber, wherein the vacuum chamber can comprise a robotic gripper and a microscopy grid receptacle; and teaching, by the device, the robotic gripper to angularly or translationally align its shaft-axis with a bore-axis of the microscopy grid receptacle, based on a light source coupled to the robotic gripper. In various aspects, such defined acts can comprise: causing, by the device, the light source to shine a light beam through a beamsplitter, wherein the beamsplitter can be configured to direct a first portion of the light beam toward a camera, wherein the beamsplitter can be configured to direct a second portion of the light beam toward a reflector that can be positioned on or in a bore corresponding to the bore-axis, wherein the reflector can be configured to reflect the second portion of the light beam back toward the beamsplitter, and wherein the beamsplitter can be configured to direct at least some of the second portion of the light beam toward the camera. In various instances, the camera can be configured to capture an image, wherein the image depicts a first illuminated spot caused by the first portion of the light beam, and wherein the image depicts a second illuminated spot caused by the at least some of the second portion of the light beam.

In various cases, such defined acts can comprise: determining, by the device and via application of an object detection technique to the image, whether or not the first illuminated spot and the second illuminated spot are overlapping. In response to a determination that the first illuminated spot and the second illuminated spot are not overlapping, such defined acts can comprise: identifying, by the device, a first centroid of the first illuminated spot, based on averaging positions of pixels belonging to the first illuminated spot; identifying, by the device, a second centroid of the second illuminated spot, based on averaging positions of pixels belonging to the second illuminated spot; computing, by the device and via one or more kinematic formulas, an angular or translational position of the robotic gripper that is predicted to reduce a distance separating the first centroid from the second centroid; and causing, by the device, the robotic gripper to move to the angular or translational position.

In response to a determination that the first illuminated spot and the second illuminated spot are overlapping, such defined acts can comprise: circumscribing, by the device, the first illuminated spot and the second illuminated spot with a least-area contour; identifying, by the device and via one or more geometric formulas based on the least-area contour, a first centroid of the first illuminated spot and a second centroid of the second illuminated spot; in response to a distance separating the first centroid from the second centroid being greater than a threshold, computing, by the device and via one or more kinematic formulas, an angular or translational position of the robotic gripper that is predicted to reduce the distance; and causing, by the device, the robotic gripper to move to the angular or translational position.

In response to a determination that the first illuminated spot and the second illuminated spot are overlapping, such defined acts can comprise: circumscribing, by the device, the first illuminated spot and the second illuminated spot with a least-area contour; identifying, by the device and via one or more geometric formulas based on the least-area contour, a first centroid of the first illuminated spot and a second centroid of the second illuminated spot; in response to a distance separating the first centroid from the second centroid being less than a threshold, causing, by the device, the robotic gripper to sweep through a range of angular or translational positions within a threshold proximity of its current angular or translational position; computing, by the device, respective areas of the least-area contour for the range of angular or translational positions; and causing, by the device, the robotic gripper to move to whichever of the range of angular or translational positions corresponds to a minimized area of the least-area contour

Such defined acts are inherently computerized. Indeed, a charged-particle microscope (e.g., SEM, TEM, dual beam microscope) is a highly-technical computerized device comprising specific computerized hardware (e.g., temperature sensors, pressure sensors, voltage sensors, ion beam emitters, electron beam emitters, focusing lenses, ion detectors, electron detectors, beam apertures, fluid valves, actuatable specimen stages). Neither a charged-particle microscope nor the specimen-handling robotic hardware thereof can be implemented by the human mind, or by a human with pen and paper, in any reasonable or practicable way without computers. Furthermore, optical hardware (e.g., cameras, light sources, reflectors, beamsplitters) that can emit, reflect, or otherwise manipulate light beams are tangible, physical devices that cannot be implemented in any reasonable way by the human mind without computers.

Moreover, various embodiments described herein can integrate into a practical application various teachings relating to the field of charged-particle microscopy. As explained above, it can be desired to teach a robotic gripper of a charged-particle microscope how to angularly or translationally align its shaft-axis with a bore-axis of a grid receptacle of the charged-particle microscope. In other words, it can be desired to identify which specific three-dimensional position or orientation of the robotic gripper causes the shaft-axis to be aligned with the bore-axis. Existing techniques facilitate such teaching or identification via borescopes or cameras that attempt to visually look for such alignment. Some existing techniques involve a borescope or camera that is coupled to or held by the robotic gripper. Such existing techniques are imprecise (e.g., can only achieve a rough visual estimate of alignment; can experience confounding deflection, since miniature cameras are generally an order of magnitude heavier than specimen grids) and time-consuming (e.g., can necessitate hours or days of positionally iterating the robotic gripper). Other existing techniques involve borescopes or cameras that are not coupled to or held by the robotic gripper and that have both the robotic gripper and the grid receptacle in their fields of view. Such other existing techniques require multiple cameras (e.g., top-view cameras cannot reliably judge top-down translational alignment or pitch angular alignment; side-view cameras cannot reliably judge left-right translational alignment or yaw angular alignment), are still imprecise (e.g., notwithstanding absence of extra deflection, still can achieve only a rough visual estimate of alignment), and are still time-consuming (e.g., again, can necessitate hours or days of positionally iterating the robotic gripper). Thus, existing techniques suffer from various technical disadvantages.

Various embodiments described herein can help to ameliorate one or more of these technical problems, by implementing teaching of charged-particle microscopy robotic grippers via beamsplitting. In particular, when given a robotic gripper and a grid receptacle, the robotic gripper can be taught how to become translationally or angularly aligned with a bore of the grid receptacle, based on a light source coupled to the robotic gripper. Indeed, the light source can shine a light beam through a beamsplitter, which can also be coupled to the robotic gripper. The beamsplitter can direct a first portion of the light beam toward a camera, thereby causing the camera to see or capture a first illuminated spot. The beamsplitter can direct a second portion of the light beam toward a reflector that is located within the bore of the grid receptacle. The reflector can direct the second portion of the light beam back toward the beamsplitter, and the beamsplitter can direct at least some of that second portion toward the camera, thereby causing the camera to see or capture a second illuminated spot. As described herein, the intra-image locations of the first and second illuminated spots can be considered as depending upon the relative angular orientations of the robotic gripper and the bore. If the robotic gripper is angularly aligned with the bore (e.g., such that the optical-axis of the light source is parallel to the bore-axis of the grid receptacle), such angular alignment will cause the first and second illuminated spots to be concentric. On the other hand, If the robotic gripper is angularly misaligned with the bore (e.g., such that the optical-axis of the light source is not parallel to the bore-axis of the grid receptacle), such angular alignment will cause the first and second illuminated spots to be not concentric. Accordingly, the concentricity or lack thereof of the first and second illuminated spots can be considered as an indicator of the angular alignment or lack thereof between the robotic gripper and the bore of the grid receptacle.

In various instances, because the dimensions of, properties of, and distances between the robotic gripper, the grid receptacle, the light source, the beamsplitter, the reflector, and the camera can be known or otherwise controlled, any suitable kinematic functions or relationships can be derived that quantify how the first and second illuminated spots move (e.g., two-dimensionally in pixel space), in response to changes in angular orientation (e.g., pitch or yaw in real-world physical space) of the robotic gripper. Thus, when given the centroids of the first and second illuminated spots, such kinematic functions or relationships can be leveraged to identify what specific angular orientation of the robotic gripper would cause those centroids to become concentric or to otherwise move closer together. In this way, the robotic gripper can be taught angular alignment in mere minutes, as opposed to the hours' worth or days' worth of tedious trial-and-error required by existing techniques.

If the first and second illuminated spots are not overlapping (e.g., as determined by any suitable object detection computer vision algorithm), then their centroids can be identified by averaging the intra-image locations of their respective pixels. If the first and second illuminated spots are overlapping, then their centroids can instead be identified by circumscribing a least-area contour around both the first and second illuminated spots and using that contour's fitted dimensions to estimate the centroids. The present inventors found that kinematic formulas work well when the centroids of the first and second illuminated spots are farther apart from each other and work less well as the centroids get closer together. Accordingly, if the centroids as identified in such contour-based fashion are less than a threshold distance a part, angular alignment can be not achieved via kinematic formulas. Instead, the robotic gripper can be swept through a range of nearby angular orientations, and whichever one causes the fitted contour to have a smallest area can be treated as achieving angular alignment.

In some cases, such illuminated spots can even be leveraged for teaching the robotic gripper how to become translationally aligned with the bore of the grid receptacle. Indeed, the reflectance of the reflector can vary spatially, such that the center of the reflector, and thus the center of the bore, is associated with a maximum or otherwise unique reflectance. So, if the second illuminated spot's intensity corresponds to (e.g., matches, is commensurate with) that maximum or otherwise unique reflectance value, then the robotic gripper can be considered as being translationally aligned with the bore. Instead, if the second illuminated spot's intensity does not correspond to (e.g., does not match, is not commensurate with) that maximum or otherwise unique reflectance value, then the robotic gripper can be considered as being translationally misaligned with the bore. In such cases, the robotic gripper can be swept through a range of nearby translational positions, and whichever one causes the second illuminated spot's intensity to correspond to the maximum or otherwise unique reflectance value of the reflector can be considered as achieving translational alignment.

In this way, various embodiments described herein can be considered as innovative techniques that efficiently and efficaciously teach the robotic gripper how to become angularly or translationally aligned with the bore of the grid receptacle. Various experiments performed by the present inventors verified that such embodiments were able to achieve angular alignment in mere minutes to less than one arcsecond per pixel resolution. That can be considered as higher or better resolution than can be achieved by existing eyeballing techniques, even after such existing eyeballing techniques consume hours' or days' worth of iteration. Additionally, such experiments involved a light source, a collimator lens, and a beamsplitter coupled together by a mounting bracket, all of which collectively weighed less than 2 grams. This demonstrates that various embodiments described herein can eliminate the excess deflection concerns that plague some existing eyeballing techniques. For at least the above reasons, various embodiments described herein can be considered as addressing or ameliorating various problems or disadvantages that afflict existing techniques. Therefore, various embodiments described herein can be considered as a concrete and tangible technical improvement in the field of charged-particle microscopy. Accordingly, various embodiments described herein certainly qualify as useful and practical applications of computers.

Furthermore, it should be appreciated that various embodiments described herein can control real-world, tangible devices. Indeed, various embodiments can involve adjusting the angular or translational positions of real-world robotic grippers that are deployed within real-world charged-particle microscopes.

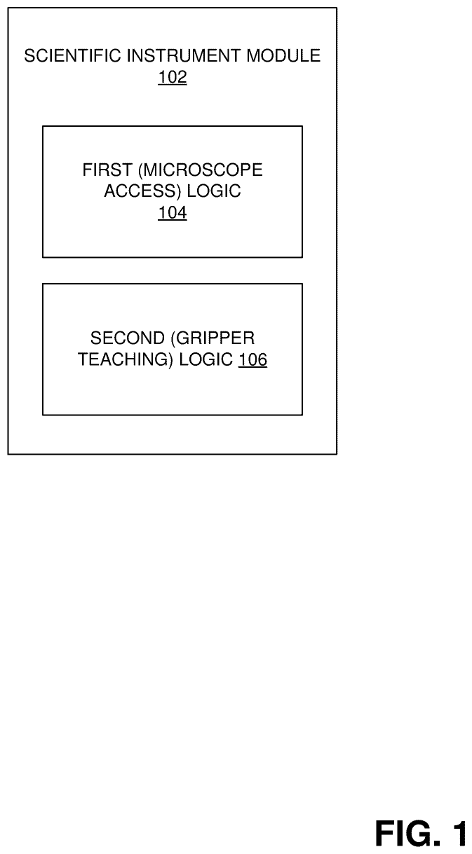

FIG. 1 illustrates an example, non-limiting block diagram of a scientific instrument module 102 in accordance with various embodiments described herein.

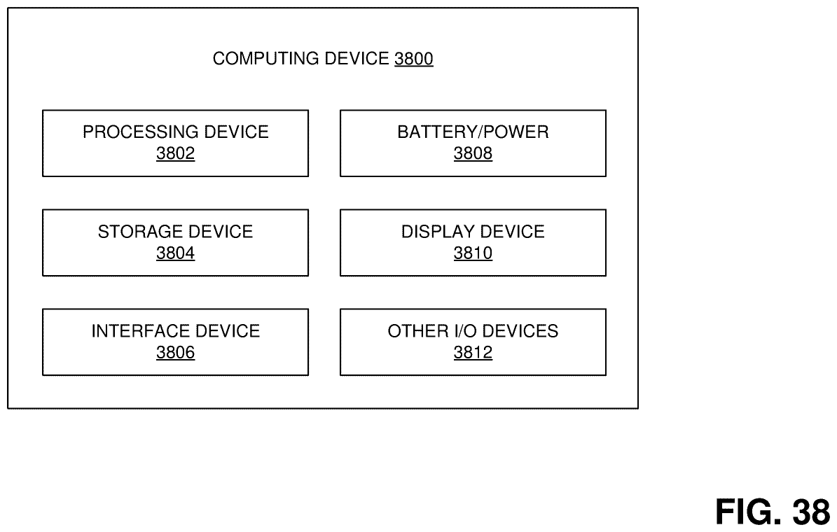

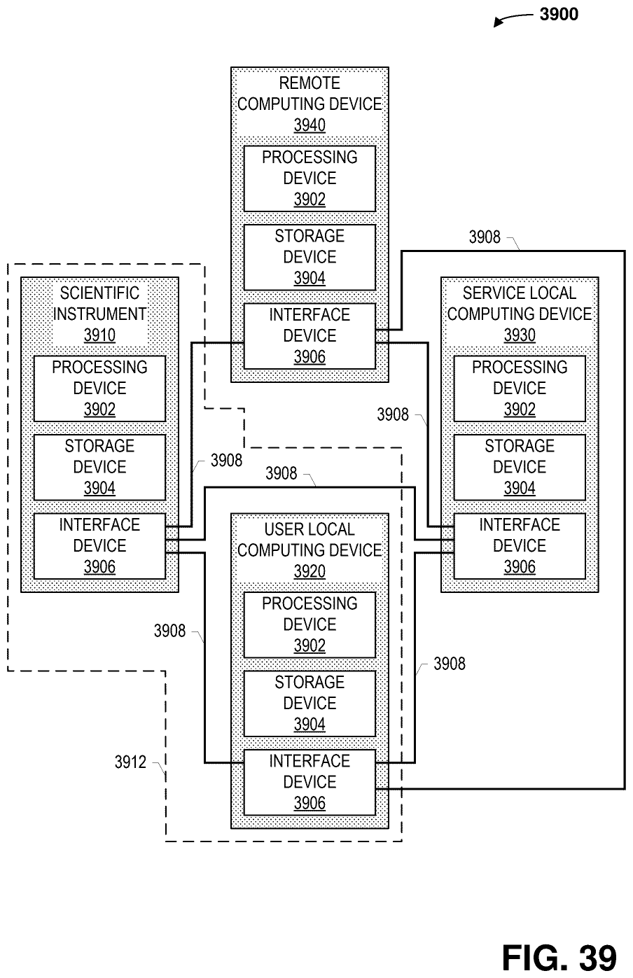

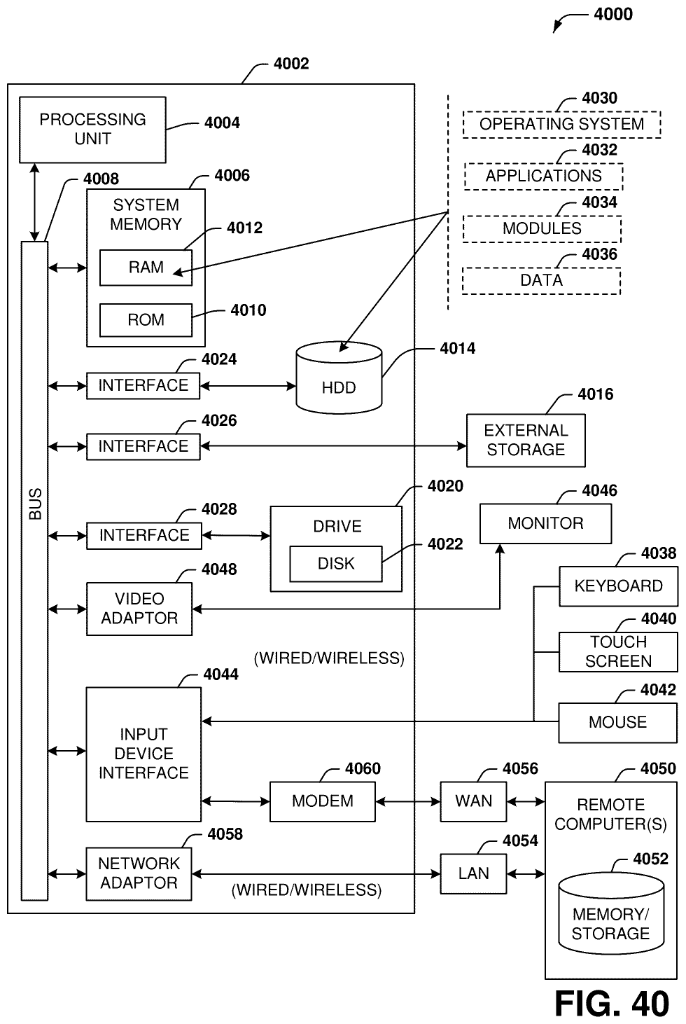

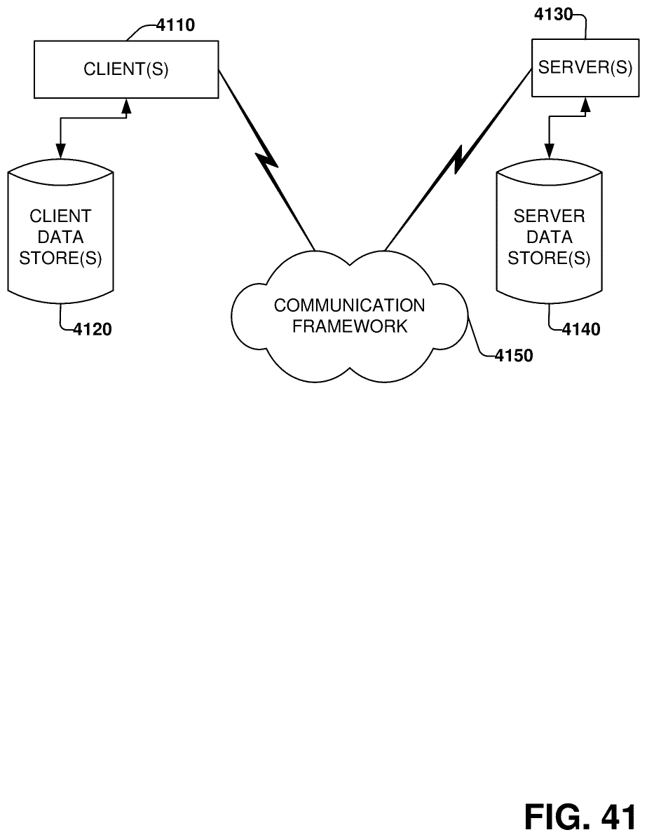

In various embodiments, the scientific instrument module 102 can be implemented by circuitry (e.g., including electrical or optical components), such as a programmed computing device. Logic of the scientific instrument module 102 can be included in a single computing device or can be distributed across multiple computing devices that are in communication with each other as appropriate. Examples of computing devices that may, singly or in combination, implement the scientific instrument module 102 are discussed herein with reference to FIGS. 38 and 40, and examples of systems or networks of interconnected computing devices, in which the scientific instrument module 102 may be implemented across one or more of the computing devices, are discussed herein with reference to FIGS. 39 and 41.

The scientific instrument module 102 can include first logic 104 and second logic 106. As used herein, the term “logic” can include an apparatus that is to perform a set of operations associated with the logic. For example, any of the logic elements included in the scientific instrument module 102 can be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module can omit one or more of the logic elements depicted in the associated drawings; for example, a module may include a subset of the logic elements depicted in the associated drawings when that module is to perform a subset of the operations discussed herein with reference to that module.

In various embodiments, there can be a scientific instrument corresponding to the scientific instrument module 102. In various aspects, the scientific instrument can be any suitable computerized device that can electronically measure some scientifically-relevant, clinically-relevant, or research-relevant characteristic, property, or attribute of an analytical specimen (e.g., of a known or unknown mixture, compound, or collection of matter). As a non-limiting example, a scientific instrument can be a scanning electron microscope. In such case, the scientific instrument can capture images of the analytical specimen, so as to measure or determine a surface topography, a surface material composition, or a crystallographic structure of the analytical specimen. As another non-limiting example, a scientific instrument can be a transmission electron microscope. In such case, the scientific instrument can capture images of the interior of the analytical specimen, so as to measure or determine interior structural details of the analytical specimen. As even another non-limiting example, a scientific instrument can be a dual beam microscope. In such case, the scientific instrument can capture images of the analytical specimen in addition to being able to mill the analytical specimen. As a more general non-limiting example, a scientific instrument can be any suitable type of charged-particle microscope (e.g., some types of microscopes can use beams of non-electron ions to capture images). In various instances, the scientific instrument can contain or otherwise have a vacuum chamber inside of which a robotic gripper and a grid receptacle can be deployed.

In various embodiments, the first logic 104 can involve accessing the scientific instrument. Accordingly, electronic instructions or commands can be transmitted to or from the scientific instrument.

In various embodiments, the second logic 106 can involve teaching the robotic gripper of the scientific instrument how to angularly or translationally align its shaft-axis with a bore-axis of the grid receptacle, based on a light source coupled to the robotic gripper. More specifically, the light source can shine a light beam through a beamsplitter that is also coupled to the robotic gripper. The beamsplitter can direct a first portion of the light beam toward a camera associated with the vacuum chamber, and the beamsplitter can direct a second portion of the light beam toward a reflector that is positioned within a bore of the grid receptacle. The reflector can reflect the second portion of the light beam back toward the beamsplitter, and the beamsplitter can direct at least some of the second portion of the light beam toward the camera. So, the camera can capture an image that depicts two illuminated spots: a first illuminated spot caused by the first portion of the light beam; and a second illuminated spot caused by the at least some of the second portion of the light beam. In various aspects, whether or not the first and second spots are concentric can be considered as indicating whether or not the shaft-axis of the robotic gripper is angularly aligned with the bore-axis of the grid receptacle. In various instances, when given the current centroids of the first and second illuminated spots, the second logic 106 can involve determining, via any suitable pixel-to-physical kinematic transformations, an angular position of the robotic gripper that would cause the first and second centroids to become concentric or otherwise move closer together. Thus, the robotic gripper can be taught to become angularly aligned with the grid receptacle without eyeballing trial and error. If the first and second spots are not overlapping, the second logic 106 can identify the centroids by respectively averaging the pixel positions of the first and second illuminated spots. If the first and second spots are overlapping, the second logic 106 can instead identify the centroids by fitting a contour around the first and second illuminated spots and geometrically estimating the centroids based on the fitted dimensions of the contour. In some cases, if the centroids are less than a threshold distance apart, the second logic 106 can refrain from utilizing the pixel-to-physical kinematic transformations to identify the angular position of the robotic gripper that would cause the first and second centroids to become concentric or otherwise move closer together. Instead, if the centroids are less than a threshold distance apart, the second logic 106 can sweep the robotic gripper through a range of angular positions within a threshold proximity of its current angular position, and whichever swept angular position minimizes the area of the contour can be considered as achieving angular alignment.

Accordingly, the scientific instrument module 102 can facilitate teaching of charged-particle microscopy robotic grippers via beamsplitting.

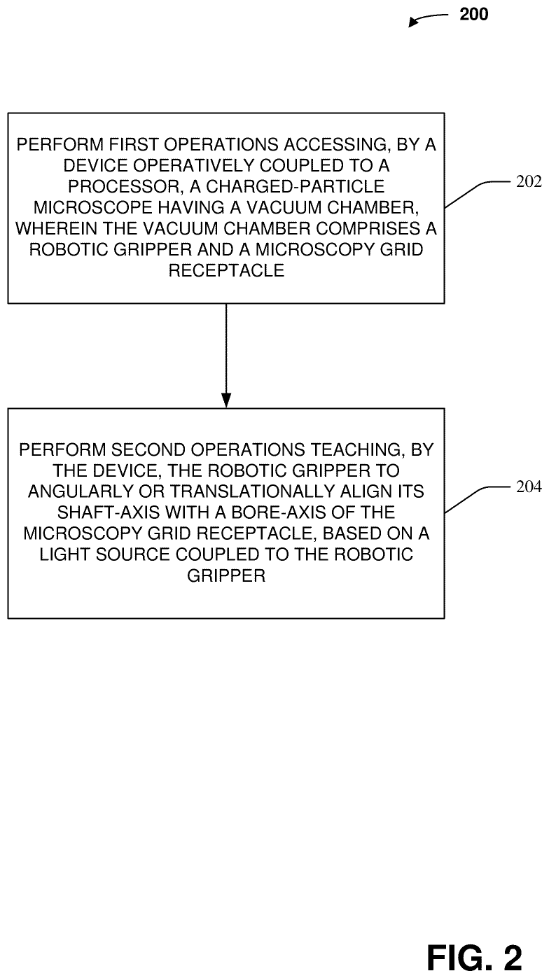

FIG. 2 is an example, non-limiting flow diagram of a computer-implemented method 200 in accordance with various embodiments described herein. The operations of the computer-implemented method 200 may be used in any suitable context to perform any suitable operations (e.g., can be performed by or used in conjunction with any of the various modules, computing devices, or graphical user interfaces described with respect to of FIGS. 1, 37, 38, 39, 40, and 41). Operations are illustrated once each and in a particular order in FIG. 2, but the operations may be reordered or repeated as desired and appropriate (e.g., different operations performed may be performed in parallel, as suitable).

In various aspects, act 202 can include performing first operations accessing, by a device operatively coupled to a processor, a charged-particle microscope having a vacuum chamber, wherein the vacuum chamber can comprise a robotic gripper and a microscopy grid receptacle. In various cases, the first logic 104 can perform or otherwise facilitate act 202.

In various aspects, act 204 can include performing second operations teaching, by the device, the robotic gripper to angularly or translationally align its shaft-axis with a bore-axis of the microscopy grid receptacle, based on a light source coupled to the robotic gripper. In various instances, the second logic 106 can perform or otherwise facilitate act 204.

Accordingly, the computer-implemented method 200 can facilitate teaching of charged-particle microscopy robotic grippers via beamsplitting.

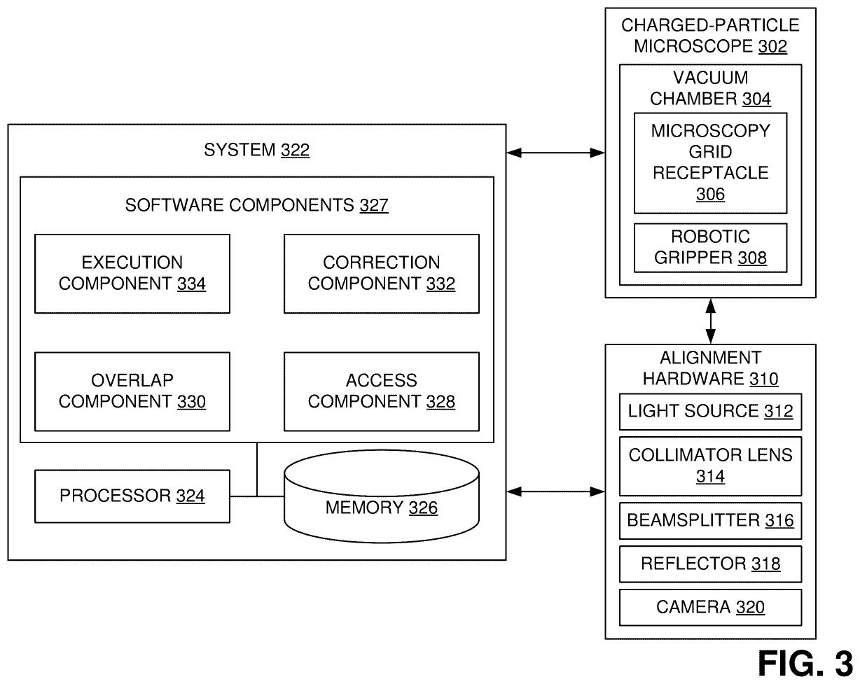

FIG. 3 illustrates a block diagram of an example, non-limiting system that can facilitate teaching of charged-particle microscopy robotic grippers via beamsplitting in accordance with one or more embodiments described herein.

In various embodiments, there can be a charged-particle microscope 302. In various aspects, the charged-particle microscope 302 can be as described above. That is, the charged-particle microscope 302 can be any suitable computerized device that can leverage its constituent hardware (e.g., electron sources, anodes, condenser lenses, condenser apertures, scan coils, objective lenses, objective apertures, deflectors, condensers, stigmators, electron detectors, X-ray detectors, actuatable specimen stages) to electronically capture any suitable image of any suitable analytical specimen. As a non-limiting example, the charged-particle microscope 302 can be any suitable SEM. As another non-limiting example, the charged-particle microscope 302 can be any suitable TEM. As yet another non-limiting example, the charged-particle microscope 302 can be any suitable dual-beam microscope.

Although not explicitly shown in the figures, the charged-particle microscope 302 can be electronically integrated with any suitable human-computer interface device, which can be remote from or local to the charged-particle microscope 302. Accordingly, a user or technician associated with the charged-particle microscope 302 can interact with or otherwise control the charged-particle microscope 302. Some non-limiting examples of the human-computer interface device can be a keyboard of the charged-particle microscope 302, a keypad of the charged-particle microscope 302, a touchscreen of the charged-particle microscope 302, or a voice-command system of the charged-particle microscope 302.

In any case, the charged-particle microscope 302 can comprise a vacuum chamber 304. In various aspects, the vacuum chamber 304 can be any suitable type of structural shell or enclosure having any suitable size or shape, being made up of any suitable materials (e.g., stainless steel, titanium), and having an interior volume that can be vacated or evacuated of air or other gases to any suitable vacuum pressure via any suitable vacuum pumps. Indeed, when it is desired for the charged-particle microscope 302 to scan any given specimen, such scanning can be performed under vacuum within the vacuum chamber 304. After all, if such scanning were not performed under vacuum, whatever charged-particle beam that the charged-particle microscope 302 were to use for such scanning would experience instability or interference due to collisions with gas molecules.

In various embodiments, a microscopy grid receptacle 306 and a robotic gripper 308 can be implemented or deployed within the vacuum chamber 304.

In various instances, the microscopy grid receptacle 306 can be any suitable structure having any suitable size or shape, being made up of any suitable materials (e.g., stainless steel, titanium, aluminum), and being configured to physically hold or support any suitable number of microscopy grids. In various cases, a microscopy grid can be any suitable partitioned or non-partitioned plate, dish, or slab on which any suitable specimen can be placed or set for purposes of carrying, transportation, or conveyance. Non-limiting examples of a microscopy grid can include: a copper grid; a gold grid; a quantifoil grid; a carbon grid; a silicon nitride grid; a mesh grid; a holey grid; or a support film.

In various aspects, the robotic gripper 308 can be any suitable automated end-effector that can controllably move through three-dimensional space. In particular, the robotic gripper 308 can be any suitable automated hand, automated clamp, automated claw, automated hook, or automated suction-cup affixed to any suitable articulating or telescoping arm that has any suitable number and any suitable types of kinematic degrees of freedom. In various cases, the robotic gripper 308 can be made up of any suitable types of linear or rotational actuators, such as: electric, electronic, or piezoelectric linear or rotational actuators (e.g., servo motors); pneumatic linear or rotational actuators; or hydraulic linear or rotational actuators. Prior to a microscopy scan, the robotic gripper 308 can physically grab a given microscopy grid from the microscopy grid receptacle 306, can angularly or translationally transport that given microscopy grid to an actuatable stage (not shown) within the vacuum chamber 304, and can then release its grip, thereby placing or setting the given microscopy grid onto the actuatable stage in preparation for the microscopy scan. Conversely, after the microscopy scan, the robotic gripper 308 can physically grab the given microscopy grid receptacle from the surface of the actuatable stage, can angularly or translationally transport the given microscopy grid back to the microscopy grid receptacle 306, and can then release grip, thereby replacing or resetting the given microscopy grid onto or into the microscopy grid receptacle 306.

In particular, a microscopy grid (or any suitable accessory hardware that can be coupled to the microscopy grid) can comprise a protruding shaft. In various aspects, such shaft can be configured to mate with a respective bore of the microscopy grid receptacle 306. In other words, such shaft can be insertable into the bore of the microscopy grid receptacle 306. When the shaft is inserted into the bore of the microscopy grid receptacle 306, the microscopy grid can be considered as being slidably or removably coupled to the microscopy grid receptacle 306. Accordingly, the microscopy grid receptacle 306 can, in some cases, be considered as a structural rack, stand, or other fixture on which or from which microscopy grids can be pegged or hung via such shaft-to-bore insertion.

In order to avoid damage to the charged-particle microscope 302, and in order to avoid damage to or contamination of any specimens that are to be scanned by the charged-particle microscope 302, it can be desired to teach the robotic gripper 308 how to angularly or translationally align a shaft protruding from any given microscopy grid with the bore of the microscopy grid receptacle 306. As described herein, a system 322 can facilitate such teaching, by leveraging various alignment hardware 310.

In various embodiments, the alignment hardware 310 can comprise a light source 312, a collimator lens 314, a beamsplitter 316, a reflector 318, or a camera 320.

In various aspects, the light source 312 can be any suitable optical device whose mass can be less than or otherwise within any suitable threshold margin of 1 gram, and that can emit a focused beam of light of any suitable wavelength. As a non-limiting example, the light source 312 can be any suitable micro-spot-size LED fabricated or manufactured on a few square millimeters or centimeters of printed circuit board. As another non-limiting example, the light source 312 can be a micro laser.

In various instances, the collimator lens 314 can be any suitable optical device whose mass can be less than or otherwise within any suitable threshold margin of 1 gram, and that can cause incident light rays to become parallel or collimated with each other. As a non-limiting example, the collimator lens 314 can be any suitable plano-convex lens. As another non-limiting example, the collimator lens 314 can be any suitable double-convex lens. As even another non-limiting example, the collimator lens 314 can be any suitable meniscus lens. As yet another non-limiting example, the collimator lens 314 can be any suitable aspheric lens. As still another non-limiting example, the collimator lens 314 can be any suitable cylindrical lens. As another non-limiting example, the collimator lens 314 can be any suitable Fresnel lens.

In various cases, the beamsplitter 316 can be any suitable optical device whose mass can be less than or otherwise within any suitable threshold margin of 1 gram, and that can transmit some portion of incident light while reflecting a remainder of such incident light. As a non-limiting example, the beamsplitter 316 can be a cubic prism beamsplitter. As another non-limiting example, the beamsplitter 316 can be a plate beamsplitter. It should be appreciated that the beamsplitter 316 can utilize or implement any suitable types of beamsplitting coatings. As a non-limiting example, the beamsplitter 316 can utilize any suitable dielectric beamsplitting coatings. As another non-limiting example, the beamsplitter 316 can utilize any suitable metallic beamsplitting coatings.

In various aspects, the reflector 318 can be any suitable optical device that can reflect incident light. As a non-limiting example, the reflector 318 can be any suitable flat dielectric mirror. As another non-limiting example, the reflector 318 can be any suitable flat metallic mirror. As even another non-limiting example, the reflector 318 can be any suitable flat acrylic mirror. It should be appreciated that, in some cases, the reflector 318 can have a non-zero transmittance.

In various instances, the camera 320 can be any suitable optical device that can capture or generate images in response to incident light. As a non-limiting example, the camera 320 can be any suitable charge-coupled device (CCD) camera. As another non-limiting example, the camera 320 can be any suitable complementary metal-oxide-semiconductor (CMOS) camera. In various cases, the camera 320 can be set to infinity focus (e.g., can be set to a focal length that approaches or approximates infinity). Such infinity focus can be considered as causing the camera 320 to be more sensitive to angular changes of incident light than to translational changes of incident light. Indeed, the image plane of a camera can be considered as being located at the focal length of the camera. When the focal length of a camera lens is set to infinity, two translationally-offset light beams that pass through the camera lens can be considered as striking a coincident point on the image plane, if those two translationally-offset light beams are parallel to each other prior to passing through the camera lens. Now, if those translationally-offset light beams are instead not parallel to each other prior to passing through the camera lens, they can instead strike different or separate points on the image plane. Furthermore, those different or separate points can: vary or change with the angle of incidence between those non-parallel, translationally-offset light beams; and not vary or change with changes in the translational offset between those two light beams. Thus, by setting the camera 320 to infinity focus, the camera 320 can be considered as being sensitive to changes in incidence angle of incoming light and as not being sensitive to translational changes in such incoming light.

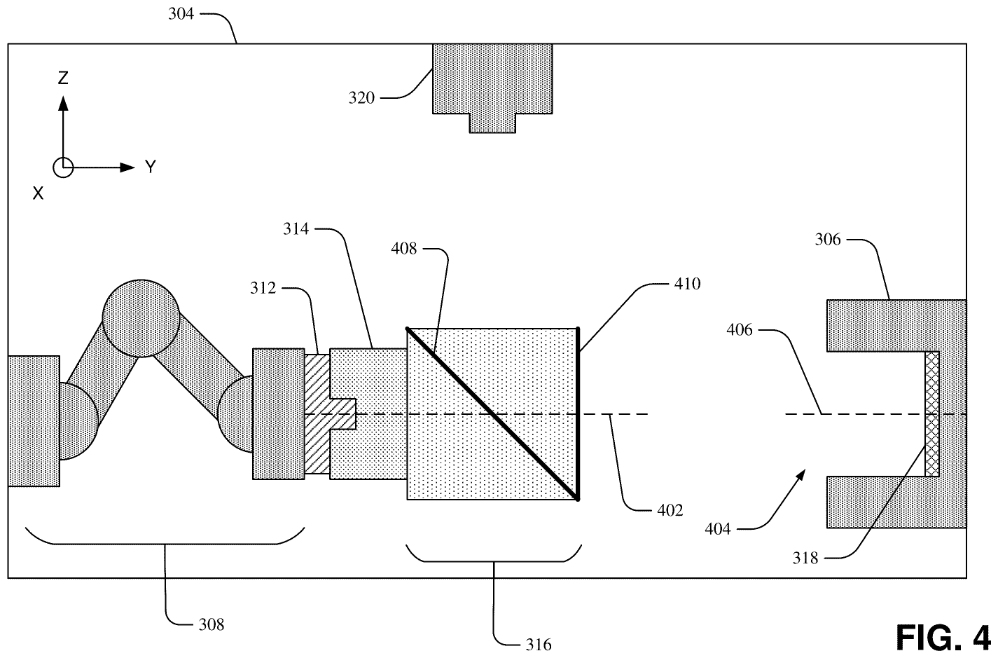

In various embodiments, the robotic gripper 308 and the microscopy grid receptacle 306 can be outfitted or equipped with the alignment hardware 310. Indeed, in various aspects, the light source 312, the collimator lens 314, and the beamsplitter 316 can be coupled to or otherwise held by the robotic gripper 308. In various instances, the reflector 318 can be located in or on the bore of the microscopy grid receptacle 306. In various cases, the camera 320 can be located in or near the vacuum chamber 304, so as to be able to see or capture light that is reflected from the beamsplitter 316. Non-limiting aspects are described with respect to FIGS. 4-12.

FIGS. 4-12 illustrate example, non-limiting block diagrams showing how the robotic gripper 308 and the microscopy grid receptacle 306 can be outfitted or equipped with the alignment hardware 310 in accordance with one or more embodiments described herein. It should be appreciated that FIGS. 4-12 are not necessarily drawn to scale.

First, consider FIG. 4. In various embodiments, the microscopy grid receptacle 306 and the robotic gripper 308 can be affixed in any suitable fashions (e.g., via bolts, screws, or any other suitable mechanical fasteners) to any suitable interior walls or surfaces of the vacuum chamber 304, such that the microscopy grid receptacle 306 is within reach of the robotic gripper 308. It should be appreciated that FIG. 4 shows mere conceptual depictions of the robotic gripper 308 and of the microscopy grid receptacle 306 for ease of illustration. Indeed, although FIG. 4 crudely shows the robotic gripper 308 as being a three-joint articulating arm, it should be understood that the robotic gripper 308 can exhibit any suitable level of mechanical complexity and can, as mentioned above, have any suitable degrees of kinematic freedom. Indeed, the robotic gripper 308 can be able to move its end-effector in three translational directions (e.g., X-direction, Y-direction, and Z-direction of FIG. 4) and in three angular directions (e.g., pitch direction, which can be considered as pivoting or rotating about the X-direction of FIG. 4; yaw direction, which can be considered as pivoting or rotating about the Z-direction of FIG. 4; and roll direction, which can be considered as pivoting or rotating about the Y-direction of FIG. 4). Likewise, although FIG. 4 crudely shows the microscopy grid receptacle 306 as being a mere rectilinear block, it should be understood that the microscopy grid receptacle 306 can be any suitable static or stationary structure (or, in some cases, even a dynamic or movable structure) of any suitable shape or size and exhibiting any suitable level of structural complexity.

In any case, the robotic gripper 308 can be considered as having a shaft-axis 402. In various aspects, the shaft-axis 402 can be whatever linear axis that would run longitudinally through the center of a shaft protruding from a microscopy grid, if the robotic gripper 308 were holding that microscopy grid. Indeed, the robotic gripper 308 can be configured or designed to hold microscopy grids in a uniform or otherwise repeatable way, and whichever direction that the shafts of those microscopy grids run due to such uniform or repeatable gripping can be referred to as the shaft-axis 402.

In various aspects, the microscopy grid receptacle 306 can comprise a bore 404. In various instances, the bore 404 can be configured or sized so as to receive a shaft protruding from a microscopy grid. In various cases, the bore 404 can be considered as having a bore-axis 406. In various aspects, the bore-axis 406 can whatever linear axis that runs longitudinally through the center of the bore 404.

In various instances, teaching the robotic gripper 308 how to become angularly or translationally aligned with the bore 404 of the microscopy grid receptacle 306 can be considered as equivalent to identifying what specific angular or translational positions of the robotic gripper 308 would cause the shaft-axis 402 to become parallel or colinear with the bore-axis 406.

Now, in various cases, the light source 312, the collimator lens 314, and the beamsplitter 316 can all be coupled (e.g., via any suitable mechanical fasteners) to or otherwise held by the robotic gripper 308. As a non-limiting example, there can be any suitable mounting bracket (not shown) to which all three of the light source 312, the collimator lens 314, and the beamsplitter 316 can be mechanically affixed or mounted, and the robotic gripper 308 can grasp, grip, or otherwise hold onto the mounting bracket. Note that, because the light source 312, the collimator lens 314, and the beamsplitter 316 (as well as the mounting bracket, as appropriate) can respectively weigh less than or otherwise within any suitable margin of one gram, they can collectively be considered as not causing the robotic gripper 308 to experience significantly more positional deflection than the robotic gripper 308 would experience from holding a microscopy grid.

In any case, the light source 312 and the collimator lens 314 can be coupled to or held by the robotic gripper 308 such that the shaft-axis 402 can be considered as being an optical-axis of the light source 312. In other words, light beams that are emitted by the light source 312 and collimated by the collimator lens 314 can be considered as traveling along or parallel to the shaft-axis 402.

In various aspects, the beamsplitter 316 can be coupled to or held by the robotic gripper 308, such that the beamsplitter 316 can receive light beams that have been emitted by the light source 312 and collimated by the collimator lens 314. In other words, the collimator lens 314 can be located in between the light source 312 and the beamsplitter 316.

As shown, the beamsplitter 316 can, in various instances, be a cubic prism having two distinct beamsplitting coatings: a beamsplitting coating 408; and a beamsplitting coating 410. In various cases, the beamsplitting coating 408 can exhibit any suitable material composition (e.g., dielectric, metallic) and any suitable reflectance-to-transmittance ratio (e.g., a 50/50 ratio; a 60/40 ratio). Likewise, the beamsplitting coating 410 can exhibit any suitable material composition and any suitable reflectance-to-transmittance ratio, which may be the same as or different than the size or ratio of the beamsplitting coating 408. In various aspects, as shown, the beamsplitting coating 408 can be located, positioned, or otherwise implemented on or along an interior diagonal plane of the beamsplitter 316. In contrast, and as shown, the beamsplitting coating 410 can be located, positioned, or otherwise implemented on or along whichever external surface of the beamsplitter 316 that faces towards the microscopy grid receptacle 306. Accordingly, the beamsplitting coating 410 can be considered as being orthogonal or perpendicular to the shaft-axis 402, and the beamsplitting coating 408 can be considered as making a 45-degree angle with the beamsplitting coating 410. Although not explicitly shown, any other external surfaces of the beamsplitter 316 can have any suitable anti-reflective coatings.

In various aspects, as shown, the reflector 318 can be coupled (e.g., via any suitable mechanical fasteners) to the inside of the bore 404, such that the reflector 318 can be considered as being perpendicular or orthogonal to the bore-axis 406. Indeed, in the non-limiting example of FIG. 4, the reflector 318 can be considered as being affixed to a bottom surface of the bore 404. However, this is a mere non-limiting example. In other embodiments, the reflector 318 can instead be mechanically positioned or suspended at any other depth within the bore 404, or can even be mechanically positioned or suspended outside of the bore 404, such that the reflector 318 is perpendicular or orthogonal to the bore-axis 406. In some instances, the reflector 318 can be considered as a temporary fixture on or in the bore 404 (e.g., the reflector 318 can be removed from the bore 404 when it is desired to use or operate the charged-particle microscope 302 for actual scanning of specimens). However, in other instances, the reflector 318 can be considered as a permanent fixture on or in the bore 404 (e.g., the reflector 318 can be not removable from the bore 404, such that the reflector 318 can stay inside the bore 404 even when it is desired to use or operate the charged-particle microscope 302 for actual scanning of specimens).

In various cases, as shown, the camera 320 can be coupled (e.g., via any suitable mechanical fasteners) to any suitable interior wall or surface of the vacuum chamber 304, such that the camera 320 faces toward the beamsplitter 316. However, this is a mere non-limiting example. In other embodiments, the camera 320 can instead be located or positioned outside of the vacuum chamber 304, but can nevertheless face toward the beamsplitter 316 due to any suitable window or viewport (not shown) of the vacuum chamber 304. In some aspects, the 45-degree angle formed between the beamsplitting coating 408 and the beamsplitting coating 410 can be considered as facing or opening toward the camera 320.

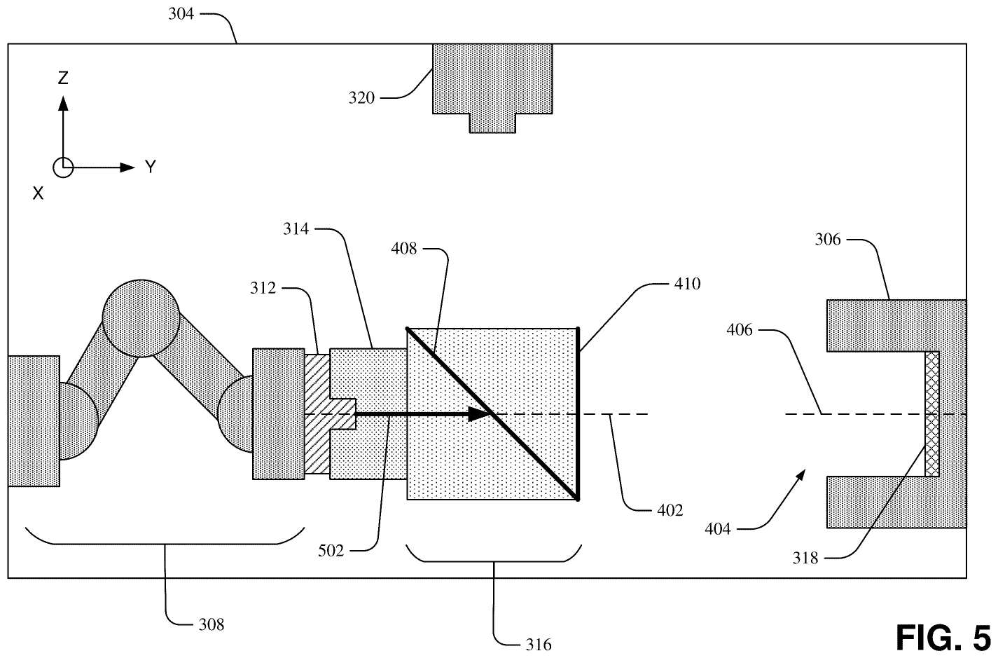

Now, consider FIG. 5. In various embodiments, as shown, the light source 312 can emit a light beam 502. The light beam 502 can pass through the collimator lens 314, which can cause the light beam 502 to travel along the shaft-axis 402. In various instances, the light beam 502 can exit the collimator lens 314 and can accordingly enter the beamsplitter 316. While propagating through the beamsplitter 316, the light beam 502 can reach, and thus interact with, the beamsplitting coating 408.

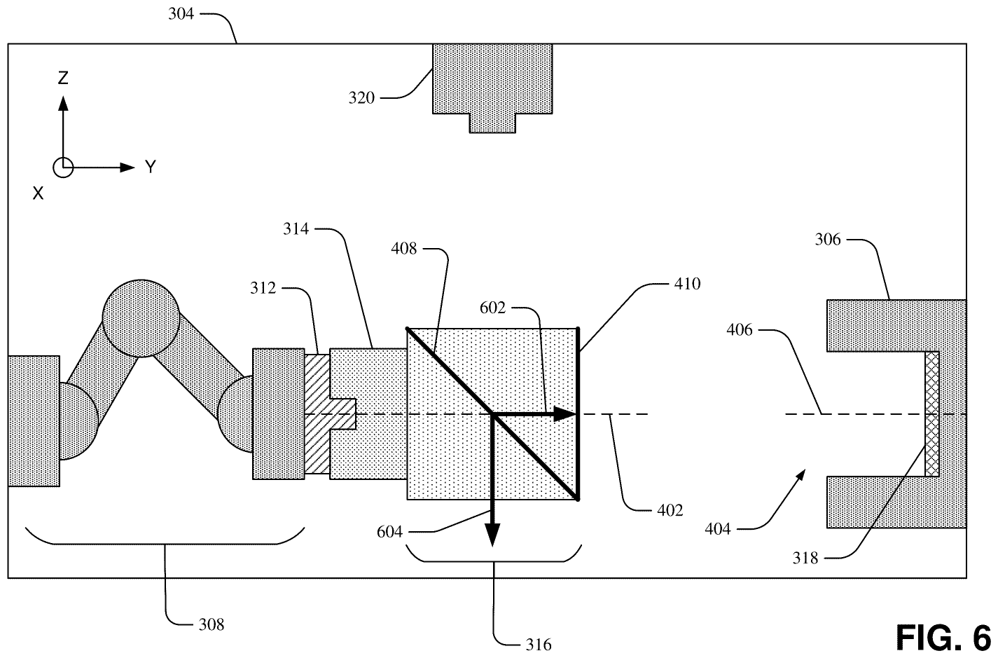

Consider FIG. 6. In various aspects, the beamsplitting coating 408 can (assuming lossless or zero-absorption conditions) cause some of the light beam 502 to pass (e.g., according to the transmittance value or property of the beamsplitting coating 408) and can cause a remainder of the light beam 502 to instead be reflected (e.g., according to the reflectance value or property of the beamsplitting coating 408). That portion of the light beam 502 that the beamsplitting coating 408 passes can be referred to as a light beam 602, whereas that portion of the light beam 502 that the beamsplitting coating 408 instead reflects can be referred to as a light beam 604. Given the 45-degree orientation of the beamsplitting coating 408 with respect to the shaft-axis 402, the light beam 604 can be considered as traveling or propagating perpendicularly or orthogonally to the shaft-axis 402 in a direction away from the camera 320. In contrast, the light beam 602 can be considered as traveling or propagating along the shaft-axis 402 in the same direction as the light beam 502. While propagating through the beamsplitter 316, the light beam 602 can reach, and thus interact with, the beamsplitting coating 410.

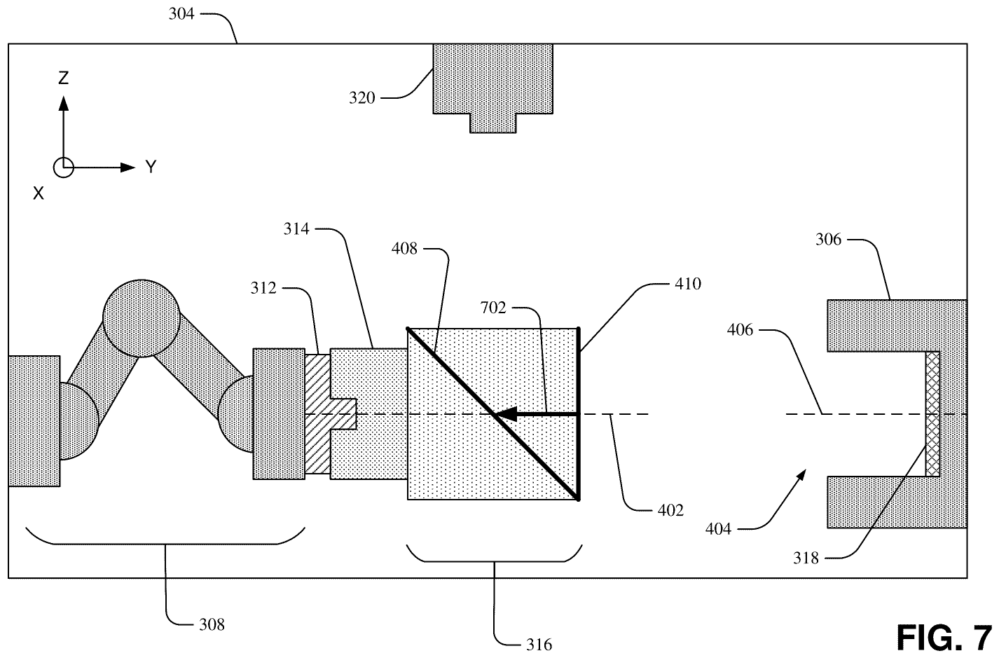

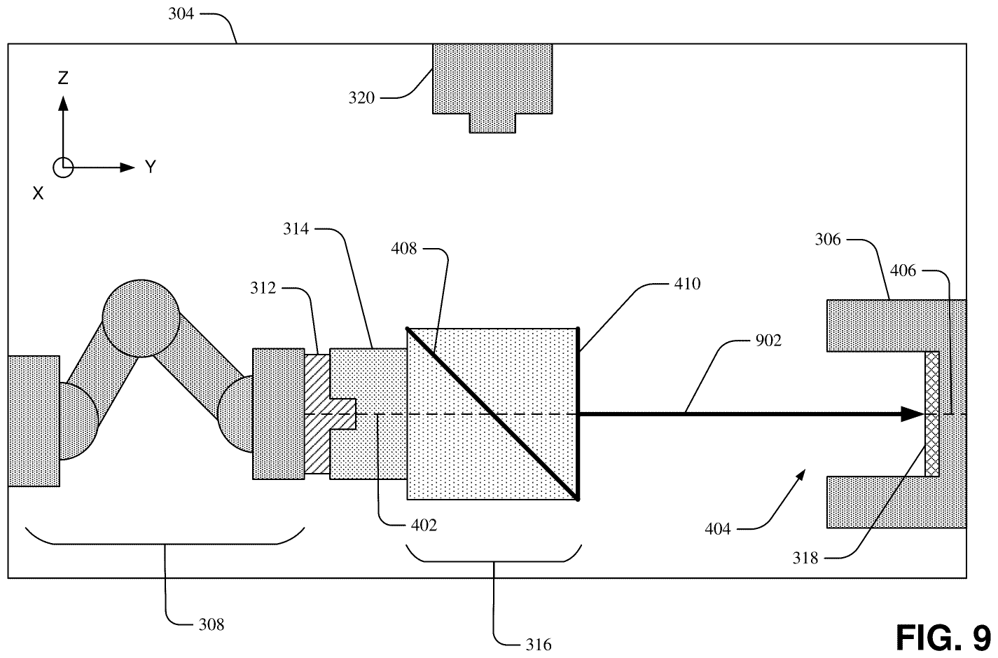

Consider FIG. 7. In various aspects, the beamsplitting coating 410 can (assuming lossless or zero-absorption conditions) cause some of the light beam 602 to pass (e.g., according to the transmittance value or property of the beamsplitting coating 410) and can cause a remainder of the light beam 602 to instead be reflected (e.g., according to the reflectance value or property of the beamsplitting coating 410). That portion of the light beam 602 that the beamsplitting coating 410 passes can be referred to as a light beam 902 (not discussed until FIG. 9), whereas that portion of the light beam 602 that the beamsplitting coating 410 instead reflects can be referred to as a light beam 702. Given the perpendicular or orthogonal orientation of the beamsplitting coating 410 with respect to the shaft-axis 402, the light beam 702 can be considered as traveling or propagating along the shaft-axis 402 in the opposite direction as the light beam 602. Thus, while propagating through the beamsplitter 316, the light beam 702 can reach, and thus interact with, the beamsplitting coating 408.

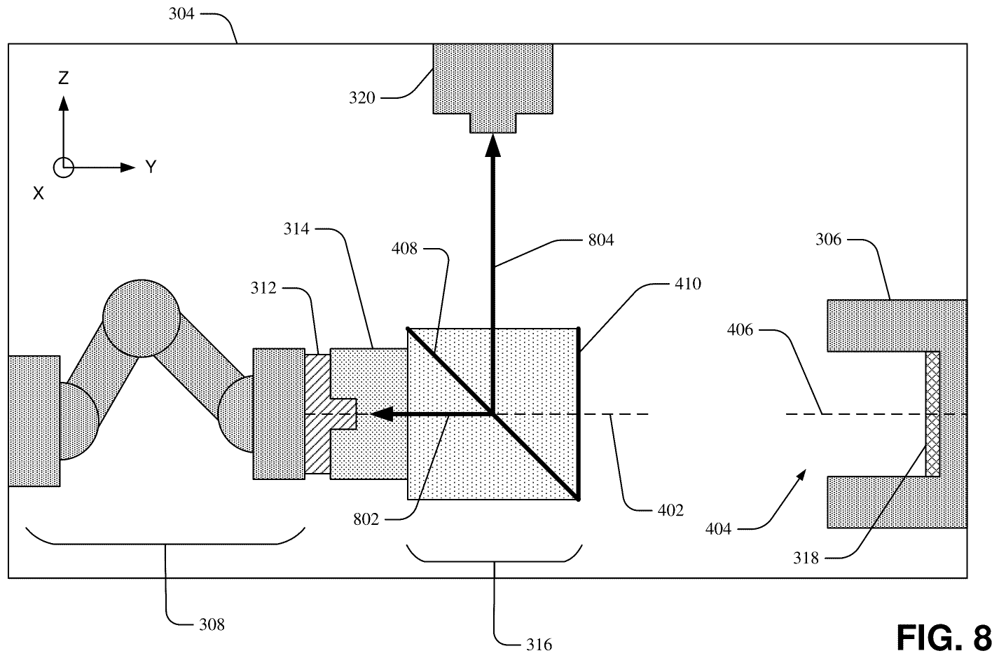

Consider FIG. 8. In various aspects, the beamsplitting coating 408 can cause some of the light beam 702 to pass and can cause a remainder of the light beam 702 to instead be reflected. That portion of the light beam 702 that the beamsplitting coating 408 passes can be referred to as a light beam 802, whereas that portion of the light beam 702 that the beamsplitting coating 408 instead reflects can be referred to as a light beam 804. Given the 45-degree orientation of the beamsplitting coating 408 with respect to the shaft-axis 402, the light beam 802 can be considered as traveling or propagating along the shaft-axis 402 toward the light source 312. In contrast, the light beam 804 can be considered as traveling or propagating perpendicularly or orthogonally to the shaft-axis 402 and toward the camera 320. Accordingly, the camera 320 can be considered as seeing, capturing, or otherwise viewing the light beam 804.

Now, consider FIG. 9. As mentioned above, the light beam 902 can be whatever portion of the light beam 602 that the beamsplitting coating 410 passes. Given the perpendicular or orthogonal orientation of the beamsplitting coating 410 with respect to the shaft-axis 402, the light beam 902 can be considered as traveling or propagating along the shaft-axis 402 in the same direction as the light beam 602. Note that, because the beamsplitting coating 410 can be applied to an external surface of the beamsplitter 316 that faces toward the bore 404 of the microscopy grid receptacle 306, the light beam 902 can be considered as propagating toward the bore 404 of the microscopy grid receptacle 306. Accordingly, while propagating, the light beam 902 can reach, and thus interact with, the reflector 318. Note that, if the robotic gripper 308 and the bore 404 are not yet aligned, the light beam 902 can be considered as not propagating along or parallel to the bore-axis 406 (e.g., the shaft-axis 402 might not yet been parallel to the Y-axis of FIG. 9). However, this lack of parallel propagation is not shown for ease of illustration.

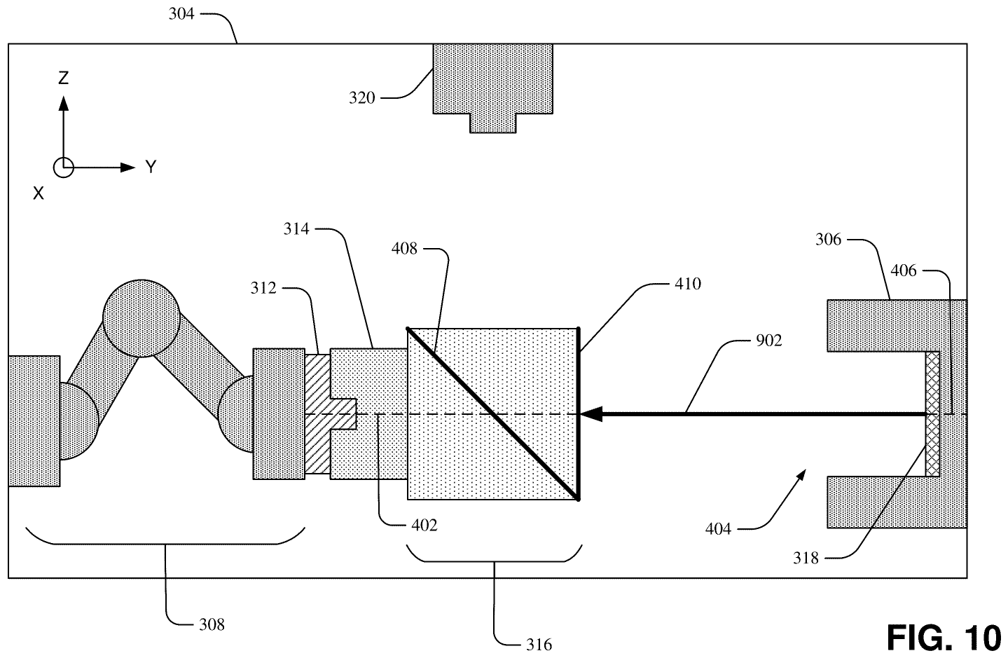

Consider FIG. 10. In various aspects, the reflector 318 can (assuming lossless, zero-absorption, and zero-transmittance conditions) cause the light beam 902 to be reflected. Accordingly, the light beam 902 can now be propagating back toward the beamsplitter 316. Note that, if the robotic gripper 308 and the bore 404 are not yet aligned, the light beam 902 can, after such reflection, be considered as propagating along or parallel to neither the bore-axis 406 nor the shaft-axis 402. However, this lack of parallel propagation is not shown for ease of illustration. In any case, while propagating, the light beam 902 can reach, and thus interact with, the beamsplitting coating 410.

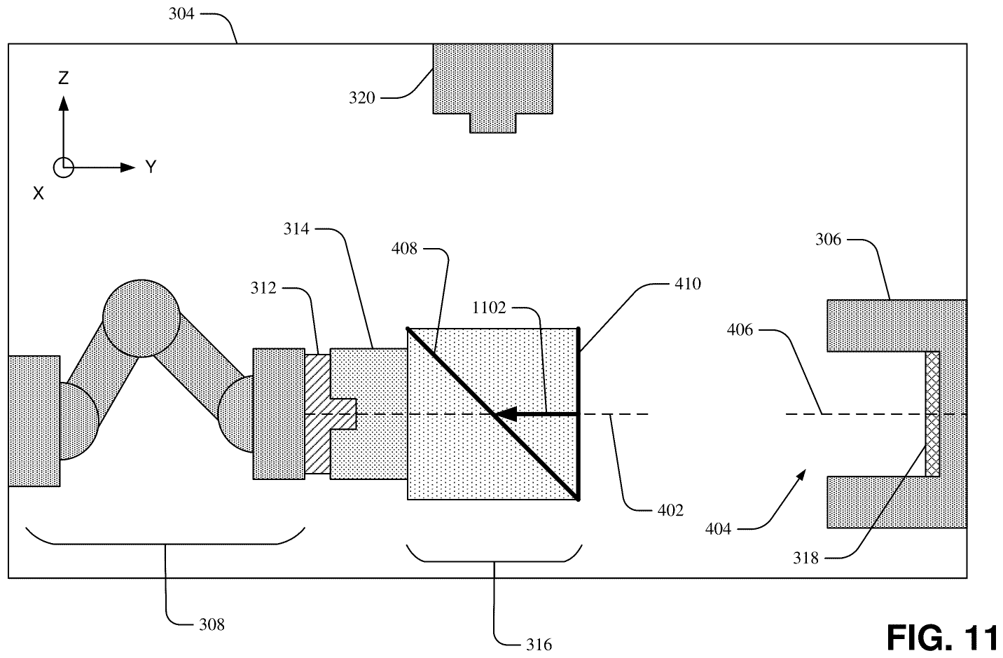

Consider FIG. 11. In various aspects, the beamsplitting coating 410 can cause some of the light beam 902 to pass and can cause a remainder of the light beam 902 to instead be reflected (e.g., back toward the bore 404). That portion of the light beam 902 that the beamsplitting coating 410 passes can be referred to as a light beam 1102. Note that, because the light beam 902 might not be propagating along or orthogonal to the shaft-axis 402, the light beam 1102 likewise might not be propagating along or parallel to the shaft-axis 402. In any case, while propagating through the beamsplitter 316, the light beam 1102 can reach, and thus interact with, the beamsplitting coating 408.

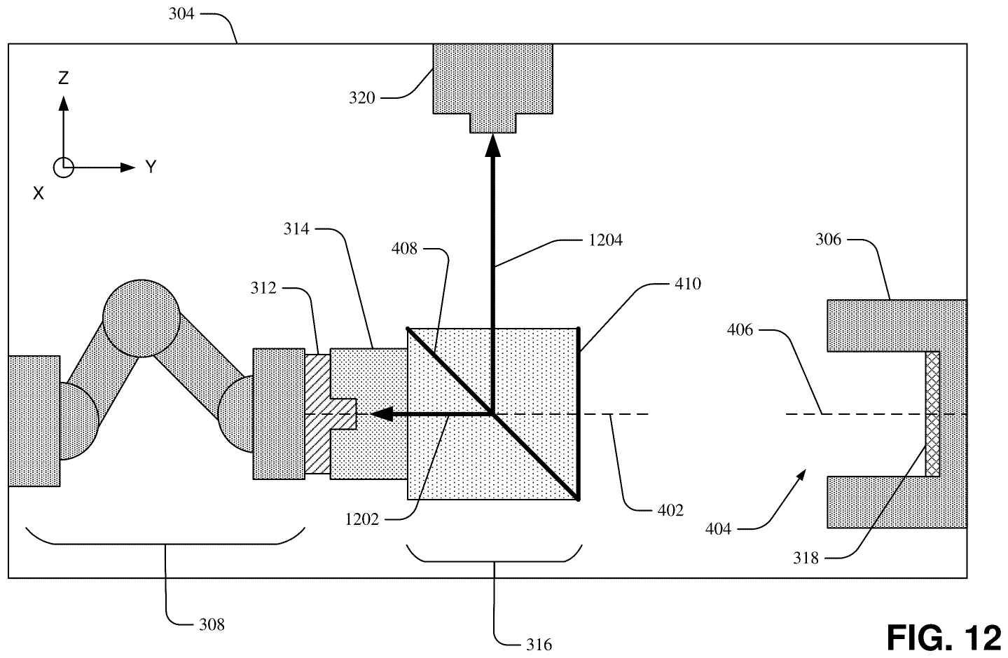

Consider FIG. 12. In various aspects, the beamsplitting coating 408 can cause some of the light beam 1102 to pass and can cause a remainder of the light beam 1102 to instead be reflected. That portion of the light beam 1102 that the beamsplitting coating 408 passes can be referred to as a light beam 1202, whereas that portion of the light beam 1102 that the beamsplitting coating 408 instead reflects can be referred to as a light beam 1204. Given the 45-degree orientation of the beamsplitting coating 408 with respect to the shaft-axis 402, the light beam 1202 can be considered as traveling or propagating toward the light source 312 (e.g., although the light beam 1202 might not be along or parallel to the shaft-axis 402). In contrast, the light beam 1204 can be considered as traveling or propagating toward the camera 320 (e.g., although the light beam 1204 might not be perpendicular or orthogonal to the shaft-axis 402). Accordingly, the camera 320 can be considered as seeing, capturing, or otherwise viewing the light beam 1204.

Referring back to FIG. 3, the system 322 can be electronically integrated, via any suitable wired or wireless electronic connections, with the charged-particle microscope 302 or with the alignment hardware 310. In various cases, the system 322 can electronically teach the robotic gripper 308 how to align the shaft-axis 402 with the bore-axis 406, by leveraging information captured by the camera 320.

In various aspects, the system 322 can comprise a processor 324 (e.g., computer processing unit, microprocessor) and a non-transitory computer-readable memory 326 that is operably or operatively or communicatively connected or coupled to the processor 324. The non-transitory computer-readable memory 326 can store computer-executable instructions which, upon execution by the processor 324, can cause the processor 324 or other components of the system 322 (e.g., access component 328, overlap component 330, correction component 332, execution component 334) to perform one or more acts. In various embodiments, the non-transitory computer-readable memory 326 can store computer-executable components (e.g., access component 328, overlap component 330, correction component 332, execution component 334), and the processor 324 can execute the computer-executable components.

In various embodiments, the system 322 can comprise an access component 328. In various aspects, the access component 328 can electronically access the charged-particle microscope 302 or the alignment hardware 310. That is, the access component 328 can electronically communicate or otherwise electronically interact with (e.g., transmit electronic instructions or commands to, receive electronic data from) the charged-particle microscope 302 (e.g., with the robotic gripper 308) or with the alignment hardware 310 (e.g., with the light source 312 or with the camera 320). Accordingly, the access component 328 can be considered as a proxy or conduit through which other components of the system 322 can interact with, communicate with, or otherwise manipulate the charged-particle microscope 302 or the alignment hardware 310. In various instances, the access component 328 can, as described herein, access an image that is captured by the camera 320. In various cases, that image can depict a first illuminated spot corresponding to the light beam 804 and a second illuminated spot corresponding to the light beam 1204.

In various embodiments, the system 322 can comprise an overlap component 330. In various aspects, the overlap component 330 can, as described herein, determine, via any suitable object detection algorithm, whether or not the first and second illuminated spots in the image are overlapping with each other.

In various embodiments, the system 322 can comprise a correction component 332. In various instances, the correction component 332 can, as described herein, identify an angular position of the robotic gripper 308 that would cause the shaft-axis 402 to become angularly aligned with the bore-axis 406, based on whether or not the first and second illuminated spots are overlapping.

In various embodiments, the system 322 can comprise an execution component 334. In various cases, the execution component 334 can, as described herein, facilitate any suitable electronic actions, based on the identified angular position.

Note that, in various instances, the access component 328, the overlap component 330, the correction component 332, and the execution component 334 can collectively be considered as being one or more software components 327 of the system 322. In various aspects, it should be appreciated that the one or more software components 327 are described primarily herein as comprising four components (e.g., the access component 328, the overlap component 330, the correction component 332, and the execution component 334) for ease of explanation and illustration. However, the one or more software components 327 are not limited to being implemented as exactly such four components in every embodiment. Indeed, in some embodiments, the functionalities described herein of such four components can be combined in any suitable fashions, so as to be implemented in or by fewer than four components (e.g., in some cases, a single component can perform all of the functionalities that are described herein with respect to the access component 328, the overlap component 330, the correction component 332, and the execution component 334). In other embodiments, the functionalities described herein of such four components can instead be distributed, separated, split, or fragmented in any suitable fashions, so as to be implemented in or by more than four components (e.g., two or more components can facilitate the functionalities that are performable by the access component 328; two or more components can facilitate the functionalities that are performable by the overlap component 330; two or more components can facilitate the functionalities that are performable by the correction component 332; two or more components can facilitate the functionalities that are performable by the execution component 334).

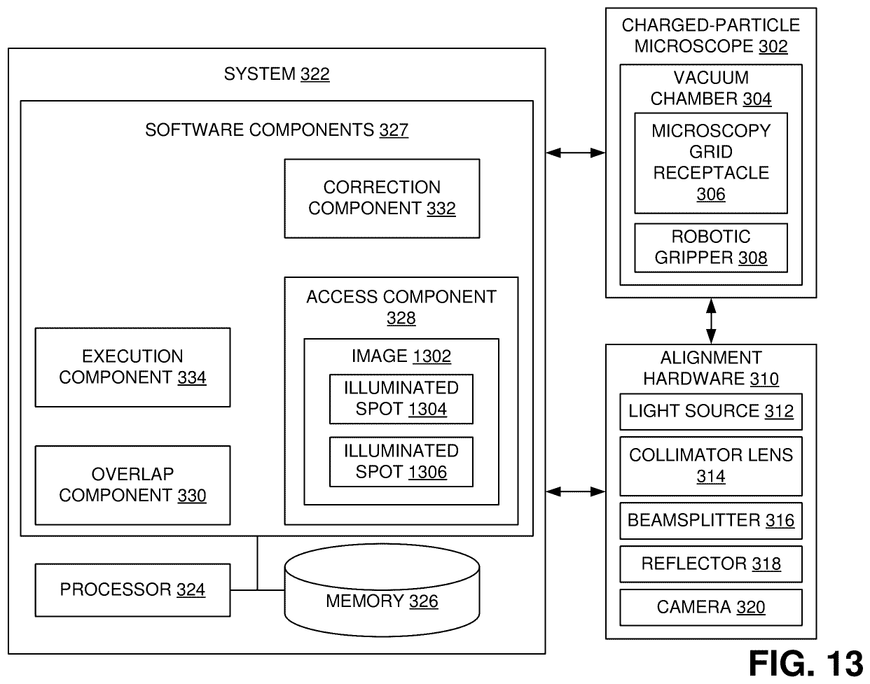

FIG. 13 illustrates a block diagram of an example, non-limiting system including an image that can facilitate teaching of charged-particle microscopy robotic grippers via beamsplitting in accordance with one or more embodiments described herein.

In various embodiments, the access component 328 can electronically access an image 1302. In some aspects, the access component 328 can electronically retrieve, electronically receive, or otherwise electronically obtain the image 1302 from the camera 320. In various instances, the image 1302 can exhibit any suitable format, size, or dimensionality. As a non-limiting example, the image 1302 can be an x-by-y array of pixels, for any suitable positive integers x and y. In various cases, the image 1302 can depict or illustrate an illuminated spot 1304 and an illuminated spot 1306. In various aspects, the illuminated spot 1304 can be any suitable circular cluster of pixels of the image 1302 having non-zero intensity values that are caused by the light beam 804. In other words, the light beam 804 can, as described above, be directed by the beamsplitter 316 toward the camera 320 so as to strike a viewing lens of the camera 320, and the illuminated spot 1304 can be considered as the resultant pixel values caused by such lens-striking. Similarly, in various instances, the illuminated spot 1306 can be any suitable circular cluster of pixels of the image 1302 having non-zero intensity values that are caused by the light beam 1204. In other words, the light beam 1204 can, as described above, be directed by the beamsplitter 316 toward the camera 320 so as to strike a viewing lens of the camera 320, and the illuminated spot 1306 can be considered as the resultant pixel values caused by such lens-striking. In some cases, the illuminated spot 1304 and the illuminated spot 1306 can have the same or different size or radius as each other. In some instances, the illuminated spot 1304 and the illuminated spot 1306 can have the same or different pixel intensities as each other.

In various aspects, the image 1302 can be considered as depicting or illustrating nothing other than the illuminated spot 1304 and the illuminated spot 1306. In other words, the image 1302 can be considered as having pixels with non-zero intensity values and pixels with zero intensity values, where some pixels having non-zero intensity values can belong to or make up the illuminated spot 1304, and where the remaining pixels having non-zero intensity values can belong to or make up the illuminated spot 1306.

In various aspects, the illuminated spot 1304 can be considered as being created from or due to a reflective interaction of the beamsplitting coating 410. Indeed, the illuminated spot 1304 can be considered as the visual representation of the light beam 804 captured by the camera 320, and the light beam 804 can be considered as being derived from the light beam 702 which was reflected off the beamsplitting coating 410. Since the illuminated spot 1304 can have been created from or due to a reflective interaction of the beamsplitting coating 410, and since the beamsplitting coating 410 can be considered as always perpendicular or orthogonal to the shaft-axis 402, the illuminated spot 1304 can be considered as serving as a visual indication of, or as otherwise corresponding to, the shaft-axis 402.

Likewise, in various instances, the illuminated spot 1306 can be considered as being created from or due to a reflective interaction of the reflector 318. After all, the illuminated spot 1306 can be considered as the visual representation of the light beam 1204 captured by the camera 320, and the light beam 1204 can be considered as being derived from the light beam 902 which was reflected off the reflector 318. Since the illuminated spot 1306 can have been created from or due to a reflective interaction of the reflector 318, and since the reflector 318 can be considered as always perpendicular or orthogonal to the bore-axis 406, the illuminated spot 1306 can be considered as serving as a visual indication of, or as otherwise corresponding to, the bore-axis 406.

Accordingly, because the illuminated spot 1304 can be considered as a visual indication of the shaft-axis 402, and because the illuminated spot 1306 can instead be considered as a visual indication of the bore-axis 406, angular alignment or the lack thereof between the shaft-axis 402 and the bore-axis 406 can visually or visibly manifest in the image 1302 as concentricity or lack thereof between the illuminated spot 1304 and the illuminated spot 1306. More specifically, when the shaft-axis 402 and the bore-axis 406 are angularly aligned (e.g., are parallel with each other, though not necessarily colinear), such angular alignment will cause the illuminated spot 1304 and the illuminated spot 1306 to be concentric. Indeed, when the shaft-axis 402 and the bore-axis 406 are parallel to each other, the light beam 902 can, after being reflected by the reflector 318, enter the beamsplitter 316 at the same location or point at which the light beam 902 originated from the beamsplitter 316. This can cause the light beam 1102 to travel or propagate in the same direction as the light beam 702, which can in turn cause the light beam 1204 to propagate in the same direction as the light beam 804. Thus, the light beam 804 and the light beam 1204 can be considered as striking the viewing lens of the camera 320 at the same point or location as each other, which would cause the illuminated spot 1304 and the illuminated spot 1306 to be concentric with each other in the image 1302. In contrast, when the shaft-axis 402 and the bore-axis 406 are angularly misaligned (e.g., are not parallel with each other), such angular misalignment will cause the illuminated spot 1304 and the illuminated spot 1306 to be non-concentric. After all, when the shaft-axis 402 and the bore-axis 406 are not parallel to each other, the light beam 902 can, after being reflected by the reflector 318, enter the beamsplitter 316 at a different location or point than that at which the light beam 902 originated from the beamsplitter 316. This can cause the light beam 1102 to travel or propagate in a different direction than the light beam 702, which can in turn cause the light beam 1204 to propagate in a different direction than the light beam 804. Thus, the light beam 804 and the light beam 1204 can be considered as striking the viewing lens of the camera 320 at different points or locations than each other, which would cause the illuminated spot 1304 and the illuminated spot 1306 to be non-concentric in the image 1302.

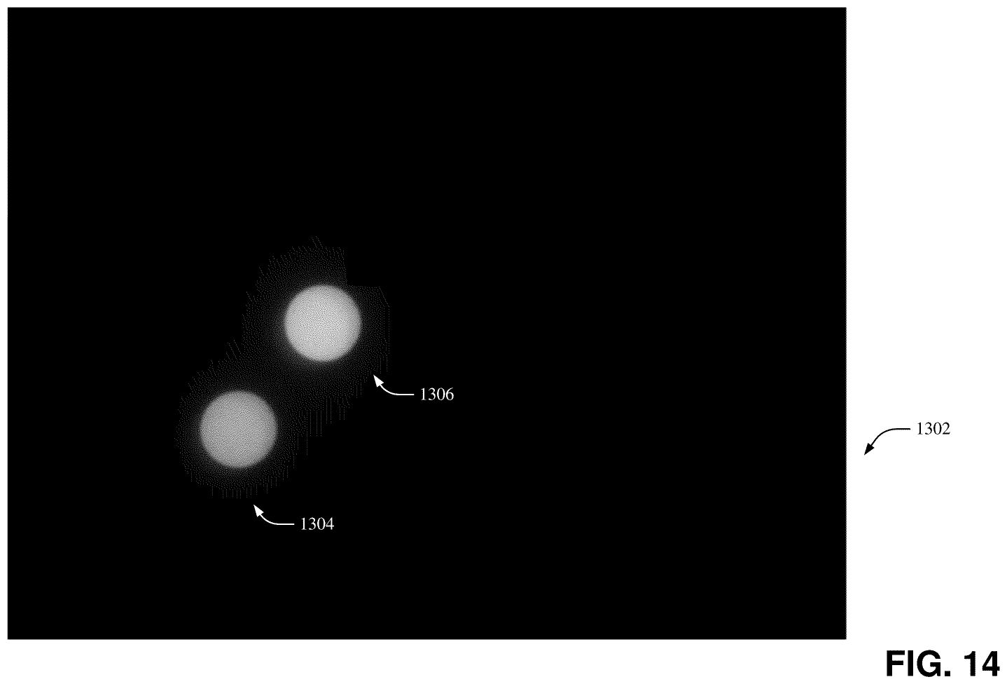

FIGS. 14-17 illustrate non-limiting examples of the image 1302 in accordance with one or more embodiments described herein.

First, consider FIG. 14. As shown in the non-limiting example of FIG. 14, the image 1302 can depict no objects other than the illuminated spot 1304 and the illuminated spot 1306. In the non-limiting example of FIG. 14, the illuminated spot 1304 and the illuminated spot 1306 are not concentric with each other. In other words, FIG. 14 shows the illuminated spot 1304 and the illuminated spot 1306 as having different locations within the image 1302 (e.g., as having different intra-image locations than each other). Accordingly, in the non-limiting example of FIG. 14, the image 1302 can be considered as indicating that the shaft-axis 402 is not angularly aligned (e.g., is not parallel) with the bore-axis 406.

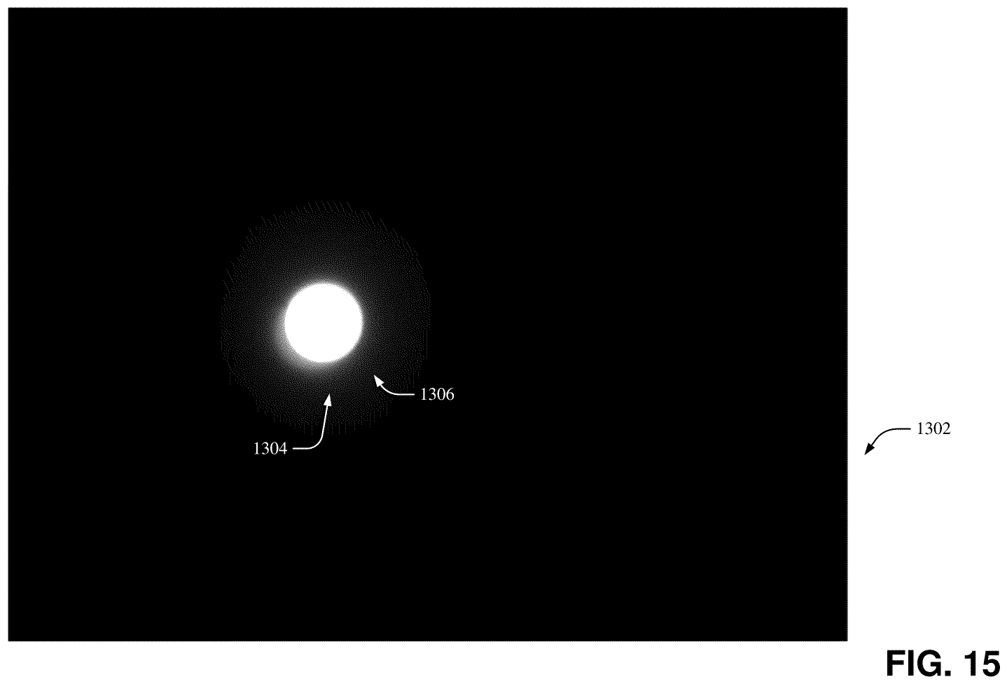

Now, consider FIG. 15. As shown in the non-limiting example of FIG. 15, the image 1302 can still depict no objects other than the illuminated spot 1304 and the illuminated spot 1306. However, in the non-limiting example of FIG. 15, the illuminated spot 1304 and the illuminated spot 1306 are nearly concentric with each other. In other words, FIG. 15 shows the illuminated spot 1304 and the illuminated spot 1306 as having nearly the same location as each other within the image 1302. Accordingly, in the non-limiting example of FIG. 15, the image 1302 can be considered as indicating that the shaft-axis 402 is nearly or mostly angularly aligned (e.g., nearly or mostly parallel) with the bore-axis 406.

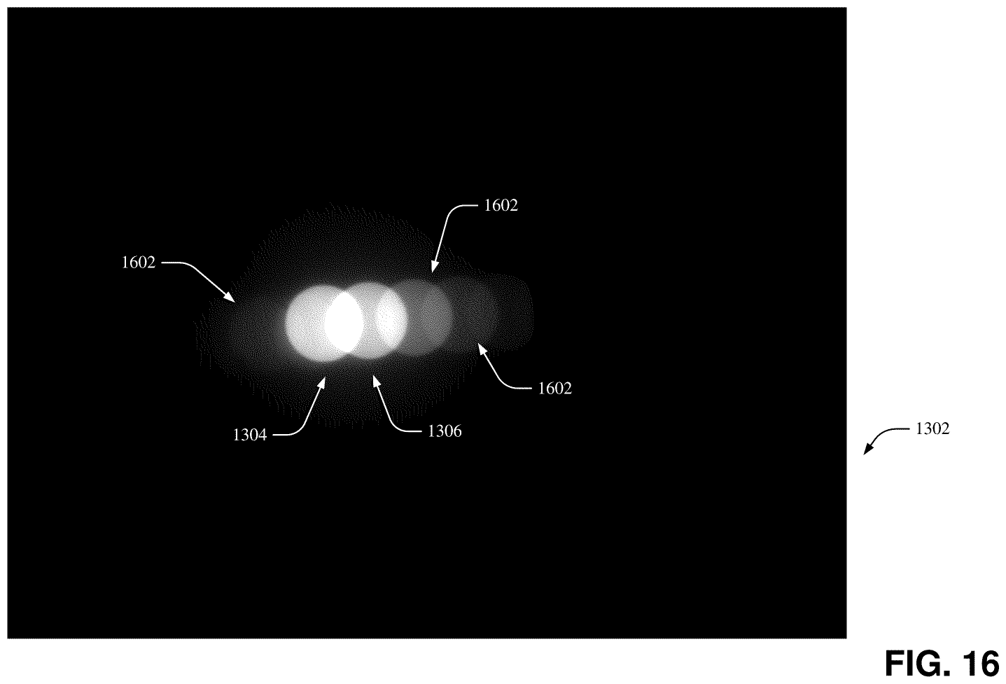

Now, consider FIG. 16. As shown in the non-limiting example of FIG. 16, the illuminated spot 1304 and the illuminated spot 1306 are overlapping but not yet concentric with each other. Accordingly, this can be considered as indicating that the shaft-axis 402 and the bore-axis 406 are closer to angular alignment than in FIG. 14 but farther from angular alignment than in FIG. 15.

Moreover, as shown in the non-limiting example of FIG. 16, it can be possible for the image 1302 to depict artifacts or residuals that are associated with the illuminated spot 1304 or with the illuminated spot 1306, as indicated by numeral 1602. Such artifacts or residuals can be considered as being caused by unintended, extra, or residual reflections or transmittances that might occur within the beamsplitter 316. As a non-limiting example, it can be possible for some portion of the light beam 604 to be reflected by the bottom-most surface of the beamsplitter 316 (e.g., notwithstanding that bottom-most surface having an applied anti-reflective coating), such that at least some of that reflected portion of the light beam 604 can pass through the beamsplitting coating 408 and thus can be directed towards the camera 320. In such case, that at least some of the reflected portion of the light beam 604 can be visually manifested as an artifact or residual with the image 1302.

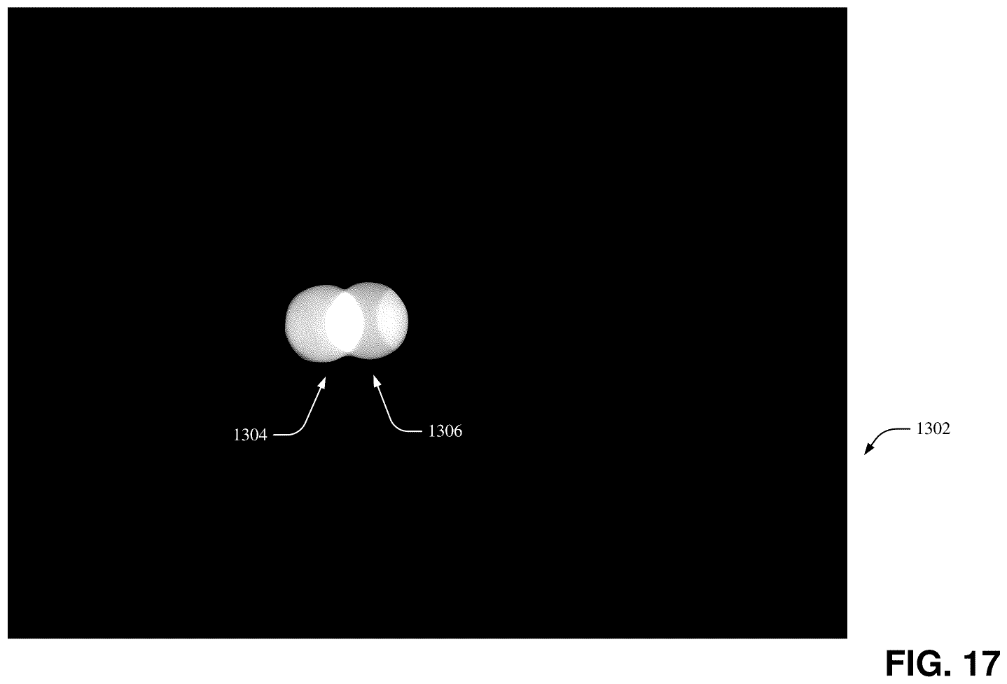

In various cases, such artifacts or residuals can be eliminated via thresholding, as shown with respect to FIG. 17. In particular, given a power rating of the light source 312, and given respective reflectance and transmittance properties of the beamsplitter 316 and of the reflector 318, the illuminated spot 1304 and the illuminated spot 1306 can be expected to have at least a threshold level of intensity when depicted or illustrated within the image 1302. In contrast, any artifacts or residuals that might be caused by unintended or residual reflections or transmittances within the beamsplitter 316 can instead be expected to be weaker than that threshold level of intensity. Accordingly, in various aspects, the access component 328 can iterate through each pixel within the image 1302. For any pixel whose intensity value is greater than or equal to the threshold level of intensity, the access component can leave that pixel unchanged. On the other hand, for any pixel whose intensity value is less than the threshold level of intensity, the access component can floor or reduce that pixel's intensity value to zero. In this way, the access component 328 can be considered as removing or eliminating any artifacts or residuals in the image 1302 without removing or eliminating the illuminated spot 1304 or the illuminated spot 1306. Thus, the image 1302 can be considered as depicting no objects other than the illuminated spot 1304 and the illuminated spot 1306.

Note that, in some cases, the illuminated spot 1304 and the illuminated spot 1306 can be treated interchangeably without loss of generality. In other words, the image 1302 can be considered as illustrating or depicting two illuminated spots, and, sometimes, it need not be known which of those two illuminated spots corresponds to the shaft-axis 402 and which instead corresponds to the bore-axis 406. After all, at least with respect to angular alignment, all that matters is the concentricity or lack thereof between such two illuminated spots. However, in other instances (e.g., such as with respect to translational alignment as described later herein), the illuminated spot 1304 and the illuminated spot 1306 can be treated as not interchangeable. In such cases, the reflectance and transmittance properties of the beamsplitter 316 and of the reflector 318 can be controlled or chosen so that the illuminated spot 1304 is expected to have a different intensity than the illuminated spot 1306. Accordingly, such intensity difference can be used to visually distinguish the illuminated spot 1304 from the illuminated spot 1306.

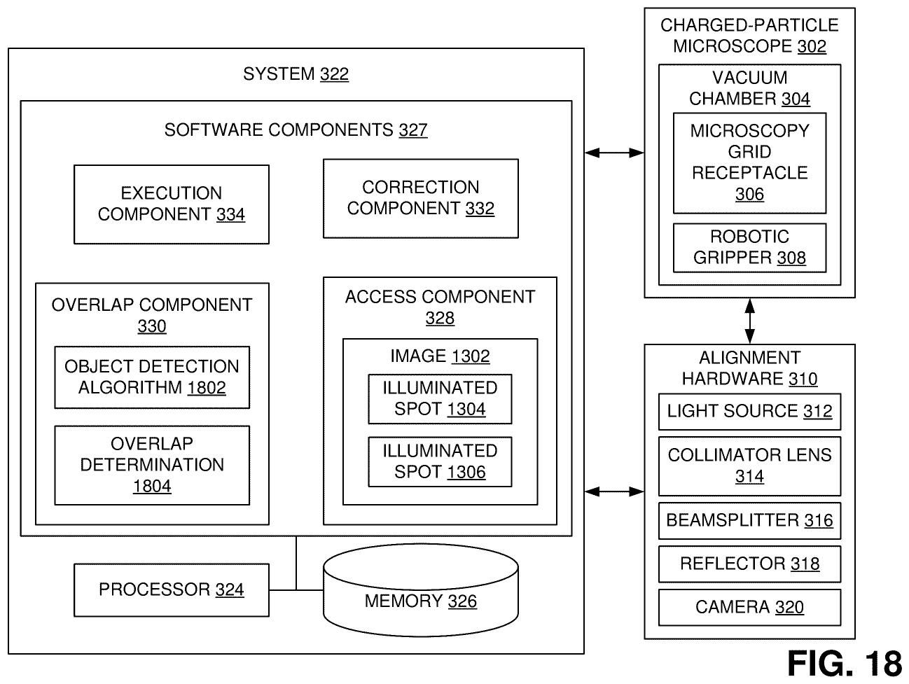

FIG. 18 illustrates a block diagram of an example, non-limiting system including an object detection algorithm and an overlap determination that can facilitate teaching of charged-particle microscopy robotic grippers via beamsplitting in accordance with one or more embodiments described herein.

In various embodiments, the overlap component 330 can electronically store, electronically maintain, electronically control, or otherwise electronically access an object detection algorithm 1802. In various aspects, the object detection algorithm 1802 can be any suitable algorithm, model, or computerized procedure that can count or tally how many distinct or separate objects are illustrated or depicted in an inputted image.

In some cases, the object detection algorithm 1802 can exhibit a deep learning neural network internal architecture. Indeed, in various cases, the object detection algorithm 1802 can have an input layer, one or more hidden layers, and an output layer. In various instances, any of such layers can be coupled together by any suitable interneuron connections or interlayer connections, such as forward connections, skip connections, or recurrent connections. Furthermore, in various cases, any of such layers can be any suitable types of neural network layers having any suitable learnable or trainable internal parameters. For example, any of such input layer, one or more hidden layers, or output layer can be convolutional layers, whose learnable or trainable parameters can be convolutional kernels. As another example, any of such input layer, one or more hidden layers, or output layer can be dense layers, whose learnable or trainable parameters can be weight matrices or bias values. As still another example, any of such input layer, one or more hidden layers, or output layer can be batch normalization layers, whose learnable or trainable parameters can be shift factors or scale factors. As even another example, any of such input layer, one or more hidden layers, or output layer can be LSTM layers, whose learnable or trainable parameters can be input-state weight matrices or hidden-state weight matrices. As yet another example, any of such input layer, one or more hidden layers, or output layer can be transformer layers, whose learnable or trainable parameters can be single-head or multi-head attention blocks or other weight matrices. Further still, in various cases, any of such layers can be any suitable types of neural network layers having any suitable fixed or non-trainable internal parameters. For example, any of such input layer, one or more hidden layers, or output layer can be non-linearity layers, padding layers, pooling layers, or concatenation layers.

In other cases, the object detection algorithm 1802 can exhibit any other suitable machine learning or artificial intelligence internal architecture. As a non-limiting example, the object detection algorithm 1802 can, in some aspects, exhibit a support vector machine internal architecture. As another non-limiting example, the object detection algorithm 1802 can, in some aspects, exhibit a naïve Bayes internal architecture. As even another non-limiting example, the object detection algorithm 1802 can, in some aspects, exhibit a decision tree or random forest internal architecture.

In yet other cases, the object detection algorithm 1802 can exhibit any suitable non-machine-learning internal architecture. As a non-limiting example, the object detection algorithm 1802 can be any suitable computer vision procedure or technique that counts or tallies objects in an inputted image based on computing or calculating Hu moments of the inputted image. As another non-limiting example, the object detection algorithm 1802 can be any suitable computer vision procedure or technique that counts or tallies objects in an inputted image based on computing or calculating pixel intensity profiles of the inputted image. As still another non-limiting example, the object detection algorithm 1802 can be any suitable computer vision procedure or technique that counts or tallies objects in an inputted image based on computing or calculating oriented gradient histograms of the inputted image. As even another non-limiting example, the object detection algorithm 1802 can be any suitable computer vision procedure or technique that counts or tallies objects in an inputted image based on applying edge boxing to the inputted image. As yet another non-limiting example, the object detection algorithm 1802 can be any suitable computer vision procedure or technique that counts or tallies objects in an inputted image based on applying template matching to the inputted image. As another non-limiting example, the object detection algorithm 1802 can be any suitable computer vision procedure or technique that counts or tallies objects in an inputted image based on applying connected component analysis (CCA) to the inputted image.

In some embodiments, the object detection algorithm 1802 can be any suitable combination of any of the aforementioned.

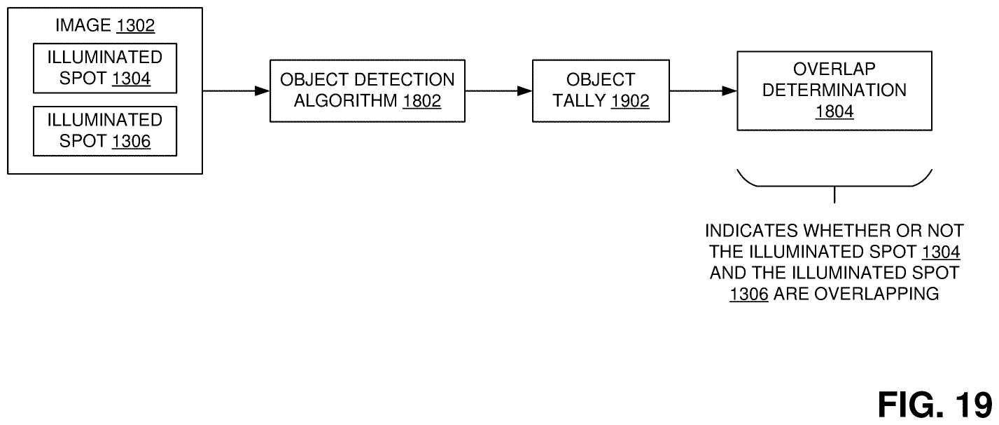

In any case, the overlap component 330 can leverage the object detection algorithm 1802, so as to generate an overlap determination 1804. Non-limiting aspects are described with respect to FIG. 19.

FIG. 19 illustrates an example, non-limiting block diagram showing how the overlap determination 1804 can be obtained in accordance with one or more embodiments described herein.

In various embodiments, the overlap component 330 can electronically apply or execute the object detection algorithm 1802 to or on the image 1302. In various aspects, such application or execution can yield an object tally 1902.

As a non-limiting example, suppose that the object detection algorithm 1802 exhibits a deep learning neural network internal architecture. In such case, the overlap component 330 can feed the image 1302 to an input layer of the object detection algorithm 1802. In various aspects, the image 1302 can complete a forward pass through one or more hidden layers of the object detection algorithm 1802. In various instances, an output layer of the object detection algorithm 1802 can compute or calculate the object tally 1902 based on activation maps or feature maps produced by the one or more hidden layers.

As another non-limiting example, suppose that the object detection algorithm 1802 instead exhibits a non-machine-learning architecture. In such case, the overlap component 330 can compute for the image 1302 whatever Hu moments, pixel intensity profiles, oriented gradient histograms, or other image metrics or image properties that are called for by the object detection algorithm 1802, and the end-result of such computations can be the object tally 1902.

In any case, the object tally 1902 can be a scalar having a positive, integer value or magnitude. In various aspects, the value or magnitude of the object tally 1902 can be considered as indicating, specifying, or otherwise representing how many distinct, discrete, or separate objects are (as determined or inferred by the object detection algorithm 1802) depicted or illustrated in the image 1302. As mentioned above, the image 1302 can (after application of thresholding as appropriate) depict or illustrate no objects other than the illuminated spot 1304 and the illuminated spot 1306. Accordingly, the object tally 1902 can be considered as having two possible values or magnitudes: a value or magnitude of 2, which can occur when the illuminated spot 1304 and the illuminated spot 1306 are not visibly touching or overlapping with each other; and a value or magnitude of 1, which can occur when the illuminated spot 1304 and the illuminated spot 1306 are instead visibly touching or overlapping with each other.

In various aspects, the overlap determination 1804 can be any suitable electronic data having any suitable format, size, or dimensionality (e.g., can be one or more scalars, one or more vectors, one or more matrices, one or more tensors, one or more character strings, or any suitable combination thereof) which can indicate or specify whether or not the illuminated spot 1304 and the illuminated spot 1306 are overlapping. In various instances, the overlap component 330 can electronically generate the overlap determination 1804 based on reading the object tally 1902.

As a non-limiting example, suppose that the object tally 1902 has a value or magnitude of 2. This can mean that the object detection algorithm 1802 recognized or counted two distinct, discrete, contiguous, or separate objects within the image 1302. Because the image 1302 can be known (due to the alignment hardware 310) to depict or illustrate both the illuminated spot 1304 and the illuminated spot 1306 with no other objects, the object tally 1902 having a value or magnitude of 2 can indicate that the illuminated spot 1304 and the illuminated spot 1306 visually appear to be separate or distinct within the image 1302, meaning that they are not overlapping.

As another non-limiting example, suppose that the object tally 1902 instead has a value or magnitude of 1. This can mean that the object detection algorithm 1802 recognized or counted only one distinct, discrete, contiguous, or separate object within the image 1302. Because the image 1302 can be known (due to the alignment hardware 310) to depict or illustrate both the illuminated spot 1304 and the illuminated spot 1306 and no other objects, the object tally 1902 having a value or magnitude of 1 can indicate that the illuminated spot 1304 and the illuminated spot 1306 visually appear to be not separated or not distinct from each other within the image 1302, meaning that they are overlapping.

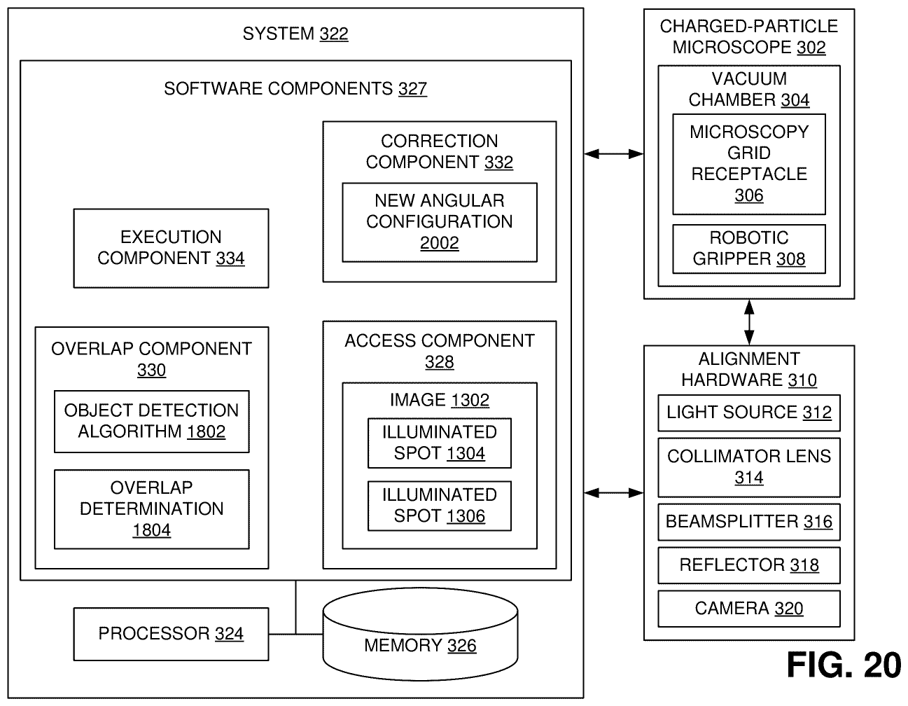

FIG. 20 illustrates a block diagram of an example, non-limiting system including a new angular configuration that can facilitate teaching of charged-particle microscopy robotic grippers via beamsplitting in accordance with one or more embodiments described herein.

In various embodiments, the correction component 332 can electronically determine, electronically calculate, or otherwise electronically identify a new angular configuration 2002, based on the overlap determination 1804. In various aspects, the new angular configuration 2002 can be specific values or states of the angular position controls, parameters, or settings of the robotic gripper 308, which values or states are predicted or expected to cause the shaft-axis 402 to become more angularly aligned with (e.g., to become more parallel to) the bore-axis 406. As a non-limiting example, consider the X-axis, the Y-axis, and the Z-axis shown in FIGS. 4-12. In such case, the three-dimensional location and orientation of the robotic gripper 308 within the vacuum chamber 304 can be quantified by the location of the robotic gripper 308 (e.g., of its end-effector) along the X-axis, the location of the robotic gripper 308 along the Y-axis, the location of the robotic gripper 308 along the Z-axis, the angle of rotation of the robotic gripper 308 about the X-axis, the angle of rotation of the robotic gripper 308 about the Y-axis, and the angle of rotation of the robotic gripper 308 about the Z-axis. In various aspects, P_{X} can denote a selectively controllable parameter of the robotic gripper 308 that dictates or otherwise affects how (e.g., in positive or negative direction, by how many units) the robotic gripper 308 translates, moves, or otherwise shifts along the X-axis. In various instances, P_{Y} can denote a selectively controllable parameter of the robotic gripper 308 that dictates or otherwise affects how (e.g., in positive or negative direction, by how many units) the robotic gripper 308 translates, moves, or otherwise shifts along the Y-axis. In various cases, P_{Z} can denote a selectively controllable parameter of the robotic gripper 308 that dictates or otherwise affects how (e.g., in positive or negative direction, by how many units) the robotic gripper 308 translates, moves, or otherwise shifts along the Z-axis. In various aspects, θ_{X} can denote a selectively controllable parameter of the robotic gripper 308 that dictates or otherwise affects how (e.g., in positive or negative direction, by how many degrees or radians) the robotic gripper 308 rotates, swivels, or otherwise moves about the X-axis. In various instances, θ_{Y} can denote a selectively controllable parameter of the robotic gripper 308 that dictates or otherwise affects how (e.g., in positive or negative direction, by how many degrees or radians) the robotic gripper 308 rotates, swivels, or otherwise moves about the Y-axis. In various cases, Oz can denote a selectively controllable parameter of the robotic gripper 308 that dictates or otherwise affects how (e.g., in positive or negative direction, by how many degrees or radians) the robotic gripper 308 rotates, swivels, or otherwise moves about the Z-axis. That is, the three-dimensional position and orientation of the robotic gripper 308 at any instant in time can be controlled based on the specific values, states, or configuration of the following parametric control vector: (P_{X}, P_{Y}, P_{Z}, θ_{X}, θ_{Y}, θ_{Z}).

In the non-limiting examples of FIGS. 4-12, the bore-axis 406 is stationary and parallel to the Y-axis. In such case, angular alignment between the shaft-axis 402 and the bore-axis 406 can depend upon ex and ez, which can be respectively considered as the selectively controllable pitch setting/parameter and the selectively controllable yaw setting/parameter of the robotic gripper 308. In contrast, angular alignment between the shaft-axis 402 and the bore-axis 406 can be agnostic to θ_{Y}, P_{X}, P_{Y}, and P_{Z}, which can respectively be considered as the selectively controllable roll setting/parameter, the selectively controllable X-displacement setting/parameter, the selectively controllable Y-displacement setting/parameter, and the selectively controllable Z-displacement setting/parameter of the robotic gripper 308. Thus, in various instances, the new angular configuration 2002 can be specific values or states of θ_{X} and θ_{Z} (e.g., a specific combination of controllable pitch and yaw values) that, if exhibited or moved to by the robotic gripper 308, would cause the shaft-axis 402 to become angularly aligned (or at least to become less angularly misaligned) with the bore-axis 406.

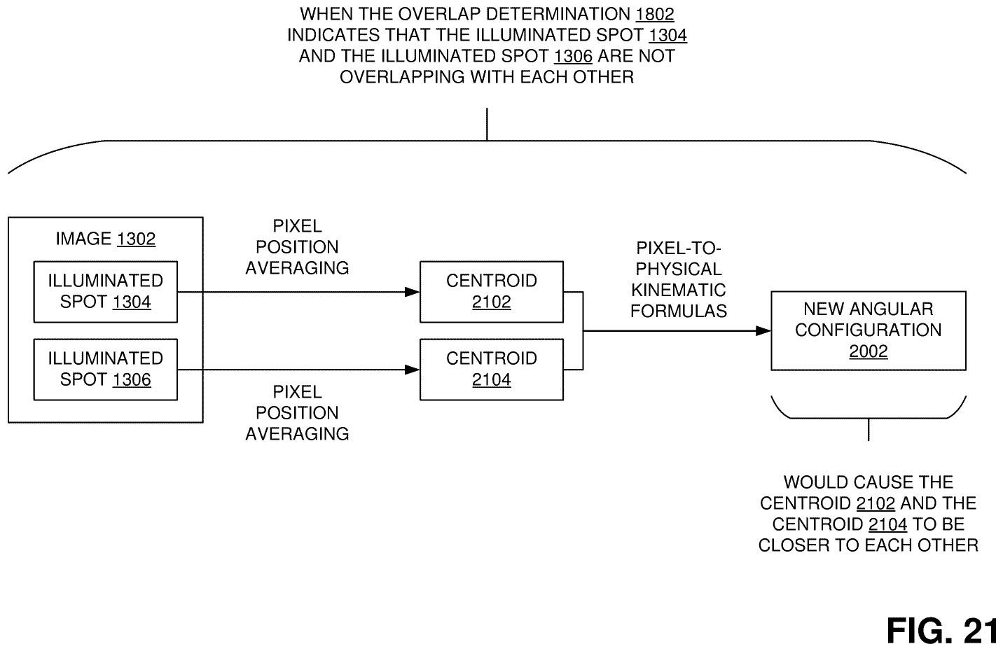

In various aspects, how the correction component 332 determines, calculates, or identifies the new angular configuration 2002 can depend upon the overlap determination 1804. Non-limiting details are described with respect to FIGS. 21-26.

FIGS. 21-26 illustrate example, non-limiting block diagrams showing how the new angular configuration 2002 can be identified based on the overlap determination 1804 in accordance with one or more embodiments described herein.

First, consider FIG. 21. FIG. 21 pertains to situations in which the overlap determination 1804 indicates or otherwise specifies that the illuminated spot 1304 and the illuminated spot 1306 are not overlapping with each other. In response to such indication, the correction component 332 can electronically compute or calculate a centroid 2102 of the illuminated spot 1304 and a centroid 2104 of the illuminated spot 1306, based on respective pixel position averaging.

In particular, each pixel of the image 1302 can be considered as having a respective or unique intra-image location (e.g., in terms of row identifier and column identifier with respect to some origin of the image 1302). Additionally, because the illuminated spot 1304 and the illuminated spot 1306 are not overlapping, the pixels of the image 1302 that belong to or make up the illuminated spot 1304 can be visibly distinct, separate, apart, or segregated from the pixels of the image 1302 that instead belong to or make up the illuminated spot 1306. So, in various aspects, the correction component 332 can average the intra-image locations of all the pixels that belong to or make up the illuminated spot 1304, and that resultant, averaged intra-image location can be considered as the centroid 2102. Likewise, in various instances, the correction component 332 can average the intra-image locations of all the pixels that belong to or make up the illuminated spot 1306, and that resultant, averaged intra-image location can be considered as the centroid 2104.

In various cases, the correction component 332 can then compute the new angular configuration 2002, by applying any suitable pixel-to-physical kinematic formulas or transformations on or to the centroid 2102 and the centroid 2104.

More specifically, the intra-image locations of the centroid 2102 and the centroid 2104 can depend upon where the light beam 804 and the light beam 1204 respectively strike the viewing lens of the camera 320. Furthermore, where the light beam 804 and the light beam 1204 respectively strike the viewing lens of the camera 320 can depend upon the distance separating the beamsplitter 316 from the camera 320 (which can be considered as known or knowable at any given instant in time since P_{Z} can be selectively controllable), can depend upon the distance separating the beamsplitter 316 from the reflector 318 (which can be considered as known or knowable at any given instant in time since P_{Y} can be selectively controllable), and can depend upon the various angles of incidence and angles of reflection that the beamsplitter 316 and the reflector 318 use to interact with the light beams 602, 702, 804, 902, 1102, and 1204. Further still, such various angles of incidence and reflection can be initially unknown but can predictably geometrically vary, according to any suitable mathematical functions (e.g., compositions of trigonometric functions), with θ_{X} and θ_{Z} (e.g., with the values or states assigned to the selectively controllable pitch and yaw settings/parameters of the robotic gripper 308).

Now, because the current or present-time distances separating the beamsplitter 316 from the camera 320 and from the reflector 318 can be known (e.g., based on the current or present-time values or states of P_{Y} and P_{Z}), because the current or present-time values or states of θₓ and θ_{Z} can be known, and because the current or present-time intra-image locations of the centroid 2102 and the centroid 2104 can be computed via pixel position averaging, the correction component 332 can, in various aspects, use that known information and the above-mentioned mathematical functions to calculate or estimate the current or present-time values of the various angles of incidence and angles of reflection that the beamsplitter 316 and the reflector 318 use to interact with the light beams 602, 702, 804, 902, 1102, and 1204. Given those calculated or estimated current or present-time values of the angles of incidence and angles of reflection, the above-mentioned mathematical functions can be considered as informing the correction component 332 how the values of the angles of incidence and angles of reflection will or would vary with controlled changes in θ_{X} and θ_{Z} (e.g., increasing the selectively controllable pitch setting/parameter of the robotic gripper 308 by a first percentage or amount might be expected to reduce some angles of incidence and reflection by second percentages or amounts and might be expected to increase other angles of incidence and reflection by third percentages or amounts). Equivalently, since where the light beams 804 and 1204 strike the viewing lens of the camera 320 can depend upon those various angles of incidence and reflection, the above-mentioned mathematical functions can be considered as informing the correction component 332 how the intra-image locations of the centroid 2102 and of the centroid 2104 will or would vary with controlled changes in θ_{X} and θ_{Z}. Therefore, such mathematical functions can be considered as mapping the real-world physical space of the vacuum chamber 304 within which the robotic gripper 308 can move to the two-dimensional pixel space of the image 1302, hence the term “pixel-to-physical”.

Thus, in various aspects, the correction component 332 can utilize those mathematical formulas (e.g., those pixel-to-physical kinematic transformations) to identify values or states of θ_{X} and Oz that would, if occupied or implemented by the robotic gripper 308, cause the centroid 2102 and the centroid 2104 to move towards or closer to each other within the image 1302. In various instances, such identified values or states of θ_{X} and ez can be referred to as the new angular configuration 2002.

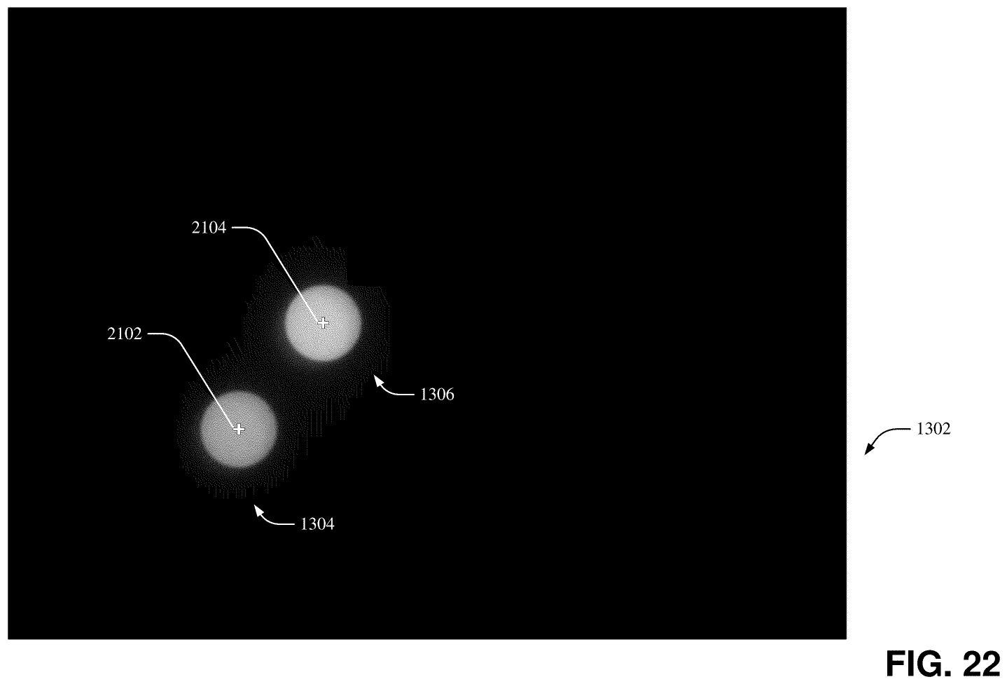

FIG. 22 illustrates a non-limiting example of the image 1302 where the computations of FIG. 21 can be implemented. In the non-limiting example of FIG. 22, the illuminated spot 1304 and the illuminated spot 1306 are not overlapping. Accordingly, their pixels can be considered as being separate or distinguishable from each other. So, the intra-image locations of the pixels that belong to the illuminated spot 1304 can be averaged, and that averaged intra-image location can be considered or treated as the location of the centroid 2102. Likewise, the intra-image locations of the pixels that belong to the illuminated spot 1306 can be averaged, and that averaged intra-image location can be considered or treated as the location of the centroid 2104. Accordingly, the pixel-to-physical kinematic formulas can be applied, so as to identify whatever values of θ_{X} and θ_{Z} (e.g., so as to identify whatever values or states of the selectively controllable pitch and yaw settings/parameters of the robotic gripper 308) would cause the centroid 2102 and the centroid 2104 to move to new intra-image locations where they would be closer to each other, and such values of θ_{X} and θ_{Z} can be referred to as the new angular configuration 2002.

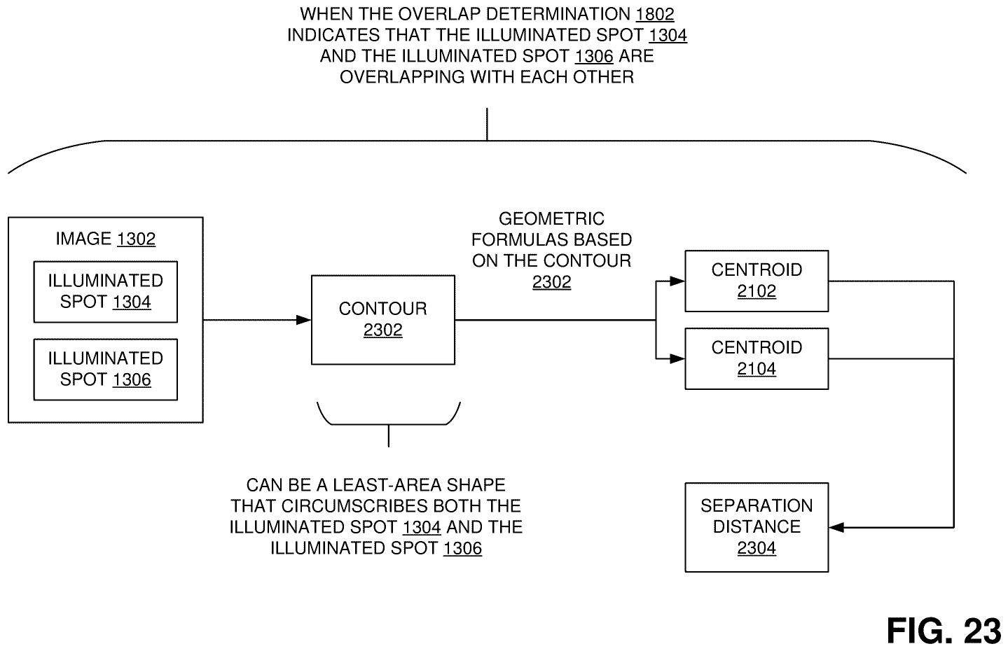

Next, consider FIG. 23. FIG. 23 pertains to situations in which the overlap determination 1804 indicates or otherwise specifies that the illuminated spot 1304 and the illuminated spot 1306 are overlapping with each other (although the extent of overlap might not be known). In response to such indication, the correction component 332 can electronically compute or calculate the centroid 2102 and the centroid 2104, based on contour fitting.

In particular, as mentioned above, each pixel of the image 1302 can be considered as having a respective or unique intra-image location (e.g., in terms of row identifier and column identifier with respect to some origin of the image 1302). However, because the illuminated spot 1304 and the illuminated spot 1306 are overlapping, some pixels of the image 1302 that belong to or make up the illuminated spot 1304 can be visibly indistinct, not separate, not apart, or not segregated from pixels of the image 1302 that belong to or make up the illuminated spot 1306. In other words, due to the overlap, there will be some pixels that belong to both the illuminated spot 1304 and to the illuminated spot 1306, but identifying such pixels can be considered as a non-trivial or difficult computer vision task. Because of this non-triviality or difficulty, pixel position averaging cannot reliably be used to identify the centroid 2102 and the centroid 2104.

Instead of utilizing pixel position averaging, the correction component 332 can, in various aspects, fit a contour 2302 to the image 1302. In various instances, the contour 2302 can be a boundary of any suitable geometric shape (e.g., a rectangular boundary, an elliptical boundary, any other polygonal boundary) of least-area that can circumscribe both the illuminated spot 1304 and the illuminated spot 1306. Here, “least-area” can mean that the contour 2302 circumscribes as few pixels of the image 1302 as possible, given its geometric shape, and given that it nevertheless circumscribes all pixels that belong to at least one of the illuminated spot 1304 and the illuminated spot 1306.

Note that the area of the contour 2302 can depend upon how far apart the illuminated spot 1304 and the illuminated spot 1306 are. For example, for whatever geometric shape the contour 2302 has, its area can decrease as the illuminated spot 1304 and the illuminated spot 1306 get closer together, and its area can instead increase as the illuminated spot 1304 and the illuminated spot 1306 get farther apart.

In various cases, the correction component 332 can generate or compute the contour 2302 via any suitable computer vision contour fitting techniques. In some aspects, the correction component 332 can generate the contour 2302 via any suitable machine learning or artificial intelligence technique. As a non-limiting example, the correction component 332 can electronically store, maintain, control, or otherwise access a deep learning neural network. In various cases, the deep learning neural network can have an input layer, one or more hidden layers, and an output layer. In various instances, any of such layers can be coupled together by any suitable interneuron connections or interlayer connections, such as forward connections, skip connections, or recurrent connections. Furthermore, in various cases, any of such layers can be any suitable types of neural network layers having any suitable learnable or trainable internal parameters. For example, any of such input layer, one or more hidden layers, or output layer can be convolutional layers, whose learnable or trainable parameters can be convolutional kernels. As another example, any of such input layer, one or more hidden layers, or output layer can be dense layers, whose learnable or trainable parameters can be weight matrices or bias values. As still another example, any of such input layer, one or more hidden layers, or output layer can be batch normalization layers, whose learnable or trainable parameters can be shift factors or scale factors. As even another example, any of such input layer, one or more hidden layers, or output layer can be LSTM layers, whose learnable or trainable parameters can be input-state weight matrices or hidden-state weight matrices. As yet another example, any of such input layer, one or more hidden layers, or output layer can be transformer layers, whose learnable or trainable parameters can be single-head or multi-head attention blocks or other weight matrices. Further still, in various cases, any of such layers can be any suitable types of neural network layers having any suitable fixed or non-trainable internal parameters. For example, any of such input layer, one or more hidden layers, or output layer can be non-linearity layers, padding layers, pooling layers, or concatenation layers.

Regardless of its specific internal architecture, the deep learning neural network can be configured to circumscribe illuminated spots depicted in inputted images with least-area contour shapes. Accordingly, in various aspects, the correction component 332 can execute the deep learning neural network on the image 1302, and such execution can cause the deep learning neural network to produce the contour 2302. For instance, the correction component 332 can feed the image 1302 to an input layer of the deep learning neural network, the image 1302 can complete a forward pass through one or more hidden layers of the deep learning neural network, and an output layer of the deep learning neural network can compute or calculate the contour 2302 based on activation maps or feature maps produced by the one or more hidden layers.

In other aspects, the correction component 332 can instead generate the contour 2302 via any suitable non-machine-learning computer vision techniques. As a non-limiting example, the correction component 332 can generate the contour 2302 by applying to the image 1302 any suitable computer vision procedure or technique that utilizes convex hull computations (e.g., Graham's Scan Algorithm). As another non-limiting example, the correction component 332 can generate the contour 2302 by applying to the image 1302 any suitable computer vision procedure or technique that utilizes polygon approximations (e.g., Douglas-Peucker Algorithm). As yet another non-limiting example, the correction component 332 can generate the contour 2302 by applying to the image 1302 any suitable computer vision procedure or technique that utilizes least-squares fitting computations (e.g., least-squares ellipse fitting, least-squares rectangle fitting).

In some embodiments, the correction component 332 can generate the contour 2302 via any suitable combination of any of the aforementioned.

In any case, the contour 2302 can be considered as having a known intra-image location and as having known fitted dimensions (e.g., known length, known width). In various aspects, the correction component 332 can identify the centroid 2102 and the centroid 2104, by applying any suitable geometric formulas or equations to the contour 2302. Indeed, given the geometric shape of the contour 2302, the radii of the illuminated spot 1304 and the illuminated spot 1306 can have any suitable known geometric relationship with the contour 2302. Accordingly, the correction component 332 can utilize the fitted dimensions of the contour 2302 and that known geometric relationship, so as to identify the intra-image locations of the centroid 2102 and the centroid 2104. As a non-limiting example, suppose that the contour 2302 is a rectangle, suppose that the illuminated spot 1304 and the illuminated spot 1306 have the same radius, and suppose that the illuminated spot 1304 and the illuminated spot 1306 are overlapping in the length-wise direction of the contour 2302. In such case, the contour 2302 can be considered as having a fitted length and a fitted width, and the fitted width of the contour 2302 can be expected to be twice the radius. So, the correction component 332 can: identify the midpoint of one of the fitted width sides of the contour 2302; traverse from that midpoint by half the fitted width in a direction that is toward the interior of the contour 2302 and that is parallel to the fitted length sides of the contour 2302; and whatever point is arrived at by such traversal can be considered as one of the centroid 2102 and the centroid 2104. Conversely, the correction component 332 can: identify the midpoint of the other of the fitted width sides of the contour 2302; traverse from that midpoint by half the fitted width in a direction that is toward the interior of the contour 2302 and that is parallel to the fitted length sides of the contour 2302; and whatever point is arrived at by such traversal can be considered as the other of the centroid 2102 and the centroid 2104.

Now, the present inventors realized that utilizing pixel-to-physical kinematic formulas to compute the new angular configuration 2002 can be more efficacious or reliable when the centroid 2102 and the centroid 2104 are farther apart (e.g., when the illuminated spot 1304 and the illuminated spot 1306 are not overlapping or are only somewhat overlapping). In contrast, the present inventors realized that utilizing pixel-to-physical kinematic formulas to compute the new angular configuration 2002 can instead be less efficacious or reliable when the centroid 2102 and the centroid 2104 are closer together (e.g., when the illuminated spot 1304 and the illuminated spot 1306 are extensively overlapping). Accordingly, in various aspects, the correction component 332 can compute a separation distance 2304 between the centroid 2102 and the centroid 2104. As a non-limiting example, the separation distance 2304 can be equal to or otherwise based on a Euclidean distance between the centroid 2102 and the centroid 2104. As another non-limiting example, the separation distance 2304 can be equal to or otherwise based on a number of intervening or intermediary pixels between the centroid 2102 and the centroid 2104. In various cases, how the correction component 332 can identify the new angular configuration 2002 can be based on the separation distance 2304.

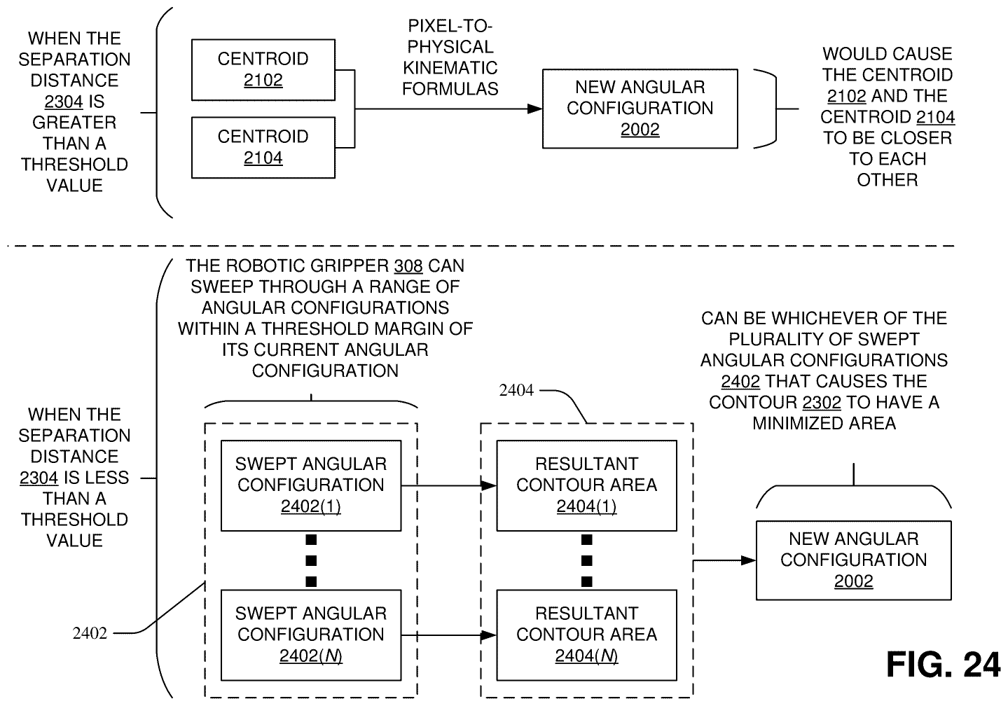

Consider FIG. 24. In various embodiments, as shown, how the correction component 332 identifies the new angular configuration 2002 can depend upon the separation distance 2304. In particular, the correction component 332 can compare the separation distance 2304 to any suitable threshold distance, and the correction component 332 can compute the new angular configuration 2002 based on such comparison.

In various aspects, suppose that the separation distance 2304 is greater than the threshold distance. In response, the correction component 332 can conclude that the centroid 2102 and the centroid 2104 are far enough apart so that the pixel-to-physical kinematic formulas can be efficaciously or reliably used. Accordingly, as shown, the correction component 332 can compute or identify the new angular configuration 2002 by applying the pixel-to-physical kinematic formulas to the centroid 2102 and the centroid 2104, as described above.

In contrast, suppose that the separation distance 2304 is less than the threshold distance. In response, the correction component 332 can conclude that the centroid 2102 and the centroid 2104 are close enough together so that the pixel-to-physical kinematic formulas cannot be efficaciously or reliably used. In such case, the correction component 332 can electronically command, electronically instruct, or otherwise electronically cause the robotic gripper 308 to move or sweep through a plurality of swept angular configurations 2402. In various instances, the plurality of swept angular configurations 2402 can comprise n configurations for any suitable positive integer n: a swept angular configuration 2402(1) to a swept angular configuration 2402(n). In various cases, each of the plurality of swept angular configurations 2402 can be a unique combination of values or states of θ_{X} and θ_{Z} that is within any suitable threshold proximity or margin of the current or present-time values or states of θ_{X} and θ_{Z}. As a non-limiting example, the swept angular configuration 2402(1) can be a first unique combination of values or states of the selectively controllable pitch and yaw settings/parameters of the robotic gripper 308 which are within the threshold proximity or margin of the values or states that are currently or presently assigned to the selectively controllable pitch and yaw settings/parameters of the robotic gripper 308. As another non-limiting example, the swept angular configuration 2402(n) can be an n-th unique combination of values or states of the selectively controllable pitch and yaw settings/parameters of the robotic gripper 308 which are within the threshold proximity or margin of the values or states that are currently or presently assigned to the selectively controllable pitch and yaw settings/parameters of the robotic gripper 308. In some cases, the threshold proximity or margin can be considered as being or defining an angular or orientational range that is centered about the current or present-time values of θₓ and θ_{Z}, and the plurality of swept angular configurations 2402 can be evenly-spaced or evenly-distributed so as to span that range. However, in other cases, the plurality of swept angular configuration 2402 can be unevenly-spaced or unevenly-distributed.

In any case, the correction component 332 can cause the robotic gripper 308 to temporarily or momentarily move or otherwise take on each of the plurality of swept angular configurations 2402. Note that such movements can alter the angles of incidence and reflection that the beamsplitter 316 and the reflector 318 impart to the light beams 602, 702, 804, 902, 1102, and 1204. Accordingly, such movements can alter the intra-image locations of the centroid 2102 and the centroid 2104, as well as the intra-image location and fitted dimensions of the contour 2302. In various aspects, the correction component 332 can compute or calculate a respective area of (e.g., a respective area that is circumscribed by) the contour 2302 for each of the plurality of swept angular configurations 2402, thereby yielding a plurality of resultant contour areas 2404. Indeed, the plurality of resultant contour areas 2404 can respectively correspond to the plurality of swept angular configurations 2402. That is, since the plurality of swept angular configurations 2402 can comprise n configurations, the plurality of resultant contour areas 2404 can comprise n areas: a resultant contour area 2404(1) to a resultant contour area 2404(n). As a non-limiting example, the resultant contour area 2404(l) can be the measured or approximated area circumscribed by the contour 2302 which is caused by whatever fitted dimensions the contour 2302 has when the robotic gripper 308 is moved to or takes on the swept angular configuration 2402(1). As another non-limiting example, the resultant contour area 2404(n) can be the measured or approximated area circumscribed by the contour 2302 which is caused by whatever fitted dimensions the contour 2302 has when the robotic gripper 308 is moved to or takes on the swept angular configuration 2402(n).

In various aspects, the correction component 332 can identify the new angular configuration 2002, based on the plurality of resultant contour areas 2404. As a non-limiting example, the new angular configuration 2002 can whichever of the plurality of swept angular configurations 2402 that has or corresponds to the lowest, the minimal, or the otherwise minimized resultant contour area. After all, if a particular angular configuration (e.g., particular values of θₓ and θ_{Z}) causes the contour 2302 to have a lower area than any other angular configurations, that particular angular configuration can be considered as achieving the most overlap between the illuminated spot 1304 and the illuminated spot 1306, and thus as achieving the most or best angular alignment between the shaft-axis 402 and the bore-axis 406.

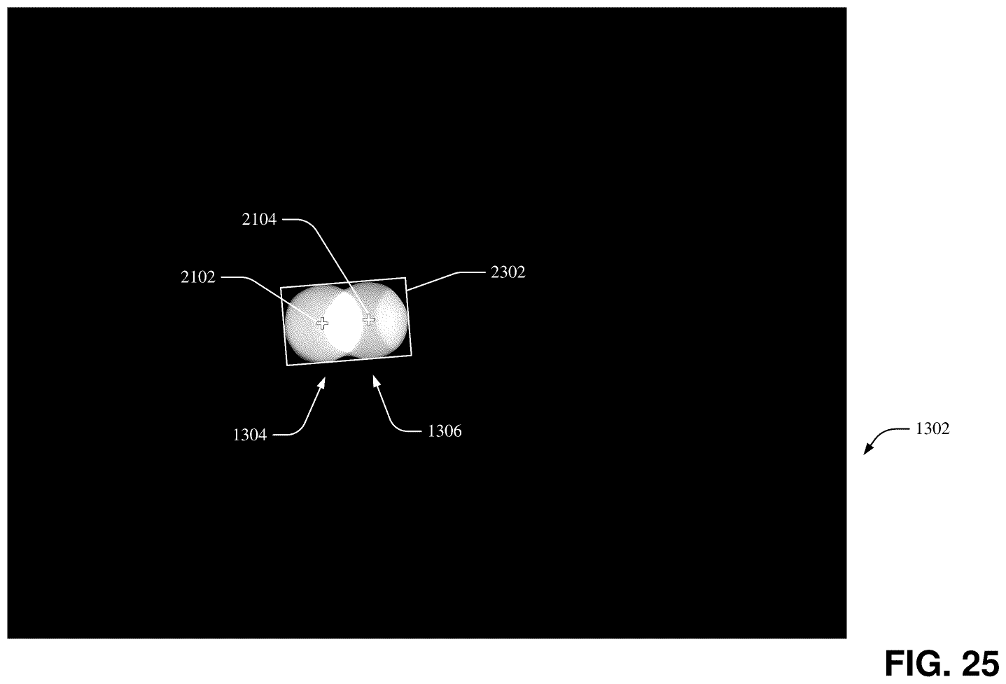

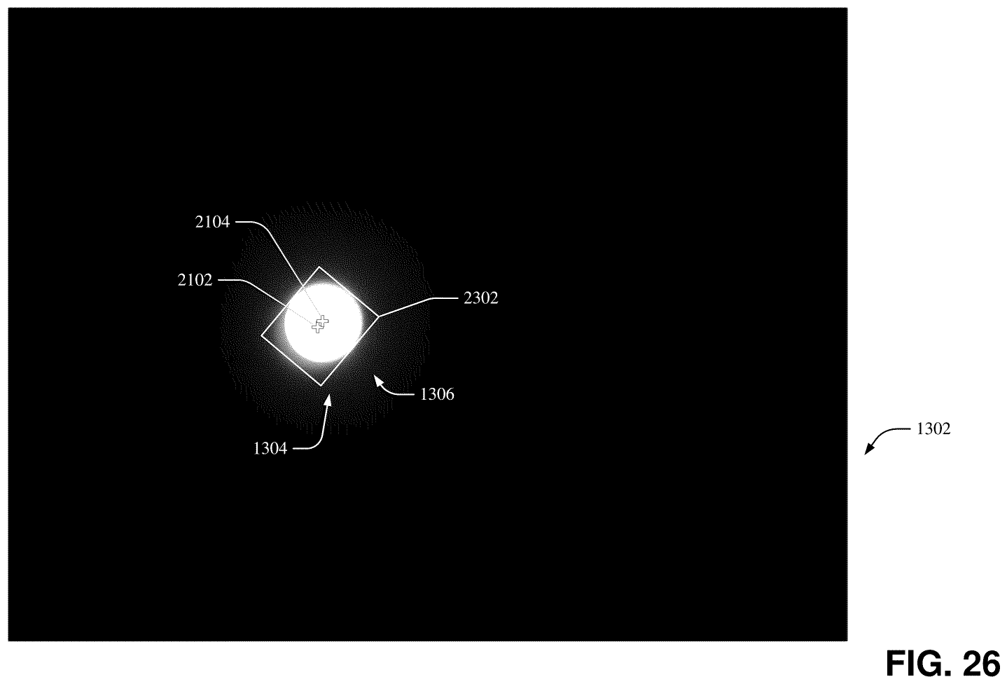

FIGS. 25-26 illustrate non-limiting examples of the image 1302 where the computations of FIGS. 23-24 can be implemented.

First, consider FIG. 25. In the non-limiting example of FIG. 25, the illuminated spot 1304 and the illuminated spot 1306 are overlapping, but such overlap is not yet extensive. Because of such overlap, their pixels cannot be considered as being separate or distinguishable from each other. So, pixel position averaging cannot be reliably or easily implemented. Instead, the contour 2302 can be fitted to the image 1302, so as to have least-area while still circumscribing both the illuminated spot 1304 and the illuminated spot 1306, and the centroid 2102 and the centroid 2104 can estimated geometrically based on the fitted dimensions of the contour 2302. In the non-limiting example of FIG. 25, the centroid 2102 and the centroid 2104 can be considered as being separated by more than the threshold distance. Accordingly, the pixel-to-physical kinematic formulas can be applied, so as to identify whatever values of θ_{X} and Oz (e.g., so as to identify whatever values or states of the selectively controllable pitch and yaw settings/parameters of the robotic gripper 308) would cause the centroid 2102 and the centroid 2104 to move to new intra-image locations where they would be closer to each other, and such values of θ_{X} and θ_{Z} can be referred to as the new angular configuration 2002.

Next, consider FIG. 26. In the non-limiting example of FIG. 26, the illuminated spot 1304 and the illuminated spot 1306 are overlapping, and such overlap is extensive. Because of such overlap, their pixels cannot be considered as being separate or distinguishable from each other. So, pixel position averaging cannot be reliably or easily implemented. Instead, the contour 2302 can be fitted to the image 1302, so as to have least-area while still circumscribing both the illuminated spot 1304 and the illuminated spot 1306, and the centroid 2102 and the centroid 2104 can estimated geometrically based on the fitted dimensions of the contour 2302. In the non-limiting example of FIG. 26, the centroid 2102 and the centroid 2104 can be considered as being separated by less than the threshold distance. Accordingly, the pixel-to-physical kinematic formulas can be eschewed. Instead, the robotic gripper 308 can be swept through any suitable range of angular configurations (e.g., of θ_{X} and θ_{Z} values) that is centered about its current angular configuration (e.g., centered about its current θ_{X} and θ_{Z} values), and a respective area of the contour 2302 can be computed for each of such swept angular configurations. In various cases, whichever of such swept angular configurations causes the contour 2302 to have a lowest area can be treated as the new angular configuration 2002.

In various embodiments, the execution component 334 can electronically perform or electronically initiate any suitable electronic actions based on the new angular configuration 2002. As a non-limiting example, the execution component 334 can electronically instruct, electronically command, or otherwise electronically cause the robotic gripper 308 to move to or take on the new angular configuration 2002. As another non-limiting example, the execution component 334 can electronically mark or electronically flag (e.g., in any suitable database or data structure) the new angular configuration 2002 as being angularly aligned with the bore 404 of the microscopy grid receptacle 306. For instance, in some cases, the execution component 334 can electronically inform the charged-particle microscope 302 that the new angular configuration 2002 has been determined or verified to be angularly aligned with the bore 404 of the microscopy grid receptacle 306. Accordingly, the charged-particle microscope 302 can be considered as now knowing, for future reference, how to make the robotic gripper 308 angularly aligned with the bore 404 of the microscopy grid receptacle 306.

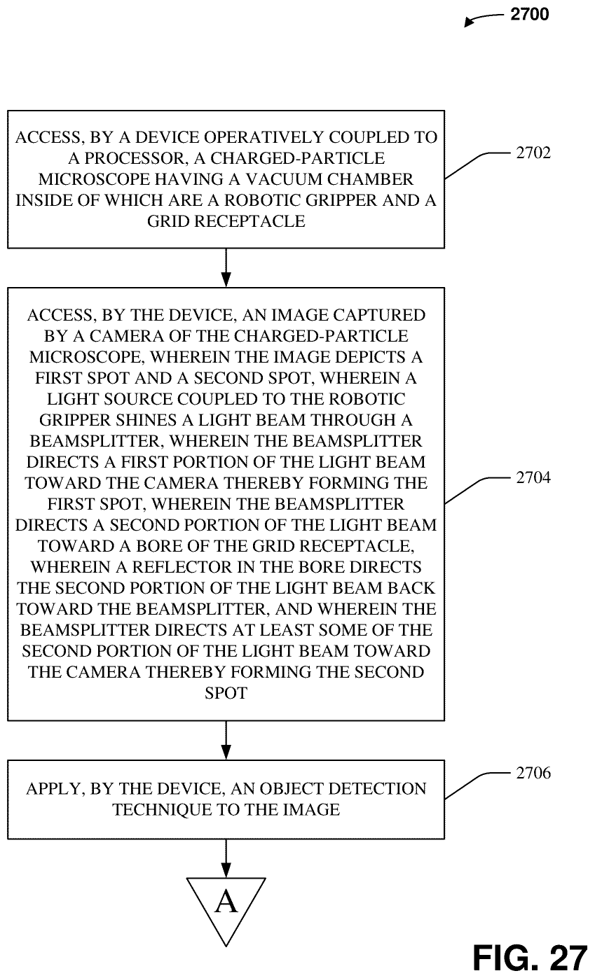

FIGS. 27-30 illustrate flow diagrams of example, non-limiting computer-implemented methods 2700, 2800, 2900, and 3000 that can facilitate teaching of charged-particle microscopy robotic grippers via beamsplitting in accordance with one or more embodiments described herein. In various cases, the system 322 can facilitate or perform the computer-implemented methods 2700, 2800, 2900, or 3000.

First, consider FIG. 27. In various embodiments, act 2702 can include accessing, by a device (e.g., via 328) operatively coupled to a processor (e.g., 324), a charged-particle microscope (e.g., 302) having a vacuum chamber (e.g., 304) inside of which are a robotic gripper (e.g., 308) and a grid receptacle (e.g., 306).

In various aspects, act 2704 can include accessing, by the device (e.g., via 328), an image (e.g., 1302) captured by a camera (e.g., 320) of the charged-particle microscope, wherein the image can depict a first spot (e.g., 1304) and a second spot (e.g., 1306), wherein a light source (e.g., 312) coupled to the robotic gripper can shine a light beam (e.g., 502) through a beamsplitter (e.g., 316), wherein the beamsplitter can direct a first portion (e.g., 804) of the light beam toward the camera thereby forming the first spot, wherein the beamsplitter can direct a second portion (e.g., 902) of the light beam toward a bore (e.g., 404) of the grid receptacle, wherein a reflector (e.g., 318) in the bore can direct the second portion of the light beam back toward the beamsplitter, and wherein the beamsplitter can direct at least some (e.g., 1204) of the second portion of the light beam toward the camera thereby forming the second spot.

In various instances, act 2706 can include applying, by the device (e.g., via 330), an object detection technique (e.g., 1802) to the image. In various cases, the computer-implemented method 2700 can proceed to act 2802 of the computer-implemented method 2800.

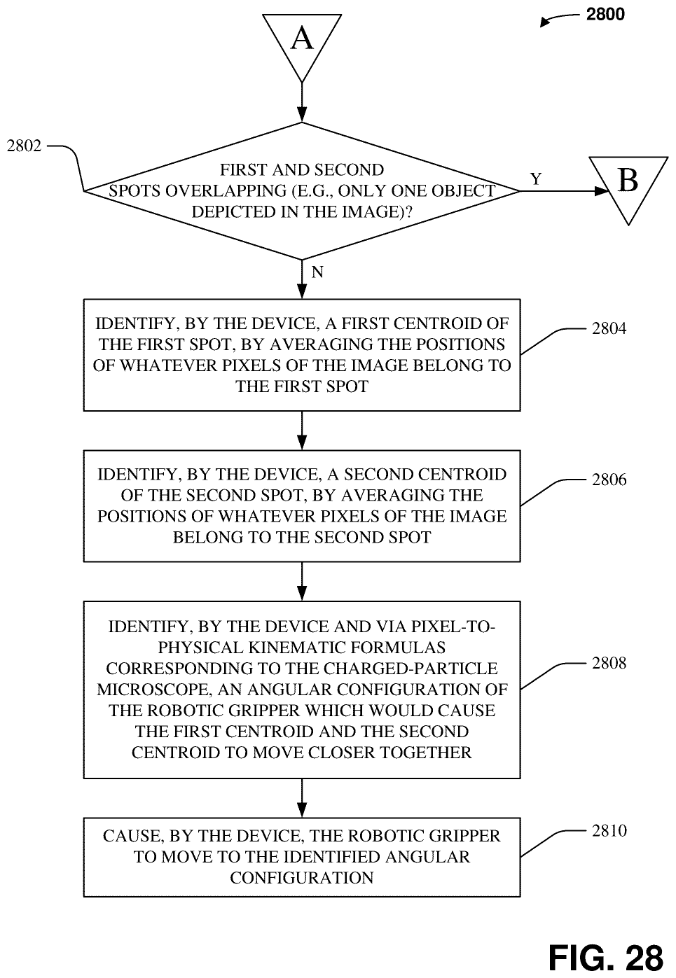

Now, consider FIG. 28. In various embodiments, act 2802 can include determining, by the device (e.g., via 332), whether the first and second spots overlap each other. In other words, the device can determine, via the object detection technique, whether the image depicts two separate objects or only one single object. If the first and second spots are overlapping (e.g., if the object detection technique recognizes only one single object in the image), the computer-implemented method 2800 can proceed to act 2902 of the computer-implemented method 2900. Instead, if the first and second spots are not overlapping (e.g., if the object detection technique recognizes two distinct or separate objects in the image), the computer-implemented method 2800 can proceed to act 2804.

In various aspects, act 2804 can include identifying, by the device (e.g., via 332), a first centroid (e.g., 2102) of the first spot, by averaging the positions of whatever pixels of the image belong to the first spot.

In various instances, act 2806 can include identifying, by the device (e.g., via 332), a second centroid (e.g., 2104) of the second spot, by averaging the positions of whatever pixels of the image belong to the second spot.

In various cases, act 2808 can include identifying, by the device (e.g., via 332) and via pixel-to-physical kinematic formulas corresponding to the charged-particle microscope, an angular configuration (e.g., 2002) of the robotic gripper which would cause the first centroid and the second centroid to move closer together.

In various aspects, act 2810 can include causing, by the device (e.g., via 334), the robotic gripper to move to the identified angular configuration.

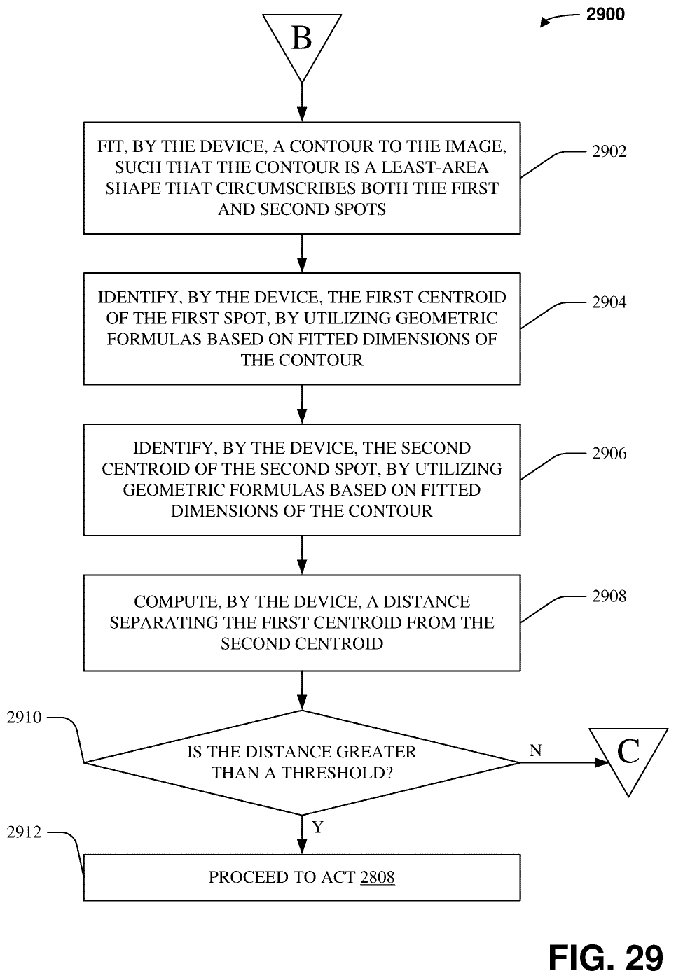

Next, consider FIG. 29. In various embodiments, act 2902 can include fitting, by the device (e.g., via 332), a contour (e.g., 2302) to the image, such that the contour is a least-area shape that circumscribes both the first and second spots.

In various aspects, act 2904 can include identifying, by the device (e.g., via 332), the first centroid of the first spot, by utilizing geometric formulas based on fitted dimensions of the contour.

In various instances, act 2906 can include identifying, by the device (e.g., via 332), the second centroid of the second spot, by utilizing geometric formulas based on fitted dimensions of the contour.

In various cases, act 2908 can include computing, by the device (e.g., via 332), a distance (e.g., 2304) separating the first centroid from the second centroid.

In various aspects, act 2910 can include determining, by the device (e.g., via 332), whether the distance is greater than a threshold. If the distance is not greater than the threshold, the computer-implemented method 2900 can proceed to act 3002 of the computer-implemented method 3000. Instead, if the distance is greater than the threshold, the computer-implemented method 2900 can proceed to act 2912.

In various instances, act 2912 can include proceeding, by the device (e.g., via 332), to act 2808 of the computer-implemented method 2800.

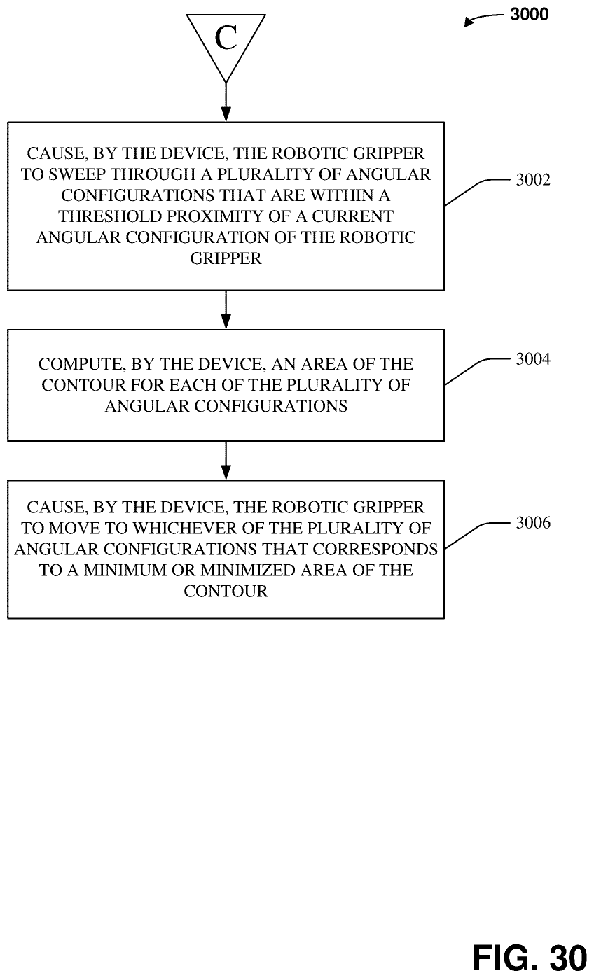

Now, consider FIG. 30. In various embodiments, act 3002 can include causing, by the device (e.g., via 332), the robotic gripper to sweep through a plurality of angular configurations (e.g., 2402) that are within a threshold proximity of a current angular configuration of the robotic gripper.

In various aspects, act 3004 can include computing, by the device (e.g., via 332), an area (e.g., respective one of 2404) of the contour for each of the plurality of angular configurations.

In various instances, act 3006 can include causing, by the device (e.g., via 334), the robotic gripper to move to whichever of the plurality of angular configurations that corresponds to a minimum or minimized area of the contour (e.g., 2002).

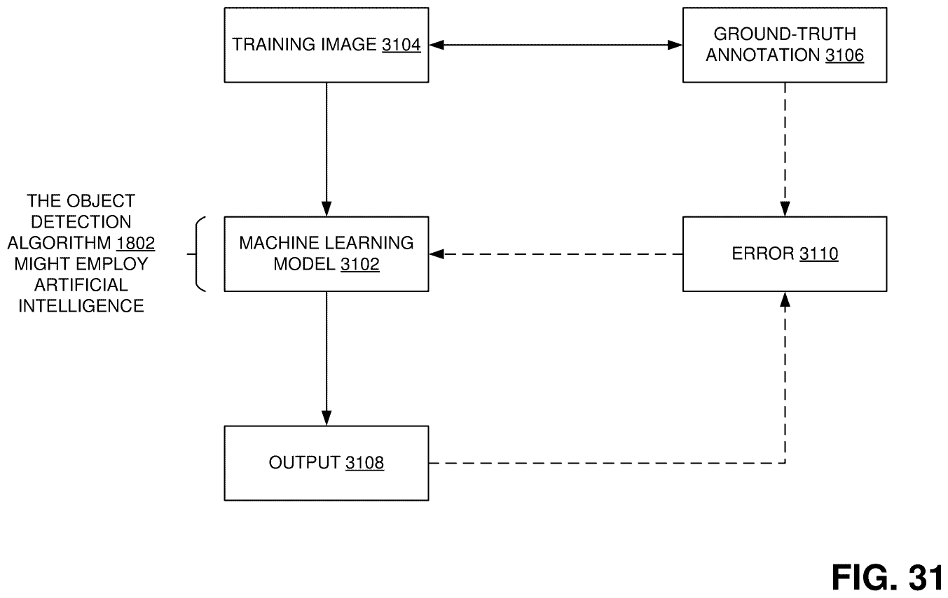

As described herein, various embodiments can be implemented via machine learning or artificial intelligence (e.g., the object detection algorithm 1802 can be a deep learning neural network; the correction component 332 can utilize a deep learning neural network to generate the contour 2302). In order for such embodiments to operate reliably, such machine learning or artificial intelligence can first undergo training. A non-limiting example of such training is described with respect to FIG. 31.

FIG. 31 illustrates an example, non-limiting block diagram showing how a machine learning model can be trained in accordance with one or more embodiments described herein.

In various aspects, there can be a machine learning model 3102. In various instances, the machine learning model 3102 can exhibit any suitable internal architecture as mentioned above (e.g., input layer, hidden layers, and output layer, any of which can be convolutional layers, LSTM layers, dense layers, or non-linearity layers, and any of which can be coupled by any suitable interlayer connections such as forward connections, recurrent connections, or skip connections). In some cases, the machine learning model 3102 can be considered as a neural network that facilitates the object detection algorithm 1802. In other cases, the machine learning model 3102 can be considered as a neural network that can compute the contour 2302. In any case, prior to beginning training, the trainable internal parameters (e.g., convolutional kernels, weight matrices, bias values) of the machine learning model 3102 can be initialized in any suitable fashion (e.g., via random initialization).

In various embodiments, there can be a training image 3104 and a ground-truth annotation 3106. If the machine learning model 3102 is designed, intended, or configured to facilitate the object detection algorithm 1802, then the training image 3104 can be any suitable image having the same format, size, or dimensionality as the image 1302 and depicting any two illuminated spots that might or might not be overlapping with each other, and the ground-truth annotation 3106 can be whatever correct or accurate object tally (e.g., correct or accurate number of distinct, separate objects) that are known or deemed to be depicted or illustrated in the training image 3104. If the machine learning model 3102 is instead designed, intended, or configured to facilitate contour fitting, then the training image 3104 can be any suitable image having the same format, size, or dimensionality as the image 1302 and depicting any two illuminated spots that are overlapping with each other, and the ground-truth annotation 3106 can be whatever correct or accurate contour having the same shape as the contour 2302 that is known or deemed to be of least-area and to be circumscribing both the illuminated spots depicted in the training image 3104.

In any case, the machine learning model 3102 can be executed on the training image 3104, thereby causing the machine learning model 3102 to produce an output 3108. For example, in some cases, the training image 3104 can be fed or routed to an input layer of the machine learning model 3102, the training image 3104 can complete a forward pass through one or more hidden layers of the machine learning model 3102, and an output layer of the machine learning model 3102 can compute the output 3108 based on activation maps or feature maps provided by the one or more hidden layers of the machine learning model 3102.

Note that the format, size, or dimensionality of the output 3108 can be dictated by the number, arrangement, sizes, or other characteristics of the neurons, convolutional kernels, LSTM layers, or other internal parameters of the output layer (or of any other layers) of the machine learning model 3102. Accordingly, the output 3108 can be forced to have any desired format, size, or dimensionality, by adding, removing, or otherwise adjusting characteristics of the output layer (or of any other layers) of the machine learning model 3102.

In various aspects, if the machine learning model 3102 is designed, configured, or intended to facilitate the object detection algorithm 1802, then the output 3108 can be considered as the predicted or inferred object tally that the machine learning model 3102 believes should correspond to the training image 3104. If the machine learning model 3102 is instead designed, configured, or intended to facilitate contour fitting, then the output 3108 can be considered as the predicted or inferred least-area, spot-circumscribing contour that the machine learning model 3102 believes should correspond to the training image 3104. Note that, if the machine learning model 3102 has so far undergone no or little training, then the output 3108 can be highly inaccurate. In other words, the output 3108 can be very different from the ground-truth annotation 3106.

In various aspects, an error 3110 (e.g., mean absolute error, mean squared error, cross-entropy error) between the output 3108 and the ground-truth annotation 3106 can be computed. In various instances, the trainable internal parameters of the machine learning model 3102 can be incrementally updated via backpropagation (e.g., stochastic gradient descent) based on the error 3110.

In various cases, such execution-and-update procedure can be repeated for any suitable number of training images. This can ultimately cause the trainable internal parameters of the machine learning model 3102 to become iteratively optimized for accurately performing its inferencing task (e.g., object tallying, or contour fitting). In various aspects, any suitable training batch sizes, any suitable error/loss functions, or any suitable training termination criteria can be utilized during such training.

Although the herein disclosure mainly describes the machine learning model 3102 as being trained in supervised fashion, this is a mere non-limiting example for ease of explanation and illustration. In various embodiments, any other suitable training paradigms can be used to train the machine learning model 3102, such as unsupervised training or reinforcement learning, any of which may be federated or non-federated.

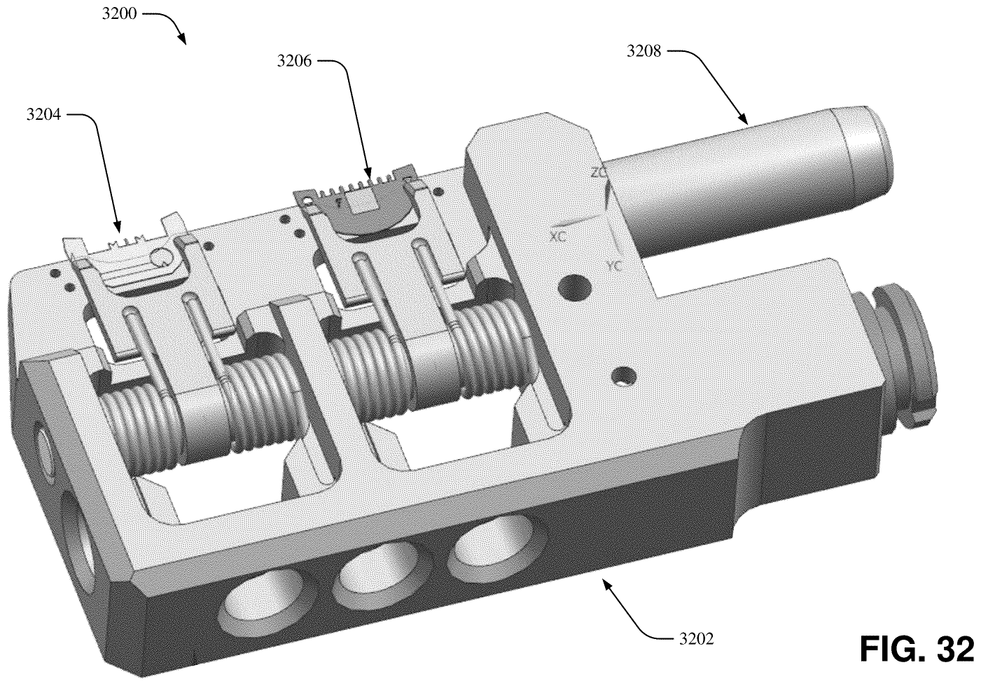

FIGS. 32-36 illustrate example, non-limiting images of various experimental reductions to practice in accordance with one or more embodiments described herein.

First, consider FIG. 32. FIG. 32 shows a computer-aided design drawing 3200 of a grid holder 3202. The grid holder 3202 can be considered as a structural accessory that can physically hold, carry, or support two microscopy grids: a first grid at a location indicated by numeral 3204; and a second grid at a location indicated by numeral 3206. As shown, there is a shaft 3208 that protrudes from the grid holder 3202. In various aspects, the robotic gripper 308 can grip or hold the grid holder 3202. When the robotic gripper 308 grips or holds the grid holder 3202, the shaft 3208 can be considered as running longitudinally along the shaft-axis 402. It should be noted that the entire mass of the grid holder 3202, when equipped with two microscopy grids, can be about 1.3 grams, as measured by the present inventors.

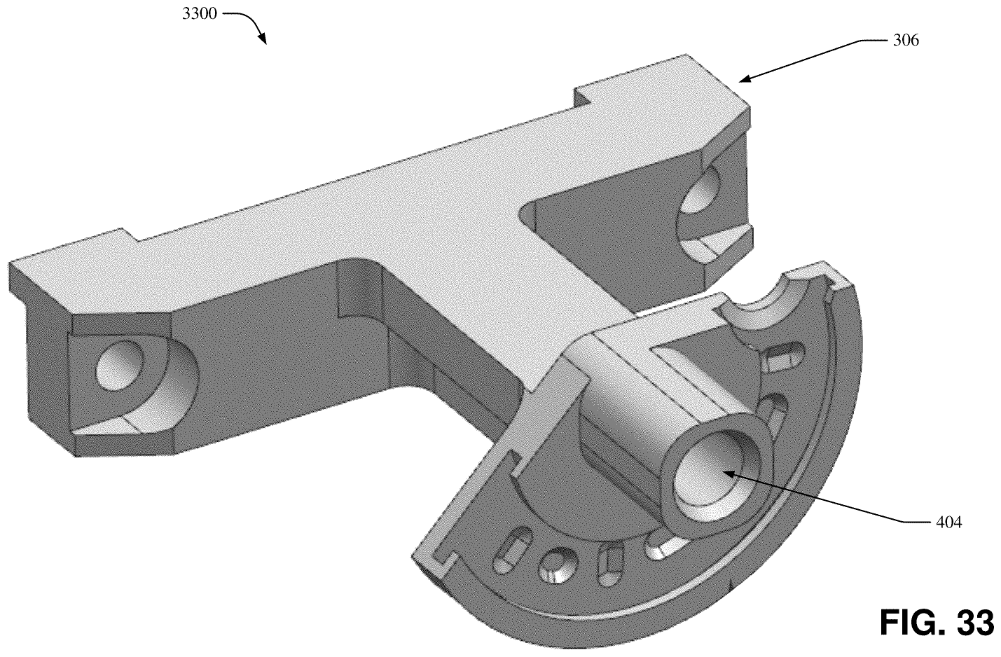

Now, consider FIG. 33. FIG. 33 shows a computer-aided design drawing 3300 of a non-limiting example embodiment of the microscopy grid receptacle 306. As shown, the microscopy grid receptacle 306 can have the bore 404. The shaft 3208 can be sized so as to slidably fit inside of the bore 404. When the shaft 3208 is slidably inserted into the bore 404, the grid holder 3202 can be considered as being temporarily affixed to the microscopy grid receptacle 306. Because there can be very tight clearance between the shaft 3208 and the bore 404, it can be desired to teach the robotic gripper 308 how to angularly align the shaft 3208 (e.g., the shaft-axis 402) with the bore 404 (e.g., with the bore-axis 406).

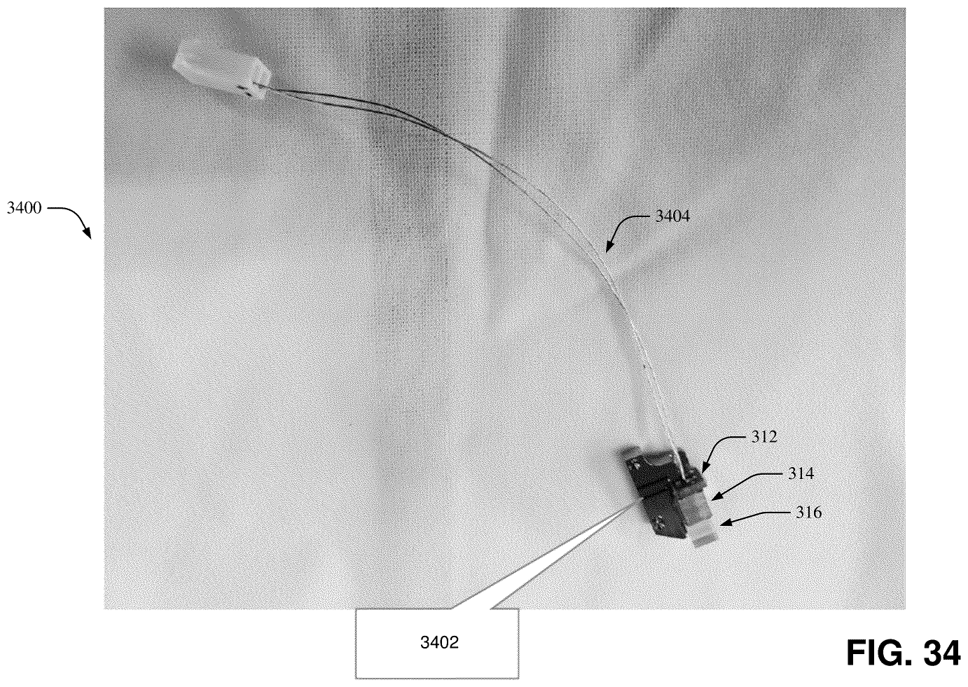

Next, consider FIG. 34. FIG. 34 shows a photograph 3400 of a prototype built by the present inventors in accordance with various embodiments described herein. As shown, the prototype includes the light source 312 (e.g., includes a printed circuit board on which the light source 312 is fabricated), the collimator lens 314 (e.g., includes a metal block or casing that contains the collimator lens 314), and the beamsplitter 316, all coupled together via a mounting bracket 3402. As also shown, the light source 312 can be powered by electric wires 3404.

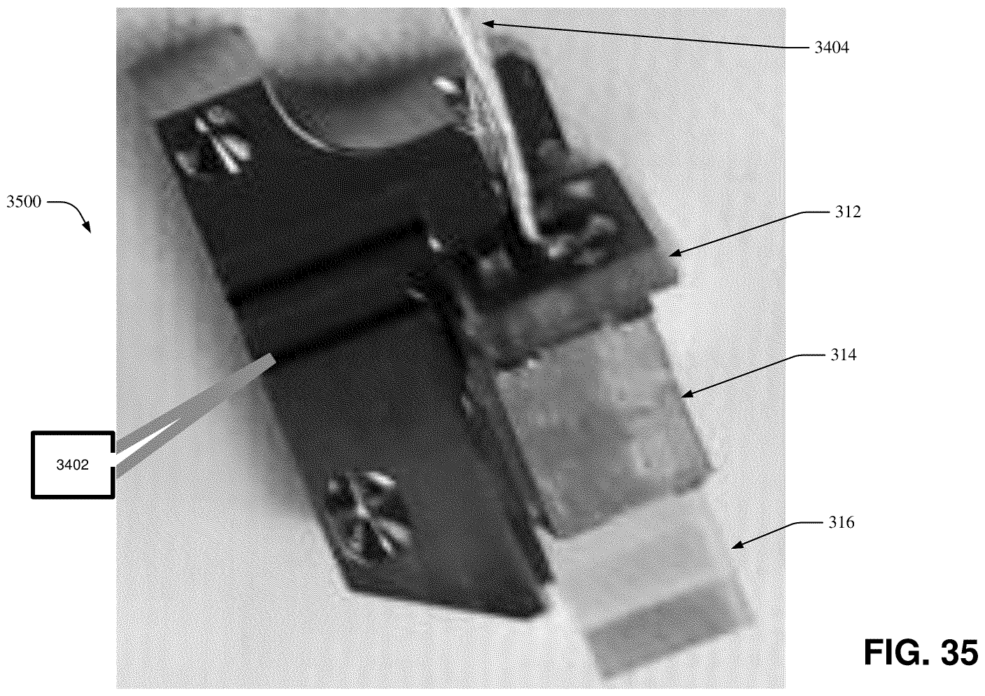

FIG. 35 depicts a zoomed view of the light source 312, the collimator lens 314, and the beamsplitter 316 being mounted on the mounting bracket 3402. The particular configuration shown in FIG. 35 had a total mass of 2 grams, as measured by the present inventors. Note that such 2-gram mass can be considered as being comparable to (e.g., on the same order of magnitude as) the 1.3-gram mass of the grid holder 3202. Accordingly, the robotic gripper 308 can be considered as not experiencing significantly more deflection when holding or gripping the configuration shown in FIG. 35 than when holding or gripping the grid holder 3202. In stark contrast, most available miniature cameras or borescopes, which are required to be held or gripped by some existing techniques, weigh tens of grams, which can cause the robotic gripper 308 to experience significantly more deflection as compared to holding or gripping the grid holder 3202.

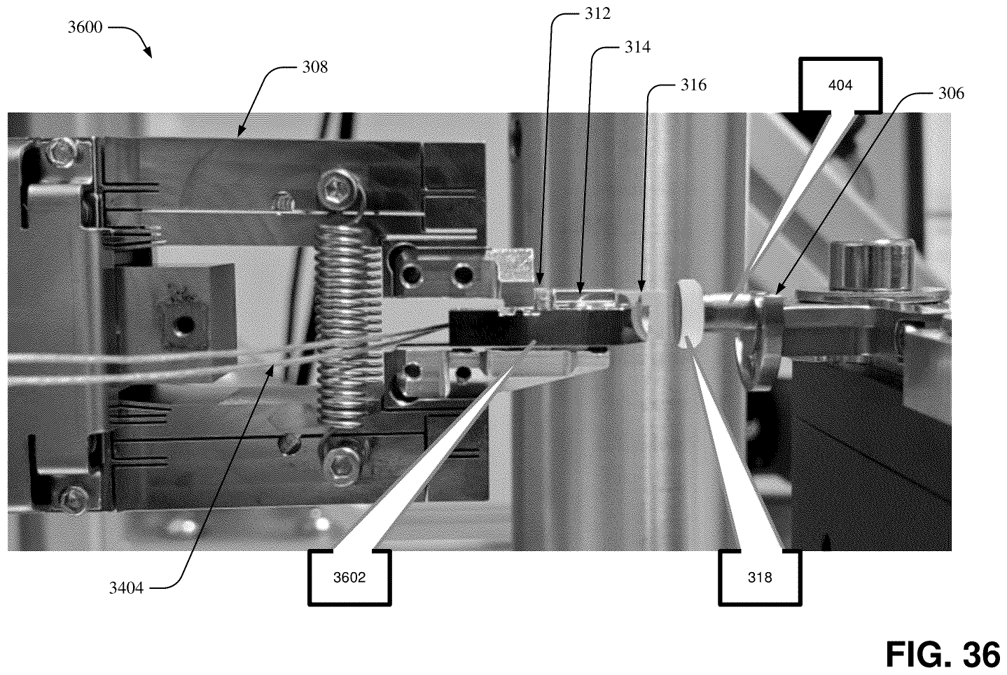

Lastly, consider FIG. 36. FIG. 36 shows (via a numeral 3602) the light source 312, the collimator lens 314, and the beamsplitter 316 (all mounted on the now-obscured mounting bracket 3402) being gripped or held by a non-limiting example embodiment of the robotic gripper 308. FIG. 36 also shows a non-limiting example embodiment of the reflector 318 being affixed perpendicularly to the outside of the bore 404 of the microscopy grid receptacle 306. As shown in FIG. 36, the light source 312, the collimator lens 314, and the beamsplitter 316 can be considered as being aimed at the reflector 318. Thus, light beams generated by the light source 312 can be passed or reflected by the beamsplitter 316 and by the reflector 318, as described with respect to FIGS. 4-12.

FIG. 36 can be considered as depicting a real-world experimental setup of various embodiments described herein. The present inventors verified that such real-world experimental setup achieved angular alignment between the robotic gripper 308 and the bore 404 to less than 1 arcsecond per pixel of resolution, which can be considered as highly precise angularly alignment. Such experimental setup validates the concrete, real-world technical benefits achieved by various embodiments described herein.

Although the herein disclosure has mainly described various embodiments that can cause the shaft-axis 402 to become angularly aligned (e.g., parallel) with the bore-axis 406, these are mere non-limiting examples. In some instances, various embodiments described herein can also be implemented so as to cause the shaft-axis 402 to become translationally aligned (e.g., colinear) with the bore-axis 406. In various aspects, as mentioned above, angular alignment between the shaft-axis 402 and the bore-axis 406 can depend upon θ_{X} and ez (e.g., can depend upon the values or states of the selectively controllable pitch and yaw settings/parameters of the robotic gripper 308). In contrast, translational alignment between the shaft-axis 402 and the bore-axis 406 can depend upon P_{X} and P_{Z} (e.g., can depend upon the values or states of the selectively controllable X-displacement and Z-displacement settings/parameters of the robotic gripper 308).

In various cases, the reflector 318 can have a reflectance that varies spatially. In other words, the amount or intensity of incident light that the reflector 318 reflects can be spatially non-uniform, depending upon where such incident light strikes the reflector. In various cases, such non-uniform reflectance can visually manifest in the intensity of the illuminated spot 1306. In other words, when given the non-uniform reflectance variation of the reflector 318, and when given the current or present-time intensity of the illuminated spot 1306, the correction component 332 can determine, identify, or otherwise infer where the light beam 902 (and thus the shaft-axis 402) is striking on the surface of the reflector 318. The correction component 332 can accordingly sweep the robotic gripper 308 through any suitable range of translational configurations (e.g., through any suitable range of values or states of P_{X} and P_{Z}) that is centered about the current or present-time translational configuration (e.g., centered about the current or present-time values of P_{X} and P_{Z}). For each of those swept translational configurations, the correction component 332 can measure the intensity (e.g., maximum or average intensity) of the illuminated spot 1306. In various instances, the center of the surface of the reflector 318 can have or be associated with a unique or distinctive reflectance. Accordingly, whichever of the swept translational configurations causes the intensity of the illuminated spot 1306 to reach or approach whatever intensity value would be expected to be caused by the unique or distinctive reflectance of the center of the reflector 318 can be considered as achieving translational alignment between the shaft-axis 402 and the bore-axis 406.

As a non-limiting example, the reflector 318 can comprise a plurality of annular reflection rings, each ring having a lower reflectance than the adjacent ring that is located radially inward of it, and each ring having a greater reflectance than the adjacent ring that is positioned radially outward of it. Thus, the reflectance of the reflector 318 can be considered as being at some maximum value at the center of its surface, and as progressively declining radially outwards from that center. In such case, the correction component 332 can determine that translational alignment has been achieved, whenever the intensity of the illuminated spot 1306 is above whatever threshold value is associated with the maximum reflectance of the center of the reflector 318. In contrast, the correction component 332 can determine that translational alignment has not yet been achieved, whenever the intensity of the illuminated spot 1306 is less than whatever threshold value is associated with the maximum reflectance of the center of the reflector 318.

In some cases, the above-described intensity-based technique of utilizing the image 1302 and a spatially-varying reflectance of the reflector 318 can be combined with the following touch-alarm technique, so as to achieve even more precise translational alignment between the shaft-axis 402 and the bore-axis 406. In various aspects, the touch-alarm technique can be implemented after performance of the above-described intensity-based technique. More specifically, the touch-alarm technique can involve: coupling to the robotic gripper 308 a touch-alarm shaft that runs longitudinally along the shaft-axis 402 and whose radius is smaller than that of a shaft that protrudes from a microscopy grid; and electrically biasing the robotic gripper 308 and the microscopy grid receptacle 306 at different electrical voltages (e.g., the robotic gripper 308 can be electrically grounded, and the microscopy grid receptacle 306 can be electrically biased at 0.5 volts). In such case, the robotic gripper 308 can move to whatever translational configuration is deemed by the above-described intensity-based technique as achieving translational alignment between the shaft-axis 402 and the bore-axis 406, the robotic gripper 308 can incrementally translate upward from that translational configuration until electrical continuity is detected between the robotic gripper 308 and the microscopy grid receptacle 306 (e.g., until the touch-alarm shaft makes physical contact with the inner surface of the bore 404), and the spatial coordinates of the robotic gripper 308 when such electrical continuity is detected can be considered as marking an upper translational alignment bound. Likewise, the robotic gripper 308 can move to whatever translational configuration is deemed by the above-described intensity-based technique as achieving translational alignment between the shaft-axis 402 and the bore-axis 406, the robotic gripper 308 can incrementally translate downward from that translational configuration until electrical continuity is detected between the robotic gripper 308 and the microscopy grid receptacle 306, and the spatial coordinates of the robotic gripper 308 when such electrical continuity is detected can be considered as marking a lower translational alignment bound. Similarly, the robotic gripper 308 can move to whatever translational configuration is deemed by the above-described intensity-based technique as achieving translational alignment between the shaft-axis 402 and the bore-axis 406, the robotic gripper 308 can incrementally translate rightward from that translational configuration until electrical continuity is detected between the robotic gripper 308 and the microscopy grid receptacle 306, and the spatial coordinates of the robotic gripper 308 when such electrical continuity is detected can be considered as marking a rightward translational alignment bound. In this same fashion, the robotic gripper 308 can move to whatever translational configuration is deemed by the above-described intensity-based technique as achieving translational alignment between the shaft-axis 402 and the bore-axis 406, the robotic gripper 308 can incrementally translate leftward from that translational configuration until electrical continuity is detected between the robotic gripper 308 and the microscopy grid receptacle 306, and the spatial coordinates of the robotic gripper 308 when such electrical continuity is detected can be considered as marking a leftward translational alignment bound. Accordingly, the center or midpoint of the upper translational alignment bound, the lower translational alignment bound, the rightward translational alignment bound, and the leftward translational alignment bound can be considered as being the precise center of the bore 404. Thus, precise translational alignment can be achieved by causing the robotic gripper 306 to place the shaft-axis 402 at the center or midpoint.

Although the herein disclosure mainly describes various embodiments in which angular misalignment between the shaft-axis 402 and the bore-axis 406 is indicated by the illuminated spot 1304 and the illuminated spot 1306 not being concentric, and in which angular alignment between the shaft-axis 402 and the bore-axis 406 is indicated by the illuminated spot 1304 and the illuminated spot 1306 being concentric, these are mere non-limiting examples for ease of explanation. It should be understood and appreciated that, although some applications or uses of the charged-particle microscope 302 can require or necessitate that the shaft-axis 402 and the bore-axis 406 be aligned in both a pitch direction and yaw direction, other applications or uses of the charged-particle microscope 302 can require or necessitate that the shaft-axis 402 and the bore-axis 406 be aligned in only one of the pitch direction and the yaw direction (e.g., aligned in pitch but not yaw; or aligned in yaw but not pitch). These applications or uses can be considered as requiring only partial angular alignment between the shaft-axis 402 and the bore-axis 406. In various cases, the system 322 can achieve such partial angular alignment by identifying (e.g., via any suitable pixel-to-physical kinematic formulations) angular configurations of the robotic gripper 308 that cause the illuminated spot 1304 and the illuminated spot 1306 to achieve some specific but non-concentric layout or arrangement with respect to each other.

As a non-limiting example, suppose without loss of generality that: adjusting the pitch of the robotic gripper 304 changes the intra-image pixel row coordinates of the centroid 2102 and the centroid 2104; and adjusting the yaw of the robotic gripper 304 changes the intra-image pixel column coordinates of the centroid 2102 and the centroid 2104. In such case, adjusting the angular configuration of the robotic gripper 308 so as to cause the illuminated spot 1304 and the illuminated spot 1306 to become concentric can be considered as equivalent to causing the centroid 2102 and the centroid 2104 to have the same intra-image pixel row and column coordinates as each other. Now, some applications or usages of the charged-particle microscope 302 can require only pitch angular alignment. Such pitch angular alignment can be achieved by identifying (e.g., via any suitable pixel-to-physical kinematic formulations) an angular configuration of the robotic gripper 308 that causes the centroid 2102 and the centroid 2104 to have the same intra-image pixel row coordinate as each other, regardless of their intra-image pixel column coordinates. Thus, partial angular alignment (e.g., aligned in pitch but not in yaw) can be achieved in this example, not by causing the illuminated spot 1304 and the illuminated spot 1306 to be concentric, but by instead causing their centroids to have the same intra-image pixel row coordinate as each other. Conversely, other applications or usages of the charged-particle microscope 302 can require only yaw angular alignment. Such yaw angular alignment can be achieved by identifying (e.g., via any suitable pixel-to-physical kinematic formulations) an angular configuration of the robotic gripper 308 that causes the centroid 2102 and the centroid 2104 to have the same intra-image pixel column coordinate as each other, regardless of their intra-image pixel row coordinates. So, partial angular alignment (e.g., aligned in yaw but not in pitch) can be achieved in this example, not by causing the illuminated spot 1304 and the illuminated spot 1306 to be concentric, but by instead causing their centroids to have the same intra-image pixel column coordinate as each other.

As mentioned above, various embodiments described herein can involve the contour 2302 being an ellipse that circumscribes both the illuminated spot 1304 and the illuminated spot 1306. In such situations, full angular alignment can be achieved by identifying (e.g., via any suitable pixel-to-physical kinematic formulas) an angular configuration that causes an ellipticity (e.g., ratio of polar radius to equatorial radius) of the contour 2302 to approach (e.g., to get within any suitable threshold margin of) 1.

The scientific instrument systems, methods, or techniques disclosed herein may include interactions with a human user (e.g., via a user local computing device 3920 discussed herein with reference to FIG. 39). These interactions may include providing information to the user (e.g., information regarding the operation of a scientific instrument such as the scientific instrument 3910 of FIG. 39, information regarding a sample being analyzed or other test or measurement performed by a scientific instrument, information retrieved from a local or remote database, or other information) or providing an option for a user to input commands (e.g., to control the operation of a scientific instrument such as the scientific instrument 3910 of FIG. 39, or to control the analysis of data generated by a scientific instrument), queries (e.g., to a local or remote database), or other information. In some embodiments, these interactions may be performed through a graphical user interface (GUI) that includes a visual display on a display device (e.g., a display device 3810 discussed herein with reference to FIG. 38) that provides outputs to the user and/or prompts the user to provide inputs (e.g., via one or more input devices, such as a keyboard, mouse, trackpad, or touchscreen, included in other I/O devices 3812 discussed herein with reference to FIG. 38). The scientific instrument systems, methods, or techniques disclosed herein may include any suitable GUls for interaction with a user.

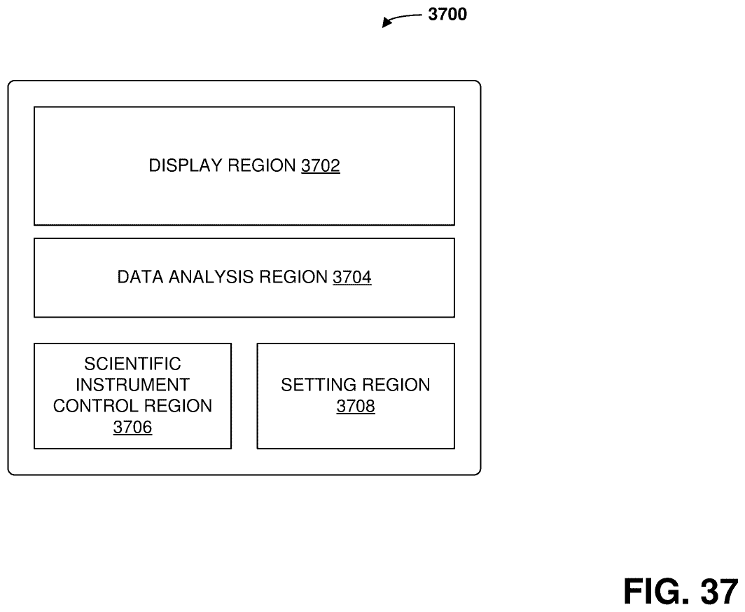

FIG. 37 depicts an example graphical user interface 3700 (hereafter “GUI 3700”) that can be used in the performance of some or all of the support methods or techniques disclosed herein, in accordance with various embodiments. In various aspects, the GUI 3700 can be provided on any suitable electronic display (e.g., a display device 3810 discussed herein with reference to FIG. 38) of a computing device (e.g., a computing device 3800 discussed herein with reference to FIG. 38) of a scientific instrument support system (e.g., a scientific instrument support system 3900 discussed herein with reference to FIG. 39), and a user or technician can interact with the GUI 3700 using any suitable input device (e.g., any of other I/O devices 3812 discussed herein with reference to FIG. 38) and input technique (e.g., movement of a cursor, motion capture, facial recognition, gesture detection, voice recognition, actuation of buttons).

The GUI 3700 can include a data display region 3702, a data analysis region 3704, a scientific instrument control region 3706, and a setting region 3708. The particular number and arrangement of regions depicted in FIG. 37 is merely illustrative, and any number and arrangement of regions, including any desired features, can be included in other embodiments of the GUI 3700.

The data display region 3702 can display data generated by a scientific instrument (e.g., a scientific instrument 3910 discussed herein with reference to FIG. 39).

The data analysis region 3704 can display any suitable data analysis results (e.g., the results of analyzing the data illustrated in the data display region 3702 or other data). In some embodiments, the data display region 3702 and the data analysis region 3704 can be combined in the GUI 3700 (e.g., to include both data output from a scientific instrument and some analysis of the data in a common graph or region).

The scientific instrument control region 3706 can include options that allow a user or technician to control a scientific instrument (e.g., the scientific instrument 3910 discussed herein with reference to FIG. 39). For example, the scientific instrument control region 3706 can include configurable parameters that govern operation of such scientific instrument (e.g., configurable parameters that govern voltages or electric currents of the scientific instrument, that govern interior temperatures of the scientific instrument, or that govern fluid flow rates of the scientific instrument).

The setting region 3708 can include options that allow a user or technician to control any features or functions of the GUI 3700 (or of other GUIs) or to perform common computing operations with respect to the data display region 3702 and the data analysis region 3704 (e.g., saving data on a storage device, such as the storage device 3804 discussed herein with reference to FIG. 38, sending data to another user, labeling data).

As noted above, the scientific instrument module 102 can be implemented by one or more computing devices. FIG. 38 is a block diagram of a computing device 3800 that can perform some or all of the scientific instrument methods or techniques disclosed herein, in accordance with various embodiments. In some embodiments, the scientific instrument module 102 can be implemented by a single instance of the computing device 3800 or by multiple instances of the computing device 3800. Further, as discussed below, the computing device 3800 (or multiple instances thereof) that implements the scientific instrument module 102 can be part of one or more of a scientific instrument 3910, a user local computing device 3920, a service local computing device 3930, or a remote computing device 3940 of FIG. 39.

The computing device 3800 is illustrated as having a number of components, but any one or more of these components can be omitted or duplicated, as suitable for the application and setting. In some embodiments, some or all of the components included in the computing device 3800 can be attached to one or more motherboards and enclosed in a housing (e.g., including plastic, metal, or other materials). In some embodiments, some these components can be fabricated onto a single system-on-a-chip (SoC) (e.g., an SoC may include one or more instances of a processing device 3802 and one or more instances of a storage device 3804). Additionally, in various embodiments, the computing device 3800 can omit one or more of the components illustrated in FIG. 38, but can include interface circuitry (not shown) for coupling to the one or more omitted components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 3800 can omit a display device 3810, but can include display device interface circuitry (e.g., a connector and driver circuitry) to which a display device 3810 can be coupled.

The computing device 3800 can include a processing device 3802 (e.g., one or more processing devices). As used herein, the term “processing device” can refer to any device or portion of a device that processes electronic data from registers or memory to transform that electronic data into other electronic data that may be stored in registers or memories. The processing device 3802 can include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 3800 can include a storage device 3804 (e.g., one or more storage devices). The storage device 3804 can include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 3804 can include memory that shares a die with a processing device 3802. In such an embodiment, the memory may be used as cache memory and may include embedded dynamic random access memory (eDRAM) or spin transfer torque magnetic random access memory (STT-MRAM), for example. In some embodiments, the storage device 3804 can include non-transitory computer readable media having instructions thereon that, when executed by one or more processing devices (e.g., the processing device 3802), cause the computing device 3800 to perform any appropriate ones of or portions of the methods disclosed herein.

The computing device 3800 can include an interface device 3806 (e.g., one or more instances of the interface device 3806). The interface device 3806 can include one or more communication chips, connectors, or other hardware and software to govern communications between the computing device 3800 and other computing devices. For example, the interface device 3806 can include circuitry for managing wireless communications for the transfer of data to and from the computing device 3800. The term “wireless” and its derivatives may be used to describe circuits, devices, systems, methods, techniques, or communications channels that may communicate data through the use of modulated electromagnetic radiation through a nonsolid medium. The term does not imply that the associated devices do not contain any wires, although in some embodiments they might not. Circuitry included in the interface device 3806 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”)). In some embodiments, circuitry included in the interface device 3806 for managing wireless communications can operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 3806 for managing wireless communications can operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 3806 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 3806 may include one or more antennas (e.g., one or more antenna arrays) to receipt and/or transmission of wireless communications.

In some embodiments, the interface device 3806 can include circuitry for managing wired communications, such as electrical, optical, or any other suitable communication protocols. For example, the interface device 3806 can include circuitry to support communications in accordance with Ethernet technologies. In some embodiments, the interface device 3806 can support both wireless and wired communication, or can support multiple wired communication protocols or multiple wireless communication protocols. For example, a first set of circuitry of the interface device 3806 may be dedicated to shorter-range wireless communications such as Wi-Fi or Bluetooth, and a second set of circuitry of the interface device 3806 may be dedicated to longer-range wireless communications such as global positioning system (GPS), EDGE, GPRS, CDMA, WiMAX, LTE, EV-DO, or others. In some embodiments, a first set of circuitry of the interface device 3806 can be dedicated to wireless communications, and a second set of circuitry of the interface device 3806 can be dedicated to wired communications.

The computing device 3800 can include battery/power circuitry 3808. The battery/power circuitry 3808 can include one or more energy storage devices (e.g., batteries or capacitors) or circuitry for coupling components of the computing device 3800 to an energy source separate from the computing device 3800 (e.g., alternating current line power).

The computing device 3800 can include a display device 3810 (e.g., multiple display devices). The display device 3810 can include any visual indicators, such as a heads-up display, a computer monitor, a projector, a touchscreen display, a liquid crystal display (LCD), a light-emitting diode display, or a flat panel display.

The computing device 3800 can include other input/output (I/O) devices 3812. The other I/O devices 3812 can include one or more audio output devices (e.g., speakers, headsets, earbuds, alarms), one or more audio input devices (e.g., microphones or microphone arrays), location devices (e.g., GPS devices in communication with a satellite-based system to receive a location of the computing device 3800), audio codecs, video codecs, printers, sensors (e.g., thermocouples or other temperature sensors, humidity sensors, pressure sensors, vibration sensors, accelerometers, gyroscopes), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 3800 can have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer), a desktop computing device, or a server computing device or other networked computing component.

One or more computing devices implementing any of the scientific instrument modules, methods, or techniques disclosed herein may be part of a scientific instrument support system. FIG. 39 is a block diagram of an example scientific instrument support system 3900 in which some or all of the scientific instrument support methods disclosed herein may be performed, in accordance with various embodiments. The scientific instrument modules, methods, or techniques disclosed herein (e.g., the scientific instrument module 102; the computer-implemented method 200; the system 322, the computer-implemented methods 2700-3000) can be implemented by one or more of a scientific instrument 3910, a user local computing device 3920, a service local computing device 3930, or a remote computing device 3940 of the scientific instrument support system 3900.

Any of the scientific instrument 3910, the user local computing device 3920, the service local computing device 3930, or the remote computing device 3940 can include any of the embodiments of the computing device 3800, and any of the scientific instrument 3910, the user local computing device 3920, the service local computing device 3930, or the remote computing device 3940 can take the form of any appropriate ones of the embodiments of the computing device 3800.

The scientific instrument 3910, the user local computing device 3920, the service local computing device 3930, or the remote computing device 3940 may each include a processing device 3902, a storage device 3904, and an interface device 3906. The processing device 3902 may take any suitable form, including any form of the processing device 3802, and the processing devices 3902 included in different ones of the scientific instrument 3910, the user local computing device 3920, the service local computing device 3930, or the remote computing device 3940 may take the same form or different forms. The storage device 3904 may take any suitable form, including any form of the storage device 3804, and the storage devices 3904 included in different ones of the scientific instrument 3910, the user local computing device 3920, the service local computing device 3930, or the remote computing device 3940 may take the same form or different forms. The interface device 3906 may take any suitable form, including any form of the interface device 3806, and the interface devices 3906 included in different ones of the scientific instrument 3910, the user local computing device 3920, the service local computing device 3930, or the remote computing device 3940 may take the same form or different forms.

The scientific instrument 3910, the user local computing device 3920, the service local computing device 3930, and the remote computing device 3940 can be in communication with other elements of the scientific instrument support system 3900 via communication pathways 3908. The communication pathways 3908 may communicatively couple the interface devices 3906 of different ones of the elements of the scientific instrument support system 3900, as shown, and may be wired or wireless communication pathways (e.g., in accordance with any of the communication techniques discussed herein with reference to the interface device 3806). The particular scientific instrument support system 3900 depicted in FIG. 39 includes communication pathways between each pair of the scientific instrument 3910, the user local computing device 3920, the service local computing device 3930, and the remote computing device 3940, but this “fully connected” implementation is merely illustrative, and in various embodiments, various ones of the communication pathways 3908 may be absent. For example, in some embodiments, a service local computing device 3930 can lack a direct communication pathway 3908 between its interface device 3906 and the interface device 3906 of the scientific instrument 3910, but can instead communicate with the scientific instrument 3910 via the communication pathway 3908 between the service local computing device 3930 and the user local computing device 3920 and the communication pathway 3908 between the user local computing device 3920 and the scientific instrument 3910.

The scientific instrument 3910 may include any appropriate scientific instrument, such as the charged-particle microscope 302.

The user local computing device 3920 can be a computing device (e.g., in accordance with any of the embodiments of the computing device 3800) that is local to a user of the scientific instrument 3910. In some embodiments, the user local computing device 3920 may also be local to the scientific instrument 3910, but this need not be the case; for example, a user local computing device 3920 that is in a user's home or office may be remote from, but in communication with, the scientific instrument 3910 so that the user may use the user local computing device 3920 to control or access data from the scientific instrument 3910. In some embodiments, the user local computing device 3920 may be a laptop, smartphone, or tablet device. In some embodiments the user local computing device 3920 can be a portable computing device.

The service local computing device 3930 can be a computing device (e.g., in accordance with any of the embodiments of the computing device 3800) that is local to an entity that services the scientific instrument 3910. For example, the service local computing device 3930 may be local to a manufacturer of the scientific instrument 3910 or to a third-party service company. In some embodiments, the service local computing device 3930 can communicate with the scientific instrument 3910, the user local computing device 3920, or the remote computing device 3940 (e.g., via a direct communication pathway 3908 or via multiple “indirect” communication pathways 3908, as discussed above) to receive data regarding the operation of the scientific instrument 3910, the user local computing device 3920, or the remote computing device 3940 (e.g., the results of self-tests of the scientific instrument 3910, calibration coefficients used by the scientific instrument 3910, the measurements of sensors associated with the scientific instrument 3910). In some embodiments, the service local computing device 3930 may communicate with the scientific instrument 3910, the user local computing device 3920, or the remote computing device 3940 (e.g., via a direct communication pathway 3908 or via multiple “indirect” communication pathways 3908, as discussed above) to transmit data to the scientific instrument 3910, the user local computing device 3920, or the remote computing device 3940 (e.g., to update programmed instructions, such as firmware, in the scientific instrument 3910, to initiate the performance of test or calibration sequences in the scientific instrument 3910, to update programmed instructions, such as software, in the user local computing device 3920 or the remote computing device 3940). A user of the scientific instrument 3910 can utilize the scientific instrument 3910 or the user local computing device 3920 to communicate with the service local computing device 3930 to report a problem with the scientific instrument 3910 or the user local computing device 3920, to request a visit from a technician to improve the operation of the scientific instrument 3910, to order consumables or replacement parts associated with the scientific instrument 3910, or for other purposes.

The remote computing device 3940 can be a computing device (e.g., in accordance with any of the embodiments of the computing device 3800 discussed herein) that is remote from the scientific instrument 3910 or from the user local computing device 3920. In some embodiments, the remote computing device 3940 can be included in a datacenter or other large-scale server environment. In some embodiments, the remote computing device 3940 may include network-attached storage (e.g., as part of the storage device 3904). The remote computing device 3940 can store data generated by the scientific instrument 3910, perform analyses of the data generated by the scientific instrument 3910 (e.g., in accordance with programmed instructions), facilitate communication between the user local computing device 3920 and the scientific instrument 3910, or facilitate communication between the service local computing device 3930 and the scientific instrument 3910.

In some embodiments, one or more of the elements of the scientific instrument support system 3900 illustrated in FIG. 39 can be omitted. Further, in some embodiments, multiple ones of various ones of the elements of the scientific instrument support system 3900 of FIG. 39 may be present. For example, a scientific instrument support system 3900 can include multiple user local computing devices 3920 (e.g., different user local computing devices 3920 associated with different users or in different locations). In another example, a scientific instrument support system 3900 may include multiple scientific instruments 3910, all in communication with service local computing device 3930 and/or a remote computing device 3940; in such an embodiment, the service local computing device 3930 may monitor these multiple scientific instruments 3910, and the service local computing device 3930 may cause updates or other information may be “broadcast” to multiple scientific instruments 3910 at the same time. Different ones of the scientific instruments 3910 in a scientific instrument support system 3900 can be located close to one another (e.g., in the same room) or farther from one another (e.g., on different floors of a building, in different buildings, in different cities, etc.). In some embodiments, a scientific instrument 3910 can be connected to an Internet-of-Things (IOT) stack that allows for command and control of the scientific instrument 3910 through a web-based application, a virtual or augmented reality application, a mobile application, or a desktop application. Any of these applications can be accessed by a user operating the user local computing device 3920 in communication with the scientific instrument 3910 by the intervening remote computing device 3940. In some embodiments, a scientific instrument 3910 may be sold by the manufacturer along with one or more associated user local computing devices 3920 as part of a local scientific instrument computing unit 3912.

In some embodiments, different ones of the scientific instruments 3910 included in a scientific instrument support system 3900 may be different types of scientific instruments 3910; for example, one scientific instrument 3910 may be a mass spectrometer, while another scientific instrument 3910 may be a chromatograph or autosampler. In some such embodiments, the remote computing device 3940 or the user local computing device 3920 can combine data from different types of scientific instruments 3910 included in a scientific instrument support system 3900.

In various instances, machine learning algorithms or models can be implemented in any suitable way to facilitate any suitable aspects described herein. To facilitate some of the above-described machine learning aspects of various embodiments, consider the following discussion of artificial intelligence (AI). Various embodiments described herein can employ artificial intelligence to facilitate automating one or more features or functionalities. The components can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z₁, z₂, z₃, z₄, zₙ), to a confidence that the input belongs to a class, as by f(z)=confidence(class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

In order to provide additional context for various embodiments described herein, FIG. 40 and the following discussion are intended to provide a brief, general description of a suitable computing environment 4000 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 40, the example environment 4000 for implementing various embodiments of the aspects described herein includes a computer 4002, the computer 4002 including a processing unit 4004, a system memory 4006 and a system bus 4008. The system bus 4008 couples system components including, but not limited to, the system memory 4006 to the processing unit 4004. The processing unit 4004 can be any of various commercially available processors. Dual microprocessors and other multi-processor architectures can also be employed as the processing unit 4004.

The system bus 4008 can be any of several types of bus structure that can further interconnect to a memory bus (with or without a memory controller), a peripheral bus, and a local bus using any of a variety of commercially available bus architectures. The system memory 4006 includes ROM 4010 and RAM 4012. A basic input/output system (BIOS) can be stored in a non-volatile memory such as ROM, erasable programmable read only memory (EPROM), EEPROM, which BIOS contains the basic routines that help to transfer information between elements within the computer 4002, such as during startup. The RAM 4012 can also include a high-speed RAM such as static RAM for caching data.

The computer 4002 further includes an internal hard disk drive (HDD) 4014 (e.g., EIDE, SATA), one or more external storage devices 4016 (e.g., a magnetic floppy disk drive (FDD) 4016, a memory stick or flash drive reader, a memory card reader, etc.) and a drive 4020, e.g., such as a solid state drive, an optical disk drive, which can read or write from a disk 4022, such as a CD-ROM disc, a DVD, a BD, etc. Alternatively, where a solid state drive is involved, disk 4022 would not be included, unless separate. While the internal HDD 4014 is illustrated as located within the computer 4002, the internal HDD 4014 can also be configured for external use in a suitable chassis (not shown). Additionally, while not shown in environment 4000, a solid state drive (SSD) could be used in addition to, or in place of, an HDD 4014. The HDD 4014, external storage device(s) 4016 and drive 4020 can be connected to the system bus 4008 by an HDD interface 4024, an external storage interface 4026 and a drive interface 4028, respectively. The interface 4024 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 4002, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 4012, including an operating system 4030, one or more application programs 4032, other program modules 4034 and program data 4036. All or portions of the operating system, applications, modules, or data can also be cached in the RAM 4012. The systems and methods described herein can be implemented utilizing various commercially available operating systems or combinations of operating systems.

Computer 4002 can optionally comprise emulation technologies. For example, a hypervisor (not shown) or other intermediary can emulate a hardware environment for operating system 4030, and the emulated hardware can optionally be different from the hardware illustrated in FIG. 40. In such an embodiment, operating system 4030 can comprise one virtual machine (VM) of multiple VMs hosted at computer 4002. Furthermore, operating system 4030 can provide runtime environments, such as the Java runtime environment or the NET framework, for applications 4032. Runtime environments are consistent execution environments that allow applications 4032 to run on any operating system that includes the runtime environment. Similarly, operating system 4030 can support containers, and applications 4032 can be in the form of containers, which are lightweight, standalone, executable packages of software that include, e.g., code, runtime, system tools, system libraries and settings for an application.

Further, computer 4002 can be enable with a security module, such as a trusted processing module (TPM). For instance with a TPM, boot components hash next in time boot components, and wait for a match of results to secured values, before loading a next boot component. This process can take place at any layer in the code execution stack of computer 4002, e.g., applied at the application execution level or at the operating system (OS) kernel level, thereby enabling security at any level of code execution.

A user can enter commands and information into the computer 4002 through one or more wired/wireless input devices, e.g., a keyboard 4038, a touch screen 4040, and a pointing device, such as a mouse 4042. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 4004 through an input device interface 4044 that can be coupled to the system bus 4008, but can be connected by other interfaces, such as a parallel port, an IEEE 1394 serial port, a game port, a USB port, an IR interface, a BLUETOOTH® interface, etc.

A monitor 4046 or other type of display device can be also connected to the system bus 4008 via an interface, such as a video adapter 4048. In addition to the monitor 4046, a computer typically includes other peripheral output devices (not shown), such as speakers, printers, etc.

The computer 4002 can operate in a networked environment using logical connections via wired or wireless communications to one or more remote computers, such as a remote computer(s) 4050. The remote computer(s) 4050 can be a workstation, a server computer, a router, a personal computer, portable computer, microprocessor-based entertainment appliance, a peer device or other common network node, and typically includes many or all of the elements described relative to the computer 4002, although, for purposes of brevity, only a memory/storage device 4052 is illustrated. The logical connections depicted include wired/wireless connectivity to a local area network (LAN) 4054 or larger networks, e.g., a wide area network (WAN) 4056. Such LAN and WAN networking environments are commonplace in offices and companies, and facilitate enterprise-wide computer networks, such as intranets, all of which can connect to a global communications network, e.g., the Internet.

When used in a LAN networking environment, the computer 4002 can be connected to the local network 4054 through a wired or wireless communication network interface or adapter 4058. The adapter 4058 can facilitate wired or wireless communication to the LAN 4054, which can also include a wireless access point (AP) disposed thereon for communicating with the adapter 4058 in a wireless mode.

When used in a WAN networking environment, the computer 4002 can include a modem 4060 or can be connected to a communications server on the WAN 4056 via other means for establishing communications over the WAN 4056, such as by way of the Internet. The modem 4060, which can be internal or external and a wired or wireless device, can be connected to the system bus 4008 via the input device interface 4044. In a networked environment, program modules depicted relative to the computer 4002 or portions thereof, can be stored in the remote memory/storage device 4052. It will be appreciated that the network connections shown are example and other means of establishing a communications link between the computers can be used.

When used in either a LAN or WAN networking environment, the computer 4002 can access cloud storage systems or other network-based storage systems in addition to, or in place of, external storage devices 4016 as described above, such as but not limited to a network virtual machine providing one or more aspects of storage or processing of information. Generally, a connection between the computer 4002 and a cloud storage system can be established over a LAN 4054 or WAN 4056 e.g., by the adapter 4058 or modem 4060, respectively. Upon connecting the computer 4002 to an associated cloud storage system, the external storage interface 4026 can, with the aid of the adapter 4058 or modem 4060, manage storage provided by the cloud storage system as it would other types of external storage. For instance, the external storage interface 4026 can be configured to provide access to cloud storage sources as if those sources were physically connected to the computer 4002.

The computer 4002 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 41 is a schematic block diagram of a sample computing environment 4100 with which the disclosed subject matter can interact. The sample computing environment 4100 includes one or more client(s) 4110. The client(s) 4110 can be hardware or software (e.g., threads, processes, computing devices). The sample computing environment 4100 also includes one or more server(s) 4130. The server(s) 4130 can also be hardware or software (e.g., threads, processes, computing devices). The servers 4130 can house threads to perform transformations by employing one or more embodiments as described herein, for example. One possible communication between a client 4110 and a server 4130 can be in the form of a data packet adapted to be transmitted between two or more computer processes. The sample computing environment 4100 includes a communication framework 4150 that can be employed to facilitate communications between the client(s) 4110 and the server(s) 4130. The client(s) 4110 are operably connected to one or more client data store(s) 4120 that can be employed to store information local to the client(s) 4110. Similarly, the server(s) 4130 are operably connected to one or more server data store(s) 4140 that can be employed to store information local to the servers 4130.

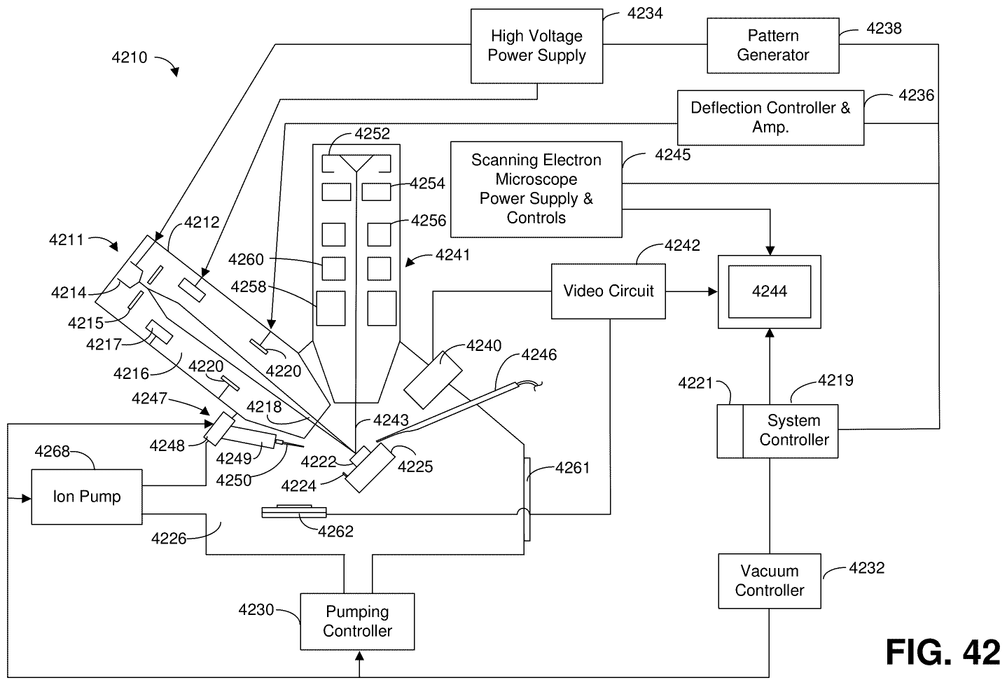

An example, non-limiting apparatus for performing various embodiments described herein is shown in FIG. 42. FIG. 42 illustrates a non-limiting example of a dual beam system 4210 with a vertically mounted scanning electron microscope (SEM) column and a focused ion beam (FIB) column mounted at an angle of approximately 52 degrees from the vertical. Such dual beam systems are commercially available, for example, from FEI Company, Hillsboro, Oregon, the assignee of the present application. While FIG. 42 shows an example of suitable microscopy hardware with which various embodiments described herein can be implemented, it is to be appreciated that such microscopy hardware is non-limiting. In other words, various embodiments described herein can be implemented in conjunction with any other suitable types of microscopy hardware. The dual beam system 4210 is a non-limiting example of the charged-particle microscope 302 or of any other scientific instruments discussed above.

A scanning electron microscope 4241, along with a power supply and control unit 4245, can be provided with the dual beam system 4210. An electron beam 4243 can be emitted from a cathode 4252 by applying voltage between the cathode 4252 and an anode 4254. The electron beam 4243 can be focused to a fine spot by means of a condensing lens 4256 and an objective lens 4258. The electron beam 4243 can be scanned two-dimensionally on any suitable specimen by means of a deflection coil 4260. Operation of the condensing lens 4256, the objective lens 4258, or the deflection coil 4260 can be controlled by the power supply and control unit 4245.

The electron beam 4243 can be focused onto a substrate 4222, which can be on a movable X-Y stage 4225 within a lower chamber 4226. When the electrons in the electron beam 4243 strike the substrate 4222, secondary electrons can be emitted. These secondary electrons can be detected by a secondary electron detector 4240 as discussed below. A scanning transmission electron microscopy (STEM) detector 4262, located beneath a STEM sample holder 4224 and the movable X-Y stage 4225, can collect electrons that are transmitted through the sample mounted on the STEM sample holder 4224 as discussed above.

The dual beam system 4210 can also include a focused ion beam (FIB) system 4211 which can comprise an evacuated chamber having an upper neck portion 4212 within which can be located an ion source 4214 and a focusing column 4216 including extractor electrodes and an electrostatic optical system (in some cases, the upper neck portion can also be referred to as an ion column 4212). The axis of the focusing column 4216 can be tilted 52 degrees (or any other suitable angular displacement) from the axis of the electron column. The ion column 4212 can include an ion source 4214, an extraction electrode 4215, a focusing element 4217, deflection elements 4220, and a focused ion beam 4218. The focused ion beam 4218 can pass from the ion source 4214 through the focusing column 4216 and between electrostatic deflection means schematically indicated at numeral 4220 toward the substrate 4222, which can comprise, for example, a semiconductor device positioned on the movable X-Y stage 4225 within the lower chamber 4226.

The movable X-Y stage 4225 can move in a horizontal plane (along X and Y axes) and vertically (along Z axis). The movable X-Y stage 4225 can tilt approximately sixty (60) degrees and rotate about the Z axis. In some embodiments, a separate STEM sample stage (not shown) can be used. Such a STEM sample stage can be moveable in the X, Y, and Z axes. A door 4261 can be opened for inserting the substrate 4222 onto the movable X-Y stage 4225 or also for servicing an internal gas supply reservoir, if one is used. The door 4261 can be interlocked so that it cannot be opened if the system is under vacuum.

An ion pump 4268 can be employed for evacuating the neck portion 4212. The chamber 4226 can be evacuated with a turbomolecular and mechanical pumping system 4230 under the control of a vacuum controller 4232. Such vacuum system can provide within the chamber 4226 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

A high voltage power supply 4234 can provide an appropriate acceleration voltage to electrodes in the focusing column 4216 for energizing and the focused ion beam 4218. When it strikes the substrate 4222, material can be sputtered (that is, physically ejected) from the sample. Alternatively, the focused ion beam 4218 can decompose a precursor gas to deposit a material.

The high voltage power supply 4234 can be connected to the ion source 4214 (which can be a liquid metal ion source) as well as to appropriate electrodes in the ion beam focusing column 4216 for forming an approximately 1 keV to 60 keV ion beam 4218 and directing the same toward a sample. A deflection controller and amplifier 4236, operated in accordance with a prescribed pattern provided by a pattern generator 4238, can be coupled to the deflection elements 4220 (which can be deflection plates) whereby the focused ion beam 4218 may be controlled manually or automatically to trace out a corresponding pattern on the upper surface of the substrate 4222. In some systems, the deflection elements 4220 can be placed before the final lens. Beam blanking electrodes (not shown) within the ion beam focusing column 4216 can cause the focused ion beam 4218 to impact onto a blanking aperture (not shown) instead of the substrate 4222 when a blanking controller (not shown) applies a blanking voltage to a blanking electrode.

The ion source 4214 can provide a metal ion beam of gallium, for example. In other examples, the ion source 4214 may be a plasma ion source that extracts ions from a generated plasma. The source can be capable of being focused into a sub one-tenth micrometer wide beam at the substrate 4222 for either modifying the substrate 4222 by ion milling, enhanced etch, material deposition, or for the purpose of imaging the substrate 4222.

A charged particle detector 4240, such as an Everhart Thornley or multi-channel plate, used for detecting secondary ion or electron emission can be connected to a video circuit 4242 that can supply drive signals to a video monitor 4244 and receive deflection signals from a system controller 4219. The location of the charged particle detector 4240 within the lower chamber 4226 can vary in different embodiments. For example, the charged particle detector 4240 can be coaxial with the ion beam and include a hole for allowing the ion beam to pass. In other embodiments, secondary particles can be collected through a final lens and then diverted off axis for collection.

A micromanipulator 4247 can precisely move objects within the vacuum chamber. The micromanipulator 4247 may comprise precision electric motors 4248 positioned outside the vacuum chamber to provide X, Y, Z, and theta control of a portion 4249 positioned within the vacuum chamber. The micromanipulator 4247 can be fitted with different end effectors for manipulating small objects. In various embodiments described herein, the end effector can be a thin probe 4250.

A gas delivery system 4246 can extend into the lower chamber 4226 for introducing and directing a gaseous vapor toward the substrate 4222. U.S. Pat. No. 5,851,413 to Casella et al. for “Gas Delivery Systems for Particle Beam Processing,” assigned to the assignee of the present invention, describes a suitable gas delivery system 4246. Another gas delivery system is described in U.S. Pat. No. 5,435,850 to Rasmussen for a “Gas Injection System,” also assigned to the assignee of the present invention. For example, iodine can be delivered to enhance etching, or a metal organic compound can be delivered to deposit a metal.

The system controller 4219 can control the operations of the various parts of the dual beam system 4210. Through the system controller 4219, a user can cause the focused ion beam 4218 or the electron beam 4243 to be scanned in a desired manner through commands entered into any suitable user interface (not shown). Alternatively, the system controller 4219 may control the dual beam system 4210 in accordance with programmed instructions stored in a memory 4221. In various embodiments, any of the one or more software components 327 can be implemented in or otherwise executed by the system controller 4219.

Various embodiments may be a system, a method, an apparatus or a computer program product at any possible technical detail level of integration. The computer program product can include a computer readable storage medium (or media) having computer readable program instructions thereon for causing a processor to carry out aspects of various embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network or a wireless network. The network can comprise copper transmission cables, optical transmission fibers, wireless transmission, routers, firewalls, switches, gateway computers or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform various aspects.

Various aspects are described herein with reference to flowchart illustrations or block diagrams of methods, apparatus (systems), and computer program products according to various embodiments. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus, or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart or block diagram block or blocks.

The flowcharts and block diagrams in the Figures illustrate the architecture, functionality, and operation of possible implementations of systems, methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that this disclosure also can or can be implemented in combination with other program modules. Generally, program modules include routines, programs, components, data structures, etc. that perform particular tasks or implement particular abstract data types. Moreover, those skilled in the art will appreciate that various aspects can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system, or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. As used herein, the term “and/or” is intended to have the same meaning as “or.” Moreover, articles “a” and “an” as used in the subject specification and annexed drawings should generally be construed to mean “one or more” unless specified otherwise or clear from context to be directed to a singular form. As used herein, the terms “example” or “exemplary” are utilized to mean serving as an example, instance, or illustration. For the avoidance of doubt, the subject matter disclosed herein is not limited by such examples. In addition, any aspect or design described herein as an “example” or “exemplary” is not necessarily to be construed as preferred or advantageous over other aspects or designs, nor is it meant to preclude equivalent exemplary structures and techniques known to those of ordinary skill in the art.

The herein disclosure describes non-limiting examples. For ease of description or explanation, various portions of the herein disclosure utilize the term “each,” “every,” or “all” when discussing various examples. Such usages of the term “each,” “every,” or “all” are non-limiting. In other words, when the herein disclosure provides a description that is applied to “each,” “every,” or “all” of some particular object or component, it should be understood that this is a non-limiting example, and it should be further understood that, in various other examples, it can be the case that such description applies to fewer than “each,” “every,” or “all” of that particular object or component.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various non-limiting aspects are described in the following examples.

EXAMPLE 1: An apparatus can comprise: a charged-particle microscope having a vacuum chamber, wherein the vacuum chamber can comprise a robotic gripper and a microscopy grid receptacle; and a processor that can be configured to teach the robotic gripper to angularly or translationally align its shaft-axis with a bore-axis of the microscopy grid receptacle, based on a light source coupled to the robotic gripper.

EXAMPLE 2: The apparatus of any preceding example can be implemented, wherein the microscopy grid receptacle can comprise a reflector that can be positioned on or in a bore corresponding to the bore-axis, such that the reflector can be orthogonal to the bore-axis, and further comprising: a camera; and a beamsplitter, wherein the light source can be configured to shine a light beam through the beamsplitter, wherein the beamsplitter can be configured to direct a first portion of the light beam toward the camera, wherein the beamsplitter can be configured to direct a second portion of the light beam toward the reflector, wherein the reflector can be configured to reflect the second portion of the light beam back toward the beamsplitter, and wherein the beamsplitter can be configured to direct at least some of the second portion of the light beam toward the camera.

EXAMPLE 3: The apparatus of any preceding example can be implemented, wherein the beamsplitter can be a cubic prism comprising a first beamsplitting coating and a second beamsplitting coating, wherein the first beamsplitting coating can be positioned along an interior diagonal plane of the cubic prism, and wherein the second beamsplitting coating can be positioned along an external surface of the cubic prism.

EXAMPLE 4: The apparatus of any preceding example can be implemented, further comprising: a collimator lens positioned between the light source and the beamsplitter.

EXAMPLE 5: The apparatus of any preceding example can be implemented, wherein the camera can be configured to capture an image, wherein the image can depict a first illuminated spot caused by the first portion of the light beam, and wherein the image can depict a second illuminated spot caused by the at least some of the second portion of the light beam.

EXAMPLE 6: The apparatus of any preceding example can be implemented, wherein the first illuminated spot and the second illuminated spot being non-concentric can indicate that the shaft-axis of the robotic gripper is angularly or translationally misaligned with the bore-axis of the microscopy grid receptacle, and wherein the first illuminated spot and the second illuminated spot being concentric can indicate that the shaft-axis of the robotic gripper is angularly or translationally aligned with the bore-axis of the microscopy grid receptacle.

EXAMPLE 7: The apparatus of any preceding example can be implemented, wherein the processor can be configured to apply an object detection technique to the image, thereby determining whether or not the first illuminated spot and the second illuminated spot are overlapping.

EXAMPLE 8: The apparatus of any preceding example can be implemented, wherein, in response to a determination that the first illuminated spot and the second illuminated spot are not overlapping, the processor can be configured to: identify a first centroid of the first illuminated spot, based on averaging positions of pixels belonging to the first illuminated spot; identify a second centroid of the second illuminated spot, based on averaging positions of pixels belonging to the second illuminated spot; compute, via one or more kinematic formulas, an angular or translational position of the robotic gripper that is predicted to reduce a distance separating the first centroid from the second centroid; and cause the robotic gripper to move to the angular or translational position.

EXAMPLE 9: The apparatus of any preceding example can be implemented, wherein, in response to a determination that the first illuminated spot and the second illuminated spot are overlapping, the processor can be configured to: circumscribe the first illuminated spot and the second illuminated spot with a least-area contour; identify, via one or more geometric formulas based on the least-area contour, a first centroid of the first illuminated spot and a second centroid of the second illuminated spot; in response to a distance separating the first centroid from the second centroid being greater than a threshold, compute, via one or more kinematic formulas, an angular or translational position of the robotic gripper that is predicted to reduce the distance; and cause the robotic gripper to move to the angular or translational position.

EXAMPLE 10: The apparatus of any preceding example can be implemented, wherein, in response to a determination that the first illuminated spot and the second illuminated spot are overlapping, the processor can be configured to: circumscribe the first illuminated spot and the second illuminated spot with a least-area contour; identify, via one or more geometric formulas based on the least-area contour, a first centroid of the first illuminated spot and a second centroid of the second illuminated spot; in response to a distance separating the first centroid from the second centroid being less than a threshold, cause the robotic gripper to sweep through a range of angular or translational positions within a threshold proximity of its current angular or translational position; compute respective areas of the least-area contour for the range of angular or translational positions; and cause the robotic gripper to move to whichever of the range of angular or translational positions corresponds to a minimized area of the least-area contour

In various embodiments, any combination or combinations of examples 1-10 can be implemented.

EXAMPLE 11: A computer-implemented method can comprise: accessing, by a device operatively coupled to a processor, a charged-particle microscope having a vacuum chamber, wherein the vacuum chamber can comprise a robotic gripper and a microscopy grid receptacle; and teaching, by the device, the robotic gripper to angularly or translationally align its shaft-axis with a bore-axis of the microscopy grid receptacle, based on a light source coupled to the robotic gripper.

EXAMPLE 12: The computer-implemented method of any preceding example can be implemented, further comprising: causing, by the device, the light source to shine a light beam through a beamsplitter, wherein the beamsplitter can be configured to direct a first portion of the light beam toward a camera, wherein the beamsplitter can be configured to direct a second portion of the light beam toward a reflector that can be positioned on or in a bore corresponding to the bore-axis, wherein the reflector can be configured to reflect the second portion of the light beam back toward the beamsplitter, and wherein the beamsplitter can be configured to direct at least some of the second portion of the light beam toward the camera.

EXAMPLE 13: The computer-implemented method of any preceding example can be implemented, wherein the beamsplitter can be a cubic prism comprising a first beamsplitting coating and a second beamsplitting coating, wherein the first beamsplitting coating can be positioned along an interior diagonal plane of the cubic prism, and wherein the second beamsplitting coating can be positioned along an external surface of the cubic prism.

EXAMPLE 14: The computer-implemented method of any preceding example can be implemented, wherein the camera can be configured to capture an image, wherein the image can depict a first illuminated spot caused by the first portion of the light beam, and wherein the image can depict a second illuminated spot caused by the at least some of the second portion of the light beam.

EXAMPLE 15: The computer-implemented method of any preceding example can be implemented, further comprising: determining, by the device and via application of an object detection technique to the image, whether or not the first illuminated spot and the second illuminated spot are overlapping.

EXAMPLE 16: The computer-implemented method of any preceding example can be implemented, further comprising, in response to a determination that the first illuminated spot and the second illuminated spot are not overlapping: identifying, by the device, a first centroid of the first illuminated spot, based on averaging positions of pixels belonging to the first illuminated spot; identifying, by the device, a second centroid of the second illuminated spot, based on averaging positions of pixels belonging to the second illuminated spot; computing, by the device and via one or more kinematic formulas, an angular or translational position of the robotic gripper that is predicted to reduce a distance separating the first centroid from the second centroid; and causing, by the device, the robotic gripper to move to the angular or translational position.

EXAMPLE 17: The computer-implemented method of any preceding example can be implemented, further comprising, in response to a determination that the first illuminated spot and the second illuminated spot are overlapping: circumscribing, by the device, the first illuminated spot and the second illuminated spot with a least-area contour; identifying, by the device and via one or more geometric formulas based on the least-area contour, a first centroid of the first illuminated spot and a second centroid of the second illuminated spot; in response to a distance separating the first centroid from the second centroid being greater than a threshold, computing, by the device and via one or more kinematic formulas, an angular or translational position of the robotic gripper that is predicted to reduce the distance; and causing, by the device, the robotic gripper to move to the angular or translational position.

EXAMPLE 18: The computer-implemented method of any preceding example can be implemented, further comprising, in response to a determination that the first illuminated spot and the second illuminated spot are overlapping: circumscribing, by the device, the first illuminated spot and the second illuminated spot with a least-area contour; identifying, by the device and via one or more geometric formulas based on the least-area contour, a first centroid of the first illuminated spot and a second centroid of the second illuminated spot; in response to a distance separating the first centroid from the second centroid being less than a threshold, causing, by the device, the robotic gripper to sweep through a range of angular or translational positions within a threshold proximity of its current angular or translational position; computing, by the device, respective areas of the least-area contour for the range of angular or translational positions; and causing, by the device, the robotic gripper to move to whichever of the range of angular or translational positions corresponds to a minimized area of the least-area contour.

In various embodiments, any combination or combinations of examples 11-18 can be implemented.

EXAMPLE 19: A computer program product for facilitating teaching of charged-particle microscopy robotic grippers via beamsplitting can comprise a non-transitory computer-readable memory having program instructions embodied therewith. In various aspects, the program instructions can be executable by a processor to cause the processor to: access a charged-particle microscope having a vacuum chamber, wherein the vacuum chamber can comprise a robotic gripper and a microscopy grid receptacle; cause a light source affixed to the robotic gripper to shine a light beam through a beamsplitter, wherein the beamsplitter can be configured to direct a first portion of the light beam toward a camera, wherein the beamsplitter can be configured to direct a second portion of the light beam toward a reflector that is positioned on or in a bore of the microscopy grid receptacle, wherein the reflector can be configured to reflect the second portion of the light beam back toward the beamsplitter, and wherein the beamsplitter can be configured to direct at least some of the second portion of the light beam toward the camera; access an image captured by the camera, wherein the image can depict a first illuminated spot caused by the first portion of the light beam, and wherein the image can depict a second illuminated spot caused by the at least some of the second portion of the light beam; identify, based on a distance separating respective centroids of the first illuminated spot and the second illuminated spot, one or more angular or translational movements of the robotic gripper that would cause a shaft-axis of the robotic gripper to become angularly or translationally aligned with the bore of the microscopy grid receptacle; and cause the robotic gripper to perform the one or more angular or translational movements.

EXAMPLE 20: The computer program product of any preceding example can be implemented, wherein how the processor analyzes the image to identify the one or more angular or translational movements can be based on whether or not the first illuminated spot and the second illuminated spot are overlapping.

In various embodiments, any combination or combinations of examples 19-20 can be implemented.

In various embodiments, any combination or combinations of examples 1-20 can be implemented.

What is claimed is:

1. An apparatus, comprising:
a charged-particle microscope having a vacuum chamber, wherein the vacuum chamber comprises a robotic gripper and a microscopy grid receptacle; and
a processor that is configured to teach the robotic gripper to angularly or translationally align its shaft-axis with a bore-axis of the microscopy grid receptacle, based on a light source coupled to the robotic gripper.

2. The apparatus of claim 1, wherein the microscopy grid receptacle comprises a reflector that is positioned on or in a bore corresponding to the bore-axis, such that the reflector is orthogonal to the bore-axis, and further comprising:
a camera; and
a beamsplitter, wherein the light source is configured to shine a light beam through the beamsplitter, wherein the beamsplitter is configured to direct a first portion of the light beam toward the camera, wherein the beamsplitter is configured to direct a second portion of the light beam toward the reflector, wherein the reflector is configured to reflect the second portion of the light beam back toward the beamsplitter, and wherein the beamsplitter is configured to direct at least some of the second portion of the light beam toward the camera.

3. The apparatus of claim 2, wherein the beamsplitter is a cubic prism comprising a first beamsplitting coating and a second beamsplitting coating, wherein the first beamsplitting coating is positioned along an interior diagonal plane of the cubic prism, and wherein the second beamsplitting coating is positioned along an external surface of the cubic prism.

4. The apparatus of claim 2, further comprising:
a collimator lens positioned between the light source and the beamsplitter.

5. The apparatus of claim 2, wherein the camera is configured to capture an image, wherein the image depicts a first illuminated spot caused by the first portion of the light beam, and wherein the image depicts a second illuminated spot caused by the at least some of the second portion of the light beam.

6. The apparatus of claim 5, wherein the first illuminated spot and the second illuminated spot being non-concentric indicates that the shaft-axis of the robotic gripper is angularly or translationally misaligned with the bore-axis of the microscopy grid receptacle, and wherein the first illuminated spot and the second illuminated spot being concentric indicates that the shaft-axis of the robotic gripper is angularly or translationally aligned with the bore-axis of the microscopy grid receptacle.

7. The apparatus of claim 5, wherein the processor is configured to apply an object detection technique to the image, thereby determining whether or not the first illuminated spot and the second illuminated spot are overlapping.

8. The apparatus of claim 7, wherein, in response to a determination that the first illuminated spot and the second illuminated spot are not overlapping, the processor is configured to:
identify a first centroid of the first illuminated spot, based on averaging positions of pixels belonging to the first illuminated spot;
identify a second centroid of the second illuminated spot, based on averaging positions of pixels belonging to the second illuminated spot;
compute, via one or more kinematic formulas, an angular or translational position of the robotic gripper that is predicted to reduce a distance separating the first centroid from the second centroid; and
cause the robotic gripper to move to the angular or translational position.

9. The apparatus of claim 7, wherein, in response to a determination that the first illuminated spot and the second illuminated spot are overlapping, the processor is configured to:
circumscribe the first illuminated spot and the second illuminated spot with a least-area contour;
identify, via one or more geometric formulas based on the least-area contour, a first centroid of the first illuminated spot and a second centroid of the second illuminated spot;
in response to a distance separating the first centroid from the second centroid being greater than a threshold, compute, via one or more kinematic formulas, an angular or translational position of the robotic gripper that is predicted to reduce the distance; and
cause the robotic gripper to move to the angular or translational position.

10. The apparatus of claim 7, wherein, in response to a determination that the first illuminated spot and the second illuminated spot are overlapping, the processor is configured to:
circumscribe the first illuminated spot and the second illuminated spot with a least-area contour;
identify, via one or more geometric formulas based on the least-area contour, a first centroid of the first illuminated spot and a second centroid of the second illuminated spot;
in response to a distance separating the first centroid from the second centroid being less than a threshold, cause the robotic gripper to sweep through a range of angular or translational positions within a threshold proximity of its current angular or translational position;
compute respective areas of the least-area contour for the range of angular or translational positions; and
cause the robotic gripper to move to whichever of the range of angular or translational positions corresponds to a minimized area of the least-area contour.

11. A computer-implemented method, comprising:
accessing, by a device operatively coupled to a processor, a charged-particle microscope having a vacuum chamber, wherein the vacuum chamber comprises a robotic gripper and a microscopy grid receptacle; and
teaching, by the device, the robotic gripper to angularly or translationally align its shaft-axis with a bore-axis of the microscopy grid receptacle, based on a light source coupled to the robotic gripper.

12. The computer-implemented method of claim 11, further comprising:
causing, by the device, the light source to shine a light beam through a beamsplitter, wherein the beamsplitter is configured to direct a first portion of the light beam toward a camera, wherein the beamsplitter is configured to direct a second portion of the light beam toward a reflector that is positioned on or in a bore corresponding to the bore-axis, wherein the reflector is configured to reflect the second portion of the light beam back toward the beamsplitter, and wherein the beamsplitter is configured to direct at least some of the second portion of the light beam toward the camera.

13. The computer-implemented method of claim 12, wherein the beamsplitter is a cubic prism comprising a first beamsplitting coating and a second beamsplitting coating, wherein the first beamsplitting coating is positioned along an interior diagonal plane of the cubic prism, and wherein the second beamsplitting coating is positioned along an external surface of the cubic prism.

14. The computer-implemented method of claim 12, wherein the camera is configured to capture an image, wherein the image depicts a first illuminated spot caused by the first portion of the light beam, and wherein the image depicts a second illuminated spot caused by the at least some of the second portion of the light beam.

15. The computer-implemented method of claim 14, further comprising:
determining, by the device and via application of an object detection technique to the image, whether or not the first illuminated spot and the second illuminated spot are overlapping.

16. The computer-implemented method of claim 15, further comprising, in response to a determination that the first illuminated spot and the second illuminated spot are not overlapping:
identifying, by the device, a first centroid of the first illuminated spot, based on averaging positions of pixels belonging to the first illuminated spot;
identifying, by the device, a second centroid of the second illuminated spot, based on averaging positions of pixels belonging to the second illuminated spot;
computing, by the device and via one or more kinematic formulas, an angular or translational position of the robotic gripper that is predicted to reduce a distance separating the first centroid from the second centroid; and
causing, by the device, the robotic gripper to move to the angular or translational position.

17. The computer-implemented method of claim 15, further comprising, in response to a determination that the first illuminated spot and the second illuminated spot are overlapping:
circumscribing, by the device, the first illuminated spot and the second illuminated spot with a least-area contour;
identifying, by the device and via one or more geometric formulas based on the least-area contour, a first centroid of the first illuminated spot and a second centroid of the second illuminated spot;
in response to a distance separating the first centroid from the second centroid being greater than a threshold, computing, by the device and via one or more kinematic formulas, an angular or translational position of the robotic gripper that is predicted to reduce the distance; and
causing, by the device, the robotic gripper to move to the angular or translational position.

18. The computer-implemented method of claim 15, further comprising, in response to a determination that the first illuminated spot and the second illuminated spot are overlapping:
circumscribing, by the device, the first illuminated spot and the second illuminated spot with a least-area contour;
identifying, by the device and via one or more geometric formulas based on the least-area contour, a first centroid of the first illuminated spot and a second centroid of the second illuminated spot;
in response to a distance separating the first centroid from the second centroid being less than a threshold, causing, by the device, the robotic gripper to sweep through a range of angular or translational positions within a threshold proximity of its current angular or translational position;
computing, by the device, respective areas of the least-area contour for the range of angular or translational positions; and
causing, by the device, the robotic gripper to move to whichever of the range of angular or translational positions corresponds to a minimized area of the least-area contour.

19. A computer program product for facilitating teaching of charged-particle microscopy robotic grippers via beamsplitting, the computer program product comprising a non-transitory computer-readable memory having program instructions embodied therewith, the program instructions executable by a processor to cause the processor to:
access a charged-particle microscope having a vacuum chamber, wherein the vacuum chamber comprises a robotic gripper and a microscopy grid receptacle;
cause a light source affixed to the robotic gripper to shine a light beam through a beamsplitter, wherein the beamsplitter is configured to direct a first portion of the light beam toward a camera, wherein the beamsplitter is configured to direct a second portion of the light beam toward a reflector that is positioned on or in a bore of the microscopy grid receptacle, wherein the reflector is configured to reflect the second portion of the light beam back toward the beamsplitter, and wherein the beamsplitter is configured to direct at least some of the second portion of the light beam toward the camera;
access an image captured by the camera, wherein the image depicts a first illuminated spot caused by the first portion of the light beam, and wherein the image depicts a second illuminated spot caused by the at least some of the second portion of the light beam;
identify, based on a distance separating respective centroids of the first illuminated spot and the second illuminated spot, one or more angular or translational movements of the robotic gripper that would cause a shaft-axis of the robotic gripper to become angularly or translationally aligned with the bore of the microscopy grid receptacle; and
cause the robotic gripper to perform the one or more angular or translational movements.

20. The computer program product of claim 19, wherein how the processor analyzes the image to identify the one or more angular or translational movements is based on whether or not the first illuminated spot and the second illuminated spot are overlapping.
